(19) United States
(12) Patent Application Publication
(10) Pub. No.: US 2024/0147745 A1
(43) Pub. Date: May 2, 2024

(54) Light-Emitting Apparatus and Electronic Device

(71) Applicant: Semiconductor Energy Laboratory Co., Ltd., Kanagawa-ken (JP)

(72) Inventors: Yui YOSHIYASU, Atsugi Kanagawa (JP); Naoaki HASHIMOTO, Sagamihara, Kanagawa (JP); Tatsuyoshi TAKAHASHI, Atsugi, Kanagawa (JP); Sachiko KAWAKAMI, Atsugi, Kanagawa (JP); Satoshi SEO, Sagamihara,Kanagawa (JP)

(73) Assignee: Semiconductor Energy Laboratory Co., Ltd., Kanagawa-ken (JP)

(21) Appl. No.: 18/275,759

(22) PCT Filed: Feb. 2, 2022
(86) PCT No.: PCT/IB2022/050880

§ 371 Date: Aug. 3, 2023

(30) Foreign Application Priority Data
Feb. 12, 2021 (JP) 2021-021328
Feb. 12, 2021 (JP) 2021-021329

(51) Int. Cl. H10K 50/11; H10K 50/16; H10K 50/17; H10K 59/95; H10K 71/20; H10K 85/10

(52) U.S. Cl. CPC H10K 50/11; H10K 50/16; H10K 50/171; H10K 59/95; H10K 71/233; H10K 85/111

(57) ABSTRACT

A light-emitting device with a high resolution and favorable characteristics manufactured by a photolithography method is provided. In the light-emitting device, a first light-emitting device and a second light-emitting device are adjacent each other. The first light-emitting device includes a first EL layer, and the second light-emitting device includes a second EL layer. The first EL layer includes at least a first light-emitting layer and a first electron-transport layer, and the second EL layer includes at least a second light-emitting layer and a second electron-transport layer. The first electron-transport layer contains a first heteroaromatic compound and a first organic compound, and the second electron-transport layer contains a second heteroaromatic compound and a second organic compound. Edge portions of the first light-emitting layer and the first electron-transport layer are aligned, and edge portions of the second light-emitting layer and the second electron-transport layer are substantially aligned. The distance between the first light-emitting device and the second light-emitting device facing each other is 2 μm to 5 μm.

### TECHNICAL FIELD

One embodiment of the present invention relates to an organic compound, a light-emitting element, a light-emitting device, a display module, a lighting module, a display device, a light-emitting apparatus, an electronic device, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display apparatus, a liquid crystal display apparatus, a light-emitting apparatus, a lighting device, a power storage device, a memory device, an imaging device, a driving method thereof, and a manufacturing method thereof.

### BACKGROUND ART

Light-emitting devices (organic EL devices) including organic compounds and utilizing electroluminescence (EL) have been put to more practical use. In the basic structure of such light-emitting devices, an organic compound layer containing a light-emitting material (an EL layer) is sandwiched between a pair of electrodes. Carriers are injected by application of a voltage to the device, and recombination energy of the carriers is used, whereby light emission can be obtained from the light-emitting material.

Such light-emitting devices are of self-luminous type and thus have advantages over liquid crystal devices, such as high visibility and no need for a backlight when used for pixels of a display, and are particularly suitable for flat panel displays. Displays including such light-emitting devices are also highly advantageous in that they can be thin and lightweight. Moreover, such light-emitting devices also have a feature that the response speed is extremely fast.

Since light-emitting layers of such light-emitting devices can be successively formed two-dimensionally, planar light emission can be achieved. This feature is difficult to realize with point light sources typified by incandescent lamps and LEDs or linear light sources typified by fluorescent lamps; thus, the light-emitting devices also have great potential as planar light sources, which can be applied to lighting and the like.

Light-emitting apparatuses including light-emitting devices are suitable for a variety of electronic devices as described above, and research and development of light-emitting devices have progressed for more favorable characteristics.

In order to obtain a higher-resolution light-emitting apparatus using an organic EL device, patterning an organic layer by a photolithography method using a photoresist or the like, instead of an evaporation method using a metal mask, has been studied. By using the photolithography method, a high-resolution light-emitting apparatus in which a distance between EL layers is several micrometers can be obtained (see Patent Document 1, for example).

### REFERENCE

### Patent Document

[Patent Document 1] Japanese Translation of PCT International Application No. 2018-521459

### SUMMARY OF THE INVENTION

### Problems to be Solved by the Invention

In patterning by a photolithography method, heat is sometimes applied at the time of forming a photomask. In an organic layer in a light-emitting device, in particular, a material used for an electron-transport region, crystallization proceeds at a low temperature owing to its stacked-layer structure in some cases, which might cause a defect, crystallization of the organic layer due to the heat applied at the time of forming the photomask. Therefore, a method for reducing heat to be applied at the time of curing the photomask is sometimes employed; however, there is a problem of not obtaining high resolution as expected because there is a limit to increasing the resolution when etching is performed using a photomask not sufficiently cured.

In view of the above, an object of one embodiment of the present invention is to provide a light-emitting device with a higher resolution and favorable characteristics manufactured by a photolithography method.

### Means for Solving the Problems

In view of the above, one embodiment of the present invention provides a light-emitting device manufactured by a photolithography method, in which an electron-transport layer includes at least two organic compounds.

That is, one embodiment of the present invention is a light-emitting apparatus including a first light-emitting device and a second light-emitting device adjacent each other over an insulating plane. The first light-emitting device includes a first anode, a first cathode, and a first EL layer interposed between the first anode and the first cathode. The second light-emitting device includes a second anode, a second cathode, and a second EL layer interposed between the second anode and the second cathode. The first EL layer includes at least a first light-emitting layer and a first electron-transport layer. The first electron-transport layer is positioned between the first light-emitting layer and the first cathode. The second EL layer includes at least a second light-emitting layer and a second electron-transport layer. The second electron-transport layer is positioned between the second light-emitting layer and the second cathode. The first electron-transport layer contains at least a first heteroaromatic compound having a first heteroaromatic ring and a first organic compound different from the first heteroaromatic compound. The second electron-transport layer contains at least a second heteroaromatic compound having a second heteroaromatic ring and a second organic compound different from the second heteroaromatic compound. The edge portion of the first light-emitting layer and the edge portion of the first electron-transport layer are substantially aligned at a first edge portion when seen from a direction perpendicular to the insulating plane. The edge portion of the second light-emitting layer and the edge portion of the second electron-transport layer are substantially aligned at a second edge portion when seen from the direction perpendicular to the insulating plane. The distance between the first edge portion and the second edge portion facing each other is 2 μm to 5 μm

Another embodiment of the present invention is the light-emitting apparatus with the above structure, in which the first electron-transport layer contains the first heteroaromatic compound having the first heteroaromatic ring and the first organic compound different from the first heteroaromatic compound, and the second electron-transport layer contains the second heteroaromatic compound having the second heteroaromatic ring and the second organic compound different from the second heteroaromatic compound.

Another embodiment of the present invention is a light-emitting apparatus including a first light-emitting device and a second light-emitting device adjacent to each other over an insulating plane. The first light-emitting device includes a first anode, a first cathode, and a first EL layer interposed between the first anode and the first cathode. The second light-emitting device includes a second anode, a second cathode, and a second EL layer interposed between the second anode and the second cathode. The first EL layer includes at least a light-emitting layer 1a, a first charge-generation layer, a light-emitting layer 1b, and an electron-transport layer 1b in this order from the first anode side. The electron-transport layer 1b is positioned between the light-emitting layer 1b and the first cathode. The second EL layer includes at least a light-emitting layer 2a, a second charge-generation layer, a light-emitting layer 2b, and an electron-transport layer 2b in this order from the second anode side. The electron-transport layer 2b is positioned between the light-emitting layer 2b and the second cathode. The electron-transport layer 1b contains at least a first heteroaromatic compound having a first heteroaromatic ring and a first organic compound different from the first heteroaromatic compound. The electron-transport layer 2b contains at least a second heteroaromatic compound having a second heteroaromatic ring and a second organic compound different from the second heteroaromatic compound. The edge portion of the light-emitting layer 1a and the edge portion of the electron-transport layer 1b are substantially aligned at a first edge portion when seen from a direction perpendicular to the insulating plane. The edge portion of the light-emitting layer 2a and the edge portion of the electron-transport layer 2b are substantially aligned at a second edge portion when seen from the direction perpendicular to the insulating plane. The distance between the first edge portion and the second edge portion facing each other is 2 μm to 5 μm

Another embodiment of the present invention is the light-emitting apparatus with the above structure, in which the electron-transport layer 1b contains the first heteroaromatic compound having the first heteroaromatic ring and the first organic compound different from the first heteroaromatic compound, and the electron-transport layer 2b contains the second heteroaromatic compound comprising the second heteroaromatic ring and the second organic compound different from the second heteroaromatic compound.

Another embodiment of the present invention is the light-emitting device with the above structure, in which the first heteroaromatic ring is the same as the second heteroaromatic ring.

Another embodiment of the present invention is the light-emitting apparatus with the above structure, in which the first heteroaromatic compound is the same as the second heteroaromatic compound.

Another embodiment of the present invention is the light-emitting apparatus with the above structure, in which the first organic compound is the same as the second organic compound.

Another embodiment of the present invention is the light-emitting device with the above structure, in which the first organic compound is an organic compound having a heteroaromatic ring.

Another embodiment of the present invention is the light-emitting apparatus with the above structure, in which the first organic compound is an organic compound having a heteroaromatic ring that is the same as the first heteroaromatic ring.

Another embodiment of the present invention is the light-emitting device with the above structure, in which the second organic compound is an organic compound having a heteroaromatic ring.

Another embodiment of the present invention is the light-emitting apparatus with the above structure, in which the second organic compound is an organic compound having a heteroaromatic ring that is the same as the second heteroaromatic ring.

Another embodiment of the present invention is the light-emitting apparatus with the above structure, in which the first heteroaromatic compound and the first organic compound are each contained in the first electron-transport layer at 10 weight % or more, and the second heteroaromatic compound and the second organic compound are each contained in the second electron-transport layer at 10 weight % or more.

Another embodiment of the present invention is the light-emitting apparatus with the above structure, in which the first heteroaromatic compound and the first organic compound are each contained in the electron-transport layer 1b at 10 weight % or more, and the second heteroaromatic compound and the second organic compound are each contained in the electron-transport layer 2b at 10 weight % or more.

Another embodiment of the present invention is the light-emitting apparatus with the above structure, in which one or both of the first organic compound and the second organic compound are heteroaromatic compounds each having two or more nitrogen atoms.

Another embodiment of the present invention is the light-emitting apparatus with the above structure, in which one or both of the first organic compound and the second organic compound have heteroaromatic rings comprising two or more nitrogen atoms.

Another embodiment of the present invention is the light-emitting apparatus with the above structure, in which one or both of the first heteroaromatic compound and the second heteroaromatic compound have two or more nitrogen atoms.

Another embodiment of the present invention is the light-emitting apparatus with the above structure, in which the first electron-transport layer and the second electron-transport layer, or the electron-transport layer 1b and the electron-transport layer 2b do not contain a metal complex.

Another embodiment of the present invention is the light-emitting apparatus with the above structure, in which the first electron-transport layer and the second electron-transport layer, or the electron-transport layer 1b and the electron-transport layer 2b do not contain alkali metal complex or an alkaline earth metal complex.

Another embodiment of the present invention is the light-emitting apparatus with the above structure, in which the first electron-transport layer and the second electron-transport layer do not contain alkali metal quinolinolato or alkaline earth metal quinolinolato.

Another embodiment of the present invention is the light-emitting apparatus with the above structure, in which one or both of the first heteroaromatic ring and the second heteroaromatic ring have two or more nitrogen atoms.

Another embodiment of the present invention is the light-emitting apparatus with the above structure, in which the electron-transport layer 1b and the electron-transport layer 2b do not contain lithium.

Another embodiment of the present invention is the light-emitting apparatus with the above structure, in which one or both of the first heteroaromatic ring and the second heteroaromatic ring are π-electron deficient heteroaromatic rings.

Another embodiment of the present invention is the light-emitting apparatus with the above structure, in which one or both of the first heteroaromatic ring and the second heteroaromatic ring are condensed heteroaromatic rings.

Another embodiment of the present invention is the light-emitting apparatus with the above structure, in which one or both of the first heteroaromatic compound and the second heteroaromatic compound are organic compounds comprising π-electron deficient heteroaromatic rings.

Another embodiment of the present invention is the light-emitting apparatus with the above structure, in which one or both of the first heteroaromatic ring and second heteroaromatic ring are any of a heteroaromatic ring comprising a polyazole skeleton, a heteroaromatic ring comprising a pyridine skeleton, a heteroaromatic ring comprising a diazine skeleton, and a heteroaromatic ring comprising a triazine skeleton.

Another embodiment of the present invention is the light-emitting apparatus with the above structure, in which the first EL layer includes an electron-transport layer 1a between the light-emitting layer 1a and the first intermediate layer, the second EL layer includes an electron-transport layer 2a between the light-emitting layer 2a and the second intermediate layer, the composition of the 1a-th electron-transport layer is different from that of the electron-transport layer 1b, and the composition of the 2a-th electron-transport layer is different from that of the electron-transport layer 2b.

Another embodiment of the present invention is the light-emitting apparatus with the above structure, in which the first EL layer includes the 1a-th electron-transport layer between the light-emitting layer 1a and the first intermediate layer, the second EL layer includes the 2a-th electron-transport layer between the light-emitting layer 2a and the second intermediate layer, the composition of the 1a-th electron-transport layer is the same as that of the electron-transport layer 1b, and the composition of the 2a-th electron-transport layer is the same as that of the electron-transport layer 2b.

Another embodiment of the present invention is the light-emitting apparatus with the above structure, in which one or both of the 1a-th electron-transport layer and the 2a-th electron-transport layer contain one kind of organic compound.

Another embodiment of the present invention is the light-emitting apparatus with the above structure, in which the first intermediate layer and the second intermediate layer are charge-generation layers.

Another embodiment of the present invention is the light-emitting apparatus with the above structure, in which the first EL layer includes a first electron-injection layer that is between the first electron-transport layer and the first cathode and in contact with the first cathode, the second EL layer includes a second electron-injection layer that is between the second electron-transport layer and the second cathode and in contact with the second cathode, and the first electron-injection layer and the second electron-injection layer are continuous in the first light-emitting device and the second light-emitting device.

Another embodiment of the present invention is the light-emitting apparatus with the above structure, in which the first cathode and the second cathode are continuous in the first light-emitting device and the second light-emitting device.

Another embodiment of the present invention is an electronic device including the light-emitting apparatus with any one of the above-described structures, a sensor, an operation button, and a speaker or a microphone.

Note that the light-emitting apparatus in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, or a module in which an IC (integrated circuit) is directly mounted on a light-emitting device by a COG (Chip On Glass) method. Furthermore, a lighting device or the like may include the light-emitting apparatus.

### Effect of the Invention

In view of the above, a light-emitting device with a higher resolution and favorable characteristics manufactured by a photolithography method can be provided in one embodiment of the present invention.

Note that the description of these effects does not preclude the existence of other effects. One embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A to FIG. 1D are diagrams illustrating light-emitting devices.

FIG. 2A to FIG. 2H are diagrams illustrating a manufacturing method of a light-emitting device.

FIG. 3A to FIG. 3G are diagrams illustrating a manufacturing method of a light-emitting device.

FIG. 4A to FIG. 4H are diagrams illustrating a manufacturing method of a light-emitting device.

FIG. 5A to FIG. 5D are diagrams illustrating a structure example of a display device.

FIG. 6A to FIG. 6F are diagrams illustrating a manufacturing method example of a display device.

FIG. 7A to FIG. 7F are diagrams illustrating a manufacturing method example of a display device.

FIG. 8 is a perspective view illustrating an example of a display device.

FIG. 9A and FIG. 9B are cross-sectional views illustrating an example of a display device.

FIG. 10A is a cross-sectional view illustrating an example of a display device. FIG. 10B is a cross-sectional view illustrating an example of a transistor.

FIG. 11A and FIG. 11B are perspective views illustrating an example of a display module.

FIG. 12 is a cross-sectional view illustrating an example of a display device.

FIG. 13 is a cross-sectional view illustrating an example of a display device.

FIG. 14 is a cross-sectional view illustrating an example of a display device.

FIG. 15A and FIG. 15B are diagrams illustrating a structure example of a display device.

FIG. 16A and FIG. 16B are diagrams illustrating an example of an electronic device.

FIG. 17A to FIG. 17D are diagrams illustrating examples of electronic devices.

FIG. 18A to FIG. 18F are diagrams illustrating examples of electronic devices.

FIG. 19A to FIG. 19F are diagrams illustrating examples of electronic devices.

FIG. 20 show photographs according to an example.

FIG. 21 show photographs according to an example.

FIG. 22 is a diagram illustrating a structure of a light-emitting device according to an example.

FIG. 23 shows radiant luminance-current density characteristics of a light-emitting device 1 and a comparative light-emitting device 1.

FIG. 24 shows current efficiency-luminance characteristics of the light-emitting device 1 and the comparative light-emitting device 1.

FIG. 25 shows luminance-voltage characteristics of the light-emitting device 1 and the comparative light-emitting device 1.

FIG. 26 shows current-voltage characteristics of the light-emitting device 1 and the comparative light-emitting device 1.

FIG. 27 shows external quantum efficiency-luminance characteristics of the light-emitting device 1 and the comparative light-emitting device 1.

FIG. 28 shows emission spectra of the light-emitting device 1 and the comparative light-emitting device 1.

FIG. 29 are graphs showing reliabilities of the light-emitting device 1 and the comparative light-emitting device 1.

FIG. 30A to FIG. 30D are diagrams illustrating light-emitting devices.

FIG. 31A to FIG. 31H are diagrams illustrating a manufacturing method of a light-emitting device.

FIG. 32A to FIG. 32G are diagrams illustrating a manufacturing method of a light-emitting device.

FIG. 33A to FIG. 33H are diagrams illustrating a manufacturing method of a light-emitting device.

FIG. 34A and FIG. 34B are diagrams illustrating light-emitting devices.

### MODE FOR CARRYING OUT THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In this specification and the like, a device formed using a metal mask or an FMM (fine metal mask, high-resolution metal mask) is sometimes referred to as a device having an MM (metal mask) structure. In this specification and the like, a device formed without using a metal mask or an FMM may be referred to as a device having an MML (metal maskless) structure.

### Embodiment 1

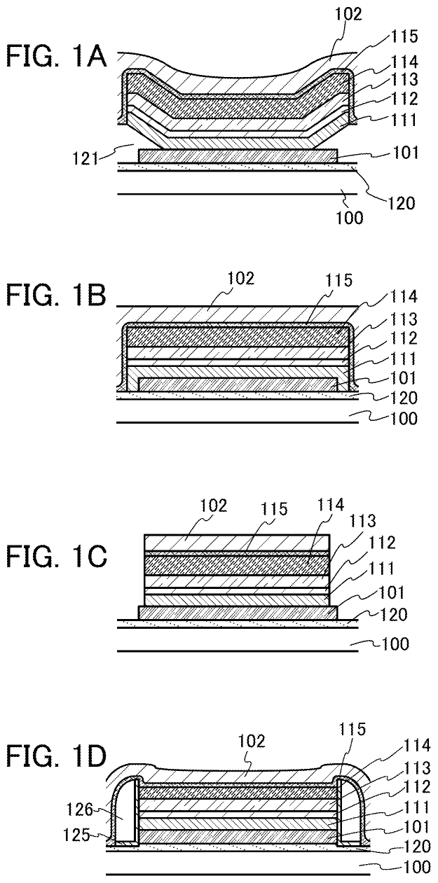

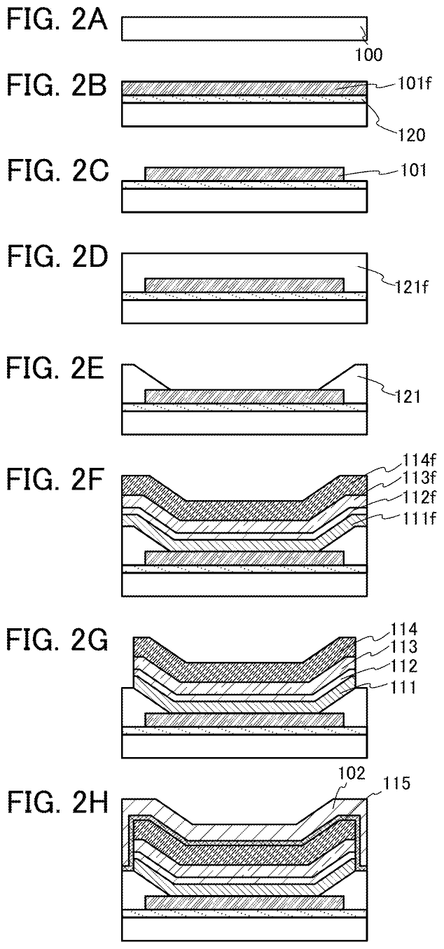

FIG. 1A to FIG. 1D are diagrams each illustrating a first light-emitting device in a light-emitting apparatus of one embodiment of the present invention. The light-emitting device is provided over a substrate 100 with an insulating layer 120 having an insulating plane therebetween and includes an anode 101, an EL layer (a first hole-injection layer 111, a first hole-transport layer 112, a first light-emitting layer 113, a first electron-transport layer 114, and a first electron-injection layer 115), and a cathode 102 in each of the examples illustrated in FIG. 1. Note that since these are examples, the components other than the first light-emitting layer 113 and the first electron-transport layer 114 are not necessarily provided, and a layer having a plurality of functions may be formed instead. As layers other than these layers, a carrier-blocking layer, an exciton-blocking layer, and the like can be given. A transistor, a capacitor, a wiring, and the like for driving the light-emitting device may be provided between the insulating layer 120 and the substrate 100.

In FIG. 1A, the edge portion of the anode 101 is covered with an insulating layer 121.

The first light-emitting device is manufactured though patterning and etching of organic layers by a photolithography method. Since patterning and etching are performed at a time that is after formation of the first electron-transport layer 114 and before formation of the electron-injection layer 115, the edge portions of the first hole-injection layer 111, the first hole-transport layer 112, the first light-emitting layer 113, and the first electron-transport layer 114 are substantially aligned. This means that the edge portions are substantially aligned even when seen from the direction perpendicular to the substrate or the insulating plane of the insulating layer 120 formed thereover. In addition, since the electron-injection layer 115 and the cathode 102 are formed later, they cover the edge portions of the first hole-injection layer 111, the first hole-transport layer 112, the first light-emitting layer 113, and the first electron-transport layer 114.

FIG. 1B illustrates a structure in which the insulating layer 120, which is formed in FIG. 1A, is not formed. Because of no existence of the insulating layer 120, a light-emitting apparatus with a higher resolution and a higher aperture ratio can be manufactured. FIG. 1C illustrates a structure of the case where patterning and etching are performed also after formation of the cathode 102 to separate the cathode 102 and the electron-injection layer 115 between light-emitting devices. Separation of light-emitting devices with this structure facilitates inhibition of generation of defects such as a short circuit and crosstalk. FIG. 1D illustrates a structure in which an insulating layer 125 and an insulating layer 126 are provided on the side surfaces of the organic layers. Owing to the insulating layer 125 and the insulating layer 126, this structure facilitates inhibition of generation of defects such as a short circuit and crosstalk and deterioration of the organic layers.

Here, the heat resistance of the first electron-transport layer 114 is important to the first light-emitting device in the light-emitting apparatus of one embodiment of the present invention because patterning and etching are performed after formation of the first electron-transport layer 114. In one embodiment of the present invention, the first electron-transport layer 114 contains at least a first heteroaromatic compound having a first heteroaromatic ring and a first organic compound different from the first heteroaromatic compound, whereby the heat resistance of the first electron-transport layer 114 is improved. Therefore, even when patterning by a photolithography method is performed at a proper temperature, proceeding of crystallization can be inhibited, so that a light-emitting apparatus with a high resolution and favorable characteristics can be obtained.

It is preferable that the first electron-transport layer 114 contain the first heteroaromatic compound having the first heteroaromatic ring, in which case the electron-transport property becomes favorable. In addition, it is preferable that the first organic compound also contain a heteroaromatic ring, in which case the electron-transport property becomes more favorable. Note that in the electron-transport layer, the heteroaromatic ring is often responsible for electron transport. For this reason, it is preferable that the heteroaromatic ring of the first organic compound be the same as the first heteroaromatic ring in order that the first organic compound would not inhibit electron transport in the electron-transport layer. Note that the structure in which the first electron-transport layer 114 contains the first heteroaromatic compound and the first organic compound is preferred to make it easier to manufacture the light-emitting device.

To obtain a significant effect of improving the heat resistance, it is preferable that the first heteroaromatic compound and the first organic compound be each contained in the first electron-transport layer 114 at 10% or more, further preferably 20 or more, still further preferably 30% or more.

Note that in the case where the first heteroaromatic ring included in the first heteroaromatic compound is a condensed heteroaromatic ring, a thermophysical property such as a glass transition temperature (Tg) is improved; however, there is a problem in that crystallization becomes likely to occur over time even at Tg or lower because an interaction between molecules is intense in a single film of the first heteroaromatic compound and thus a complete glass state is difficult to form. However, in one embodiment of the present invention, even when the first heteroaromatic ring is a condensed heteroaromatic ring, it is possible to inhibit the crystallization owing to the effect of the first organic compound. That is, a phenomenon of crystallization of the film at Tg or lower can be inhibited while the glass transition temperature is improved. Therefore, the first heteroaromatic ring is preferably a condensed heteroaromatic ring.

The first heteroaromatic ring is preferably a π-electron deficient heteroaromatic ring, and the first heteroaromatic compound is preferably, for example, any one or more of an organic compound including a heteroaromatic ring having a polyazole skeleton, an organic compound including a heteroaromatic ring having a diazine skeleton, and an organic compound including a heteroaromatic ring having a triazine skeleton.

Note that since patterning of the light-emitting devices is performed by a photolithography method, the distance between adjacent light-emitting devices can be narrowed in the light-emitting apparatus of one embodiment of the present invention. It is difficult to make the distance between EL layers of adjacent light-emitting devices less than 10 μm in a light-emitting apparatus manufactured with a metal mask, whereas the distance can be narrowed to 5 μm or less, 3 μm or less, 2 μm or less, or 1 μm or less in the light-emitting apparatus of one embodiment of the present invention. For example, with use of an exposure apparatus for LSI, the distance can be narrowed to be less than or equal to 500 nm, less than or equal to 200 nm, less than or equal to 100 nm, or less than or equal to 50 nm. Accordingly, the area of a non-light-emitting region that can exist between two adjacent light-emitting devices can be significantly reduced. For example, it is possible to achieve an aperture ratio 50% or more, 60% or more, 70% or more, 80% or more, or 90% more.

A second light-emitting device adjacent to the first light-emitting device has a structure similar to or the same as that of the first light-emitting device.

The second light-emitting device is also manufactured through patterning and etching of organic layers by a photolithography method, and thus the edge portions of the hole-injection layer, the hole-transport layer, the light-emitting layer, and the electron-transport layer are substantially aligned.

The electron-transport layer of the second light-emitting device contains a second heteroaromatic compound having a second heteroaromatic ring and a second organic compound different from the second heteroaromatic compound, whereby the heat resistance of the electron-transport layer is also improved. Therefore, even when patterning by a photolithography method is performed at a proper temperature, proceeding of crystallization can be inhibited, so that a light-emitting apparatus with a high resolution and favorable characteristics can be obtained.

The second electron-transport layer has a favorable electron-transport property by containing the second heteroaromatic compound having the second heteroaromatic ring. It is preferable that the second organic compound also contain a heteroaromatic ring, in which case the electron-transport property becomes more favorable. Note that in the electron-transport layer, the heteroaromatic ring is often responsible for electron transport. For this reason, it is preferable that the heteroaromatic ring of the second organic compound be the same as the second heteroaromatic ring in order that the second organic compound would not inhibit electron transport in the electron-transport layer. The structure in which the second electron-transport layer contains the second heteroaromatic compound and the second organic compound is preferred to make it easier to manufacture the light-emitting device.

To obtain a significant effect of improving the heat resistance, it is preferable that the second heteroaromatic compound and the second organic compound be each contained in the second electron-transport layer at 10% or more, further preferably 20 or more, still further preferably 30% or more.

Note that in the case where the second heteroaromatic ring included in the second heteroaromatic compound is a condensed heteroaromatic ring, a thermophysical property such as a glass transition temperature (Tg) is improved; however, there is a problem in that crystallization becomes likely to occur over time even at Tg or lower because an interaction between molecules is intense in a single film of the second heteroaromatic compound and thus a complete glass state is difficult to form. However, in one embodiment of the present invention, even when the second heteroaromatic ring is a condensed heteroaromatic ring, it is possible to inhibit the crystallization owing to the effect of the second organic compound. That is, a phenomenon of crystallization of the film at Tg or lower can be inhibited while the glass transition temperature is improved. Therefore, the second heteroaromatic ring is preferably a condensed heteroaromatic ring.

The second heteroaromatic ring is preferably a π-electron deficient heteroaromatic ring, and the second heteroaromatic compound is preferably, for example, any one or more of an organic compound including a heteroaromatic ring having a polyazole skeleton, an organic compound including a heteroaromatic ring having a diazine skeleton, and an organic compound including a heteroaromatic ring having a triazine skeleton.

Here, in order to make the electron-injection and electron-transport properties of the first light-emitting device and those of the second light-emitting device close to each other, it is preferable that the first heteroaromatic ring be the same as the second heteroaromatic ring. In addition, when the same materials are used in the first light-emitting device and the second light-emitting device, the material costs can be reduced owing to an effect of mass production. Accordingly, it is preferable that the first heteroaromatic compound be the same as the second heteroaromatic compound. Furthermore, it is preferable that the first organic compound be the same as the second organic compound.

The first heteroaromatic compound and the first organic compound may be the same as the second heteroaromatic compound and the second organic compound, respectively, and only their the mixing ratios may be different from each other. Note that the composition of the first electron-transport layer may be the same as or different from that of the second electron-transport layer, the composition of the first light-emitting layer may be the same as or different from that of the second light-emitting layer, and the composition of another component of the first light-emitting device may be the same as or different from that of the corresponding component of the second light-emitting device. Note that it is preferable that a metal complex be not contained in the electron-transport layer in the light-emitting device in the light-emitting apparatus of one embodiment of the present invention. As the metal complex, an alkaline earth metal complex and an alkali metal complex, in particular, alkali metal quinolinolato and alkaline earth metal quinolinolato can be given.

Next, manufacturing methods of these light-emitting devices are described. The light-emitting device illustrated in FIG. 1A can be manufactured as illustrated in FIG. 2A to FIG. 2H.

First, the insulating layer 120 having an insulating plane and a conductive film 101f to be the anode 101 are formed over the substrate 100 (FIG. 2A and FIG. 2B).

Next, the conductive film 101f is subjected to patterning and etching to form the anode 101 (FIG. 2C). An insulating film 121f to be the insulating layer 121 is deposited to cover the anode 101 (FIG. 2D). An opening is formed in the insulating film 121f, whereby the insulating layer 121 is formed (FIG. 2E).

After that, organic layers 111f, 112f, 113f, and 114f to be the hole-injection layer 111, the hole-transport layer 112, the light-emitting layer 113, and the electron-transport layer 114 are formed by an evaporation method (FIG. 2F). The organic layer 114f is a layer containing at least the first heteroaromatic compound having the first heteroaromatic ring and the first organic compound different from the first heteroaromatic compound as described above.

Next, the organic layers 111f, 112f, 113f, and 114f are subjected to patterning and etching by a photolithography method to form the hole-injection layer 111, the hole-transport layer 112, the light-emitting layer 113, and the electron-transport layer 114 (FIG. 2G). At this time, although heating is performed for curing a photoresist mask, a high-resolution light-emitting apparatus can be obtained because the electron-transport layer 114 is a layer containing at least the first heteroaromatic compound having the first heteroaromatic ring and the first organic compound different from the first heteroaromatic compound as described above and has favorable heat resistance, and it is possible to perform the heating at a temperature allowing a photomask to be cured certainly. Moreover, the light-emitting apparatus can have high reliability.

Note that a protective layer or a sacrificial layer for reducing damage due to a solvent or the like may be formed over the organic layer 114f before application of a photoresist. Thus, damage to the electron-transport layer 114 is reduced, which makes it easier to achieve more favorable characteristics of the light-emitting apparatus.

Finally, the electron-injection layer 115 and the cathode 102 are formed, whereby the light-emitting device illustrated in FIG. 1A can be manufactured (FIG. 2H).

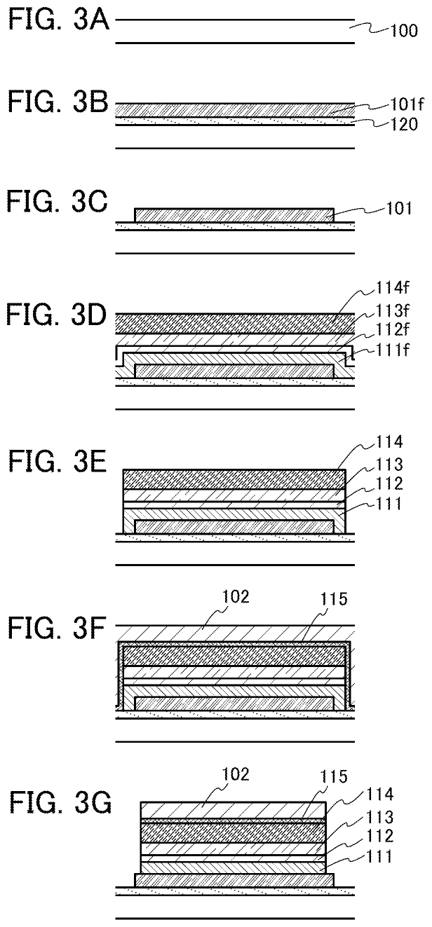

Next, a manufacturing method of the light-emitting device illustrated in FIG. 1B is described with reference to FIG. 3A to FIG. 3F. First, up to formation of the anode 101, the components are formed in the same manner as that for FIG. 2A to FIG. 2C (FIG. 3A to FIG. 3C).

Next, the organic layers 111f, 112f, 113f, and 114f to be the hole-injection layer 111, the hole-transport layer 112, the light-emitting layer 113, and the electron-transport layer 114 are formed by an evaporation method (FIG. 3D). The organic layer 114f is a layer containing at least the first heteroaromatic compound having the first heteroaromatic ring and the first organic compound different from the first heteroaromatic compound as described above.

Subsequently, the organic layers 111f, 112f, 113f, and 114f are subjected to patterning and etching by a photolithography method to form the hole-injection layer 111, the hole-transport layer 112, the light-emitting layer 113, and the electron-transport layer 114 (FIG. 3E). At this time, although heating is performed for curing a photoresist mask, a high-resolution light-emitting apparatus can be obtained because the electron-transport layer 114 is a layer containing at least the first heteroaromatic compound having the first heteroaromatic ring and the first organic compound different from the first heteroaromatic compound as described above and has favorable heat resistance, and it is possible to perform the heating at a temperature allowing a photomask to be cured certainly. Moreover, the light-emitting apparatus can have high reliability.

Note that a protective layer or a sacrificial layer for reducing damage due to a solvent or the like may be formed over the organic layer 114f before application of a photoresist. Thus, damage to the electron-transport layer 114 is reduced, which makes it easier to achieve more favorable characteristics of the light-emitting apparatus.

Finally, the electron-injection layer 115 and the cathode 102 are formed, whereby the light-emitting device illustrated in FIG. 1B can be manufactured (FIG. 3F). Note that by further performing patterning and etching by a photolithography method after that, it is possible to form the light-emitting device having a shape illustrated in FIG. 3G (FIG. 1C).

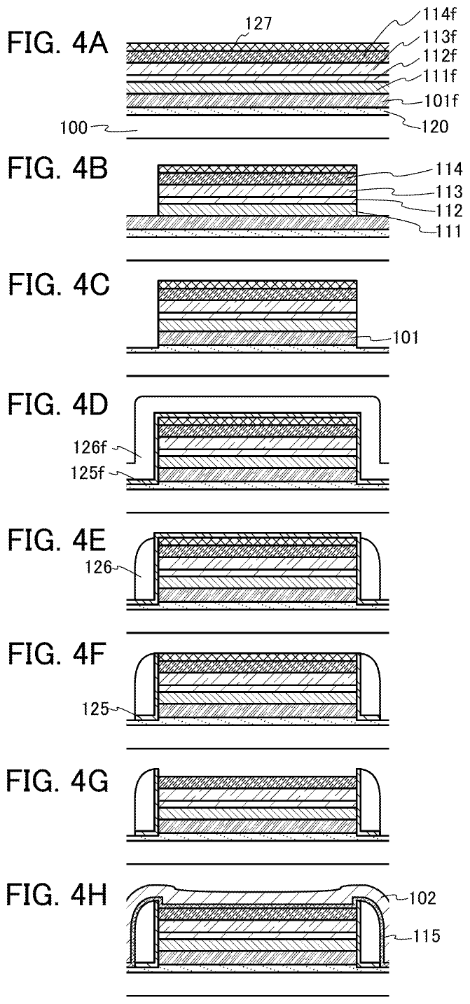

Next, a manufacturing method of the light-emitting device illustrated in FIG. 1D is described with reference to FIG. 4A to FIG. 4H.

First, the insulating layer 120 having an insulating plane, the conductive film 101f to be the anode 101, the organic layers 11 if, 112f, 113f, and 114f to be the hole-injection layer 111, the hole-transport layer 112, the light-emitting layer 113, and the electron-transport layer 114, and a sacrificial layer 127 are formed over the substrate 100 (FIG. 4A). The organic layer 114f is a layer containing at least the first heteroaromatic compound having the first heteroaromatic ring and the first organic compound different from the first heteroaromatic compound as described above.

Next, the organic layers 1l1f, 112f, 113f, and 114f and the sacrificial layer 127 are subjected to patterning and etching by a photolithography method to form the hole-injection layer 111, the hole-transport layer 112, the light-emitting layer 113, and the electron-transport layer 114 (FIG. 4B). At this time, although heating is performed for curing a photoresist mask, a high-resolution light-emitting apparatus can be obtained because the electron-transport layer 114 is a layer containing at least the first heteroaromatic compound having the first heteroaromatic ring and the first organic compound different from the first heteroaromatic compound as described above and has favorable heat resistance, and it is possible to perform the heating at a temperature allowing a photomask to be cured certainly. Moreover, the light-emitting apparatus can have high reliability.

After that, the conductive film 101f is subjected to patterning and etching by a photolithography method and the like to form the anode 101 (FIG. 4C). Note that a mask for etching the anode 101 may be a mask formed for etching the organic layer.

Next, an insulating film 125f and an insulating film 126f to be the insulating layer 125 and the insulating layer 126 are deposited. The insulating film 125f and the insulating film 126f are preferably inorganic insulating films.

After that, anisotropic etching is performed to remove the insulating film 126f so that only the insulating film 126f existing on the side surface portions of the organic layers is left; thus, the insulating layer 126 is formed (FIG. 4E).

Subsequently, the exposed insulating film 125f is removed to form the insulating layer 125 (FIG. 4F), and then the exposed sacrificial layer 127 is removed to expose the electron-transport layer 114 (FIG. 4G).

Finally, the electron-injection layer 115 and the cathode 102 are formed, whereby the light-emitting device illustrated in FIG. 1D can be manufactured (FIG. 4H).

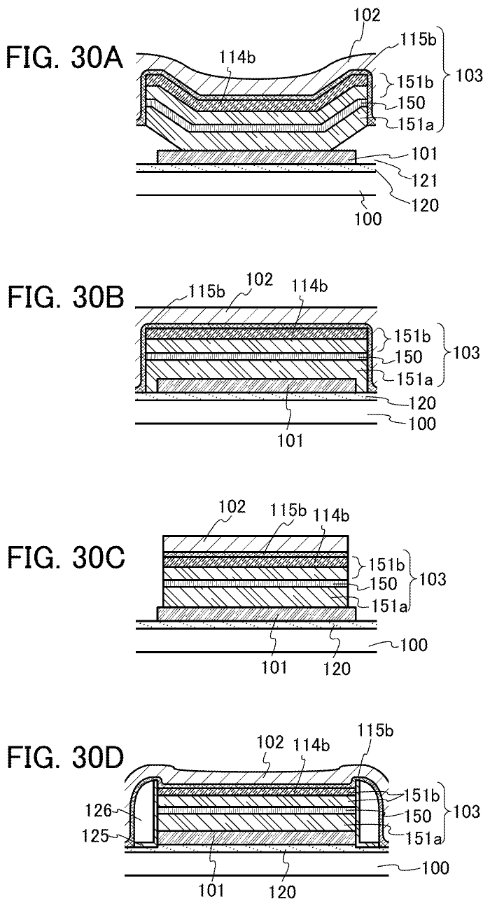

Next, FIG. 30A to FIG. 30D each illustrate a tandem light-emitting device that is another structure of the first light-emitting device in the light-emitting apparatus of one embodiment of the present invention. Note that description on components similar to those of the light-emitting devices illustrated in FIG. 1A to FIG. 1D are omitted in some cases.

The light-emitting device is a light-emitting device having a tandem structure that is provided over the substrate 100 with an insulating layer 120 having an insulating plane therebetween and includes the anode 101, an EL layer (a light-emitting unit A 151a, an intermediate layer 150, and a light-emitting unit B 151b), and the cathode 102 in FIG. 1. The light-emitting unit A 151a includes at least a light-emitting layer A 113a, and the light-emitting unit B 151b includes at least a light-emitting layer B 113b and an electron-transport layer B 114b. A transistor, a capacitor, a wiring, and the like for driving the light-emitting device may be provided between the insulating layer 120 and the substrate 100.

In FIG. 30A, the edge portion of the anode 101 is covered with the insulating layer 121.

The light-emitting device is manufactured though patterning and etching of organic layers by a photolithography method. Since patterning and etching are performed at a time that is after formation of the electron-transport layer B 114b in the light-emitting unit B 151b and before formation of an electron-injection layer B 115b, the edge portions of the light-emitting unit A 151a, the intermediate layer 150, and the first light-emitting unit B 151b are substantially aligned. Needless to say, the edge portions of a plurality of organic layers included in the light-emitting unit A 151a and the edge portions of a plurality of organic layers included in the light-emitting unit B 151b are substantially aligned, and the edge portion of the light-emitting layer A 113a of the light-emitting unit A 151a and the edge portion of the electron-transport layer B 114b included in the light-emitting unit B 151b are also substantially aligned. This means that these edge portions are substantially aligned even when seen from the direction perpendicular to the substrate or the insulating plane of the insulating layer 120 formed thereover. In addition, since the electron-injection layer B 115b of the light-emitting unit B and the cathode 102 are formed later, they cover the edge portions of the light-emitting unit A 151a, the intermediate layer 150, and the light-emitting unit B 151b.

FIG. 30B illustrates a structure in which the insulating layer 120, which is formed in FIG. 30A, is not formed. Because of no existence of the insulating layer 120, a light-emitting apparatus with a higher resolution and a higher aperture ratio can be manufactured. FIG. 30C illustrates a structure of the case where patterning and etching are performed also after formation of the cathode 102 to separate the cathode 102 and an electron-transport layer 115 between light-emitting devices. Separation of light-emitting devices with this structure facilitates inhibition of generation of defects such as a short circuit and crosstalk. FIG. 30D illustrates a structure in which the insulating layer 125 and the insulating layer 126 are provided on the side surface of the organic layers. Owing to the insulating layer 125 and the insulating layer 126, this structure facilitates inhibition of generation of defects such as a short circuit and crosstalk and deterioration of the organic layers.

Here, the heat resistance of the first electron-transport layer B 114b is important to the first light-emitting device in the light-emitting apparatus of one embodiment of the present invention because patterning and etching are performed after formation of the first electron-transport layer B 114b. In one embodiment of the present invention, the first electron-transport layer B 114b contains at least the first heteroaromatic compound having the first heteroaromatic ring and the first organic compound different from the first heteroaromatic compound, whereby the heat resistance of the first electron-transport layer B 114b is improved in the light-emitting device. Therefore, even when patterning by a photolithography method is performed at a proper temperature, proceeding of crystallization can be inhibited, so that a light-emitting apparatus with a high resolution and favorable characteristics can be obtained.

It is preferable that the first electron-transport layer B 114b contain the first heteroaromatic compound having the first heteroaromatic ring, in which case the electron-transport property becomes favorable. In addition, it is preferable that the first organic compound also contain a heteroaromatic ring, in which case the electron-transport property becomes more favorable. Note that in the electron-transport layer, the heteroaromatic ring is often responsible for electron transport. For this reason, it is preferable that the heteroaromatic ring of the first organic compound be the same as the first heteroaromatic ring in order that the first organic compound would not inhibit electron transport in the electron-transport layer. Note that the structure in which the first electron-transport layer B 114b contains the first heteroaromatic compound and the first organic compound is preferred to make it easier to manufacture the light-emitting device.

To obtain a significant effect of improving the heat resistance, it is preferable that the first heteroaromatic compound and the first organic compound be each contained in the first electron-transport layer B 114b at 10% or more, further preferably 20 or more, still further preferably 30% or more.

Note that in the case where the first heteroaromatic ring included in the first heteroaromatic compound is a condensed heteroaromatic ring, a thermophysical property such as a glass transition temperature (Tg) is improved; however, there is a problem in that crystallization becomes likely to occur over time even at Tg or lower because an interaction between molecules is intense in a single film of the first heteroaromatic compound and thus a complete glass state is difficult to form. However, in one embodiment of the present invention, even when the first heteroaromatic ring is a condensed heteroaromatic ring, it is possible to inhibit the crystallization owing to the effect of the first organic compound. That is, a phenomenon of crystallization of the film at Tg or lower can be inhibited while the glass transition temperature is improved. Therefore, the first heteroaromatic ring is preferably a condensed heteroaromatic ring.

The first heteroaromatic ring is preferably a π-electron deficient heteroaromatic ring, and the first heteroaromatic compound is preferably, for example, any one or more of an organic compound including a heteroaromatic ring having a polyazole skeleton, an organic compound including a heteroaromatic ring having a diazine skeleton, and an organic compound including a heteroaromatic ring having a triazine skeleton.

Note that since patterning of the light-emitting devices is performed by a photolithography method, the distance between adjacent light-emitting devices can be narrowed in the light-emitting apparatus of one embodiment of the present invention. It is difficult to make the distance between EL layers of adjacent light-emitting devices less than 10 μm in a light-emitting apparatus manufactured with a metal mask, whereas the distance can be narrowed to 5 μm or less, 3 μm or less, 2 μm or less, or 1 μm or less in the light-emitting apparatus of one embodiment of the present invention. For example, with use of an exposure apparatus for LSI, the distance can be narrowed to be less than or equal to 500 nm, less than or equal to 200 nm, less than or equal to 100 nm, or less than or equal to 50 nm. Accordingly, the area of a non-light-emitting region that can exist between two adjacent light-emitting devices can be significantly reduced. For example, it is possible to achieve an aperture ratio 50% or more, 60% or more, 70% or more, 80% or more, or 90% more.

A second light-emitting device adjacent to the first light-emitting device has a structure similar to or the same as that of the first light-emitting device. The first light-emitting device is a light-emitting device having a tandem structure in which at least a second anode, a second EL layer (a second light-emitting unit A, a second intermediate layer, and a second light-emitting unit B) and the cathode 102 are stacked in this order. Note that the second light-emitting unit A includes at least a second light-emitting layer A, and the second light-emitting unit B includes at least a second light-emitting layer B and a second electron-transport layer B. The second electron-transport layer B is positioned between the second light-emitting layer B and the cathode.

The second light-emitting device is also manufactured through patterning and etching of the organic layers by a photolithography method, and thus the edge portions of the second light-emitting unit A, the second intermediate layer, and the second light-emitting unit B are substantially aligned.

The second electron-transport layer B of the second light-emitting device contains a second heteroaromatic compound having a second heteroaromatic ring and a second organic compound different from the second heteroaromatic compound, whereby the heat resistance of the electron-transport layer is also improved. Therefore, even when patterning by a photolithography method is performed at a proper temperature, proceeding of crystallization can be inhibited, so that a light-emitting apparatus with a high resolution and favorable characteristics can be obtained.

The second electron-transport layer B has a favorable electron-transport property by containing the second heteroaromatic compound having the second heteroaromatic ring. It is preferable that the second organic compound also contain a heteroaromatic ring, in which case the electron-transport property becomes more favorable. Note that in the electron-transport layer, the heteroaromatic ring is often responsible for electron transport. For this reason, it is preferable that the heteroaromatic ring of the second organic compound be the same as the second heteroaromatic ring in order that the second organic compound would not inhibit electron transport in the electron-transport layer. The structure in which the second electron-transport layer B contains the second heteroaromatic compound and the second organic compound is preferred to make it easier to manufacture the light-emitting device.

To obtain a significant effect of improving the heat resistance, it is preferable that the second heteroaromatic compound and the second organic compound be each contained in the second electron-transport layer B at 10% or more, further preferably 20 or more, still further preferably 30% or more.

Note that in the case where the second heteroaromatic ring included in the second heteroaromatic compound is a condensed heteroaromatic ring, a thermophysical property such as a glass transition temperature (Tg) is improved; however, there is a problem in that crystallization becomes likely to occur over time even at Tg or lower because an interaction between molecules is intense in a single film of the second heteroaromatic compound and thus a complete glass state is difficult to form. However, in one embodiment of the present invention, even when the second heteroaromatic ring is a condensed heteroaromatic ring, it is possible to inhibit the crystallization owing to the effect of the second organic compound. That is, a phenomenon of crystallization of the film at Tg or lower can be inhibited while the glass transition temperature is improved. Therefore, the second heteroaromatic ring is preferably a condensed heteroaromatic ring.

The second heteroaromatic ring is preferably a π-electron deficient heteroaromatic ring, and the second heteroaromatic compound is preferably, for example, any one or more of an organic compound including a heteroaromatic ring having a polyazole skeleton, an organic compound including a heteroaromatic ring having a diazine skeleton, and an organic compound including a heteroaromatic ring having a triazine skeleton.

Here, in order to make the electron-injection and electron-transport properties of the first light-emitting device and those of the second light-emitting device close to each other, it is preferable that the first heteroaromatic ring be the same as the second heteroaromatic ring. In addition, when the same materials are used in the first light-emitting device and the second light-emitting device, the material costs can be reduced owing to an effect of mass production. Accordingly, it is preferable that the first heteroaromatic compound be the same as the second heteroaromatic compound. Furthermore, it is preferable that the first organic compound be the same as the second organic compound.

The first heteroaromatic compound and the first organic compound may be the same as the second heteroaromatic compound and the second organic compound, respectively, and only their the mixing ratios may be different from each other.

Note that the composition of the first electron-transport layer B may be the same as or different from that of the second electron-transport layer B, the composition of the first light-emitting layer A may be the same as or different from that of the second light-emitting layer A, the composition of the first light-emitting layer B may be the same as or different from that of the second light-emitting layer B, and the composition of another component of the first light-emitting device may be the same as or different from that of the corresponding component of the second light-emitting device.

Note that it is preferable that a metal complex be not contained in the electron-transport layer in the light-emitting device in the light-emitting apparatus of one embodiment of the present invention. As the metal complex, an alkaline earth metal complex and an alkali metal complex, in particular, alkali metal quinolinolato and alkaline earth metal quinolinolato can be given.

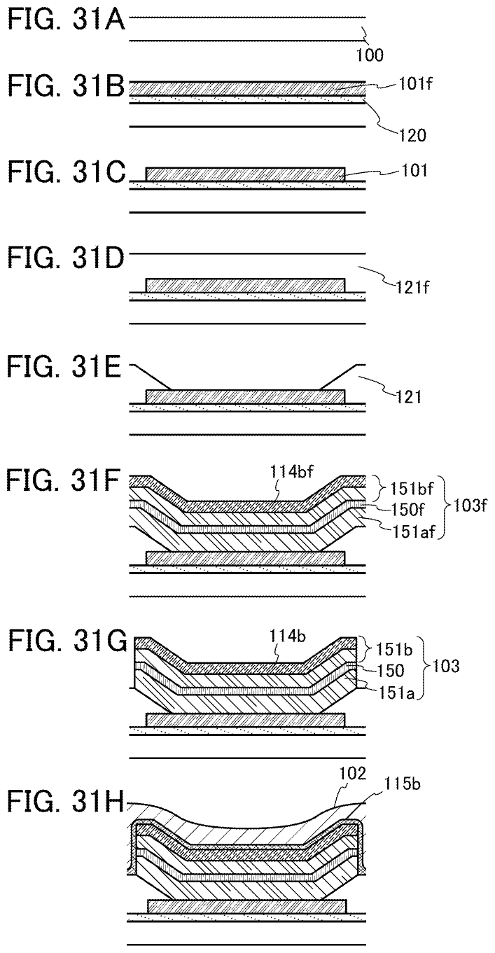

Next, manufacturing methods of these light-emitting devices are described. The light-emitting device illustrated in FIG. 30A can be manufactured as illustrated in FIG. 31A to FIG. 31H.

Here, the heat resistance of the first electron-transport layer B 114b is important to the first light-emitting device in the light-emitting apparatus of one embodiment of the present invention because patterning and etching are performed after formation of the first electron-transport layer B 114b. In one embodiment of the present invention, the first electron-transport layer B 114b contains at least the first heteroaromatic compound having the first heteroaromatic ring and the first organic compound different from the first heteroaromatic compound, whereby the heat resistance of the first electron-transport layer B 114b is improved. Therefore, even when patterning by a photolithography method is performed at a proper temperature, proceeding of crystallization can be inhibited, so that a light-emitting apparatus with a high resolution and favorable characteristics can be obtained.

It is preferable that the first electron-transport layer B 114b contain the first heteroaromatic compound having the first heteroaromatic ring, in which case the electron-transport property becomes favorable. In addition, it is preferable that the first organic compound also contain a heteroaromatic ring, in which case the electron-transport property becomes more favorable. Note that in the electron-transport layer, the heteroaromatic ring is often responsible for electron transport. For this reason, it is preferable that the heteroaromatic ring of the first organic compound be the same as the first heteroaromatic ring in order that the first organic compound would not inhibit electron transport in the electron-transport layer. Note that the structure in which the first electron-transport layer B 114b contains the first heteroaromatic compound and the first organic compound is preferred to make it easier to manufacture the light-emitting device.

To obtain a significant effect of improving the heat resistance, it is preferable that the first heteroaromatic compound and the first organic compound be each contained in the first electron-transport layer B 114b at 10% or more, further preferably 20 or more, still further preferably 30% or more.

Note that in the case where the first heteroaromatic ring included in the first heteroaromatic compound is a condensed heteroaromatic ring, a thermophysical property such as a glass transition temperature (Tg) is improved; however, there is a problem in that crystallization becomes likely to occur over time even at Tg or lower because an interaction between molecules is intense in a single film of the first heteroaromatic compound and thus a complete glass state is difficult to form. However, in one embodiment of the present invention, even when the first heteroaromatic ring is a condensed heteroaromatic ring, it is possible to inhibit the crystallization owing to the effect of the first organic compound. That is, a phenomenon of crystallization of the film at Tg or lower can be inhibited while the glass transition temperature is improved. Therefore, the first heteroaromatic ring is preferably a condensed heteroaromatic ring.

The first heteroaromatic ring is preferably a π-electron deficient heteroaromatic ring, and the first heteroaromatic compound is preferably, for example, any one or more of an organic compound including a heteroaromatic ring having a polyazole skeleton, an organic compound including a heteroaromatic ring having a diazine skeleton, and an organic compound including a heteroaromatic ring having a triazine skeleton.

Note that since patterning of the light-emitting devices is performed by a photolithography method, the distance between adjacent light-emitting devices can be narrowed in the light-emitting apparatus of one embodiment of the present invention. It is difficult to make the distance between EL layers of adjacent light-emitting devices less than 10 μm in a light-emitting apparatus manufactured with a metal mask, whereas the distance can be narrowed to 5 μm or less, 3 μm or less, 2 μm or less, or 1 μm or less in the light-emitting apparatus of one embodiment of the present invention. For example, with use of an exposure apparatus for LSI, the distance can be narrowed to be less than or equal to 500 nm, less than or equal to 200 nm, less than or equal to 100 nm, or less than or equal to 50 nm. Accordingly, the area of a non-light-emitting region that can exist between two adjacent light-emitting devices can be significantly reduced. For example, it is possible to achieve an aperture ratio 50% or more, 60% or more, 70% or more, 80% or more, or 90% more.

A second light-emitting device adjacent to the first light-emitting device has a structure similar to or the same as that of the first light-emitting device. The first light-emitting device is a light-emitting device having a tandem structure in which at least a second anode, a second EL layer (a second light-emitting unit A, a second intermediate layer, and a second light-emitting unit B) and the cathode 102 are stacked in this order. Note that the second light-emitting unit A includes at least a second light-emitting layer A, and the second light-emitting unit B includes at least a second light-emitting layer B and a second electron-transport layer B. A second electron-transport layer 2 is positioned between the second light-emitting layer B and the cathode.

The second light-emitting device is also manufactured through patterning and etching of the organic layers by a photolithography method, and thus the edge portions of the second light-emitting unit A, the second intermediate layer, and the second light-emitting unit B are substantially aligned.

The second electron-transport layer B of the second light-emitting device contains a second heteroaromatic compound having a second heteroaromatic ring and a second organic compound different from the second heteroaromatic compound, whereby the heat resistance of the electron-transport layer is also improved. Therefore, even when patterning by a photolithography method is performed at a proper temperature, proceeding of crystallization can be inhibited, so that a light-emitting apparatus with a high resolution and favorable characteristics can be obtained.

The second electron-transport layer B has a favorable electron-transport property by containing the second heteroaromatic compound having the second heteroaromatic ring. It is preferable that the second organic compound also contain a heteroaromatic ring, in which case the electron-transport property becomes more favorable. Note that in the electron-transport layer, the heteroaromatic ring is often responsible for electron transport. For this reason, it is preferable that the heteroaromatic ring of the second organic compound be the same as the second heteroaromatic ring in order that the second organic compound would not inhibit electron transport in the electron-transport layer. The structure in which the second electron-transport layer B contains the second heteroaromatic compound and the second organic compound is preferred to make it easier to manufacture the light-emitting device.

To obtain a significant effect of improving the heat resistance, it is preferable that the second heteroaromatic compound and the second organic compound be each contained in the second electron-transport layer B at 10% or more, further preferably 20 or more, still further preferably 30% or more.

Note that in the case where the second heteroaromatic ring included in the second heteroaromatic compound is a condensed heteroaromatic ring, a thermophysical property such as a glass transition temperature (Tg) is improved; however, there is a problem in that crystallization becomes likely to occur over time even at Tg or lower because an interaction between molecules is intense in a single film of the second heteroaromatic compound and thus a complete glass state is difficult to form. However, in one embodiment of the present invention, even when the second heteroaromatic ring is a condensed heteroaromatic ring, it is possible to inhibit the crystallization owing to the effect of the second organic compound. That is, a phenomenon of crystallization of the film at Tg or lower can be inhibited while the glass transition temperature is improved. Therefore, the second heteroaromatic ring is preferably a condensed heteroaromatic ring.

The second heteroaromatic ring is preferably a π-electron deficient heteroaromatic ring, and the second heteroaromatic compound is preferably, for example, any one or more of an organic compound including a heteroaromatic ring having a polyazole skeleton, an organic compound including a heteroaromatic ring having a diazine skeleton, and an organic compound including a heteroaromatic ring having a triazine skeleton.

Here, in order to make the electron-injection and electron-transport properties of the first light-emitting device and those of the second light-emitting device close to each other, it is preferable that the first heteroaromatic ring be the same as the second heteroaromatic ring. In addition, when the same materials are used in the first light-emitting device and the second light-emitting device, the material costs can be reduced owing to an effect of mass production. Accordingly, it is preferable that the first heteroaromatic compound be the same as the second heteroaromatic compound. Furthermore, it is preferable that the first organic compound be the same as the second organic compound.

The first heteroaromatic compound and the first organic compound may be the same as the second heteroaromatic compound and the second organic compound, respectively, and only their the mixing ratios may be different from each other.

Note that the composition of the first electron-transport layer B may be the same as or different from that of the second electron-transport layer B, the composition of the first light-emitting layer A may be the same as or different from that of the second light-emitting layer A, the composition of the first light-emitting layer B may be the same as or different from that of the second light-emitting layer B, and the composition of another component of the first light-emitting device may be the same as or different from that of the corresponding component of the second light-emitting device.

Note that it is preferable that a metal complex be not contained in the electron-transport layer in the light-emitting device in the light-emitting apparatus of one embodiment of the present invention. As the metal complex, an alkaline earth metal complex and an alkali metal complex, in particular, alkali metal quinolinolato and alkaline earth metal quinolinolato can be given.

Next, manufacturing methods of these light-emitting devices are described. The light-emitting device illustrated in FIG. 30A can be manufactured as illustrated in FIG. 31A to FIG. 31H.

First, the insulating layer 120 having an insulating plane and the conductive film 101f to be the anode 101 are formed over the substrate 100 (FIG. 31A and FIG. 31B).

Next, the conductive film 101f is subjected to patterning and etching to form the anode 101 (FIG. 31C). the insulating film 121f to be the insulating layer 121 is deposited to cover the anode 101 (FIG. 31D). An opening is formed in the insulating film 121f, whereby the insulating layer 121 is formed (FIG. 31E).

After that, organic layers 151af, 150f, and 151bf (including 144bf) to be the light-emitting unit A 151a, the intermediate layer 150, and the light-emitting unit B 151b (including the electron-transport layer B 114b) are formed by an evaporation method (FIG. 31F). An organic layer 114bf is a layer containing at least the first heteroaromatic compound having the first heteroaromatic ring and the first organic compound different from the first heteroaromatic compound as described above.

Subsequently, the organic layers 151af, 150f, and 151bf (including 144bf) are subjected to patterning and etching by a photolithography method to form the light-emitting unit A 151a, the intermediate layer 150, and the light-emitting unit B 151b (including the electron-transport layer B 114b) (FIG. 31G). At this time, although heating is performed for curing a photoresist mask, a high-resolution light-emitting apparatus can be obtained because the electron-transport layer B 114b is a layer containing at least the first heteroaromatic compound having the first heteroaromatic ring and the first organic compound different from the first heteroaromatic compound as described above and has favorable heat resistance, and it is possible to perform heating at a temperature allowing a photomask to be cured certainly. Moreover, the light-emitting apparatus can have high reliability.

Note that a protective layer or a sacrificial layer for reducing damage due to a solvent or the like may be formed over the organic layer 114bf before application of a photoresist. Thus, damage to the electron-transport layer B 114b is reduced, which makes it easier to achieve more favorable characteristics of the light-emitting apparatus.

Finally, the electron-injection layer B 115b and the cathode 102 are formed, whereby the light-emitting device illustrated in FIG. 30A can be manufactured (FIG. 31H).

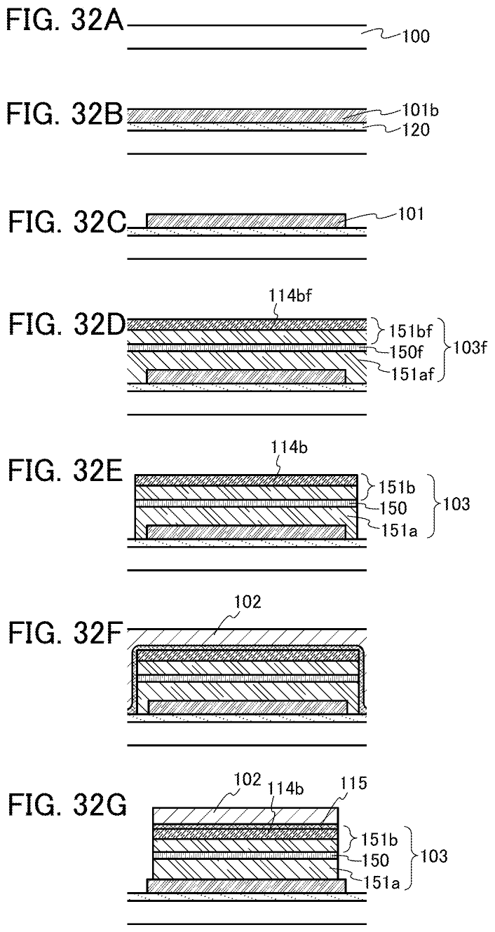

Next, a manufacturing method of the light-emitting device illustrated in FIG. 30B is described with reference to FIG. 32A to FIG. 32F. First, up to formation of the anode 101, the components are formed in the same manner as that for FIG. 31A to FIG. 31C (FIG. 32A to FIG. 32C).

Next, the organic layers 151af, 150f, and 151bf (including 144bf) to be the light-emitting unit A 151a, the intermediate layer 150, and the light-emitting unit B 151b (including the electron-transport layer B 114b) are formed by an evaporation method (FIG. 32D). The organic layer 114bf is a layer containing at least the first heteroaromatic compound having the first heteroaromatic ring and the first organic compound different from the first heteroaromatic compound as described above.

Subsequently, the organic layers 151af, 150f, and 151bf (including 144bf) are subjected to patterning and etching by a photolithography method to form the light-emitting unit A 151a, the intermediate layer 150, and the light-emitting unit B 151b (including the electron-transport layer B 114b) (FIG. 32E). At this time, although heating is performed for curing a photoresist mask, a high-resolution light-emitting apparatus can be obtained because the electron-transport layer B 114b is a layer containing at least the first heteroaromatic compound having the first heteroaromatic ring and the first organic compound different from the first heteroaromatic compound as described above and has favorable heat resistance, and it is possible to perform heating at a temperature allowing a photomask to be cured certainly. Moreover, the light-emitting apparatus can have high reliability.

Note that a protective layer or a sacrificial layer for reducing damage due to a solvent or the like may be formed over the organic layer 114bf before application of a photoresist. Thus, damage to the electron-transport layer B 114b is reduced, which makes it easier to achieve more favorable characteristics of the light-emitting apparatus.

Finally, the electron-injection layer B 115b and the cathode 102 are formed, whereby the light-emitting device illustrated in FIG. 1B can be manufactured (FIG. 32F). Note that by further performing patterning and etching by a photolithography method after that, it is possible to form the light-emitting device having a shape illustrated in FIG. 32G (FIG. 30C).

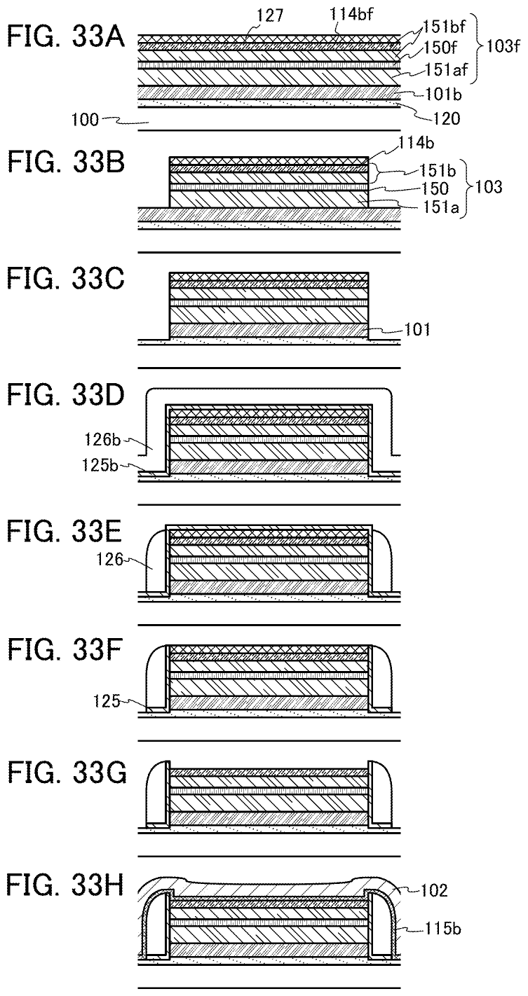

Next, a manufacturing method of the light-emitting device illustrated in FIG. 30D is described with reference to FIG. 33A to FIG. 33H.

First, the insulating layer 120 having an insulating plane, the conductive film 101f to be the anode 101, the organic layers 151af, 150f, and 151bf (including 144bf) to be the light-emitting unit A 151a, the intermediate layer 150, and the light-emitting unit B 151b (including the electron-transport layer B 114b), and the sacrificial layer 127 are formed over the substrate 100 (FIG. 33A). The organic layer 114bf is a layer containing at least the first heteroaromatic compound having the first heteroaromatic ring and the first organic compound different from the first heteroaromatic compound as described above.

Subsequently, the organic layers 151af, 150f, and 151bf (including 144bf) and the sacrificial layer 127 are subjected to patterning and etching by a photolithography method to form the light-emitting unit A 151a, the intermediate layer 150, the light-emitting unit B 151b (including the electron-transport layer B 114b), and the sacrificial layer 127 (FIG. 33B). At this time, although heating is performed for curing a photoresist mask, a high-resolution light-emitting apparatus can be obtained because the electron-transport layer B 114b is a layer containing at least the first heteroaromatic compound having the first heteroaromatic ring and the first organic compound different from the first heteroaromatic compound as described above and has favorable heat resistance, and it is possible to perform heating at a temperature allowing a photomask to be cured certainly. Moreover, the light-emitting apparatus can have high reliability.

After that, the conductive film 101f is subjected to patterning and etching by a photolithography method and the like to form the anode 101 (FIG. 33C). Note that a mask for etching the anode 101 may be a mask formed for etching the organic layer.

Next, the insulating film 125f and the insulating film 126f to be the insulating layer 125 and the insulating layer 126 are deposited. An insulating film 125b and an insulating film 126b are preferably inorganic insulating films.

After that, anisotropic etching is performed to remove the insulating film 126f so that only the insulating film 126f existing on the side surface portions of the organic layers is left; thus, the insulating layer 126 is formed (FIG. 33E).

Subsequently, the exposed insulating film 125f is removed to form the insulating layer 125 (FIG. 33F), and then the exposed sacrificial layer 127 is removed to expose the electron-transport layer B 114b (FIG. 33G).

Finally, the electron-injection layer B 115b and the cathode 102 are formed, whereby the light-emitting device illustrated in FIG. 30D can be manufactured (FIG. 33H).

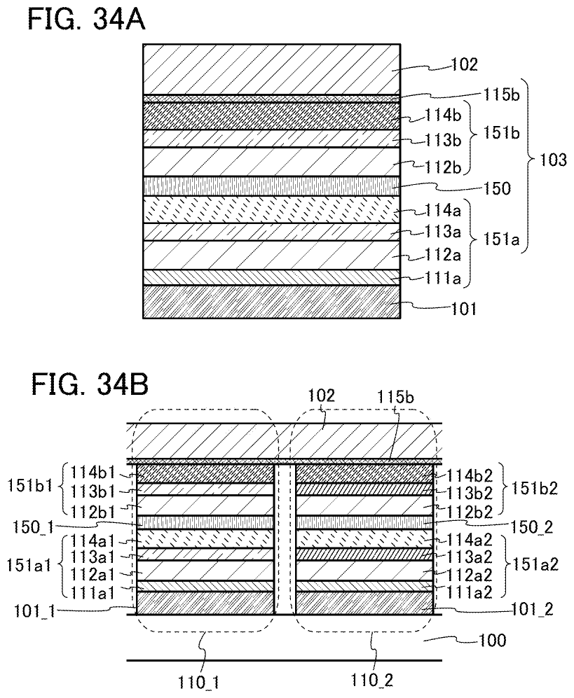

Subsequently, an element structure example of a tandem structure is described in detail with reference to FIG. 34A and FIG. 34B. As described above, the light-emitting device includes an EL layer 103 (the light-emitting unit A 151a, the intermediate layer 150, the light-emitting unit B 151b, and the electron-injection layer B 115b) between the anode 101 and the cathode 102. The light-emitting unit A 151a includes a hole-injection layer A 111a, a hole-transport layer A 112a, the light-emitting layer A 113a, and an electron-transport layer A 114a in this order from the anode 101 side, and the light-emitting unit B 151b includes a hole-transport layer B 112b, the light-emitting layer B 113b, and the electron-transport layer B 114b.

In the light-emitting device in the light-emitting apparatus of one embodiment of the present invention, patterning and etching are performed by a photolithography method after the electron-transport layer B 114b is formed, whereby the light-emitting unit A, the intermediate layer, and the light-emitting unit B are processed into a desired shape. At this time, since the electron-transport layer B 114b has improved heat resistance by containing the first heteroaromatic compound having the first heteroaromatic ring and the first organic compound different from the first heteroaromatic compound, the upper temperature limit in the heat treatment at time of forming a resist mask is raised; therefore, it is possible to perform higher-resolution patterning. Furthermore, the reliability of the light-emitting apparatus is also improved.

The composition of the electron-transport layer B 114b may be the same as or different from that of the electron-transport layer A 114a. When the electron-transport layer A 114a has the same composition as the electron-transport layer B 114b, it is possible to obtain a light-emitting device with higher heat resistance. Forming the electron-transport layer A 114a with one kind of organic compound is advantageous in view of the manufacturing cost.

FIG. 34B is a diagram schematically illustrating a first light-emitting device 110_1 and a second light-emitting device 110_2 adjacent to each other.

The first light-emitting device 1101 includes a first light-emitting unit A 151a1, a first intermediate layer 1501, a first light-emitting unit B 151b1, and the electron-injection layer B 115b (common layer) between a first anode 101_1 and the cathode 102 (common layer).

The first light-emitting unit A 151a1 includes a first hole-injection layer A 111a1, a first hole-transport layer A 112a1, a first light-emitting layer 113a1, and a first electron-transport layer A 114a1 in this order from the first anode 101_1 side, and the first light-emitting unit B 151b1 includes a first hole-transport layer B 112b1, a first light-emitting layer B 113b1, and a first electron-transport layer B 114b1.

In the light-emitting device of one embodiment of the present invention, patterning and etching by a photolithography method are performed after the first electron-transport layer B 114b1 is formed, whereby the first light-emitting unit A 151a1, the first intermediate layer 1501, and the first light-emitting unit B 151b1 are processed into a desired shape. Accordingly, the edge portions of the first light-emitting unit A 151a1, the first intermediate layer 150_1, and the first light-emitting unit B 151b1 are substantially aligned. Needless to say, the edge portions of the plurality of organic layers included in the first light-emitting unit A 151a1 and the edge portions of the plurality of organic layers included in the first light-emitting unit B 151b1 are substantially aligned, and the edge portion of the first light-emitting layer A 113a1 of the first light-emitting unit A 151a1 and the edge portion of the first electron-transport layer B 114b1 included in the first light-emitting unit B 151b1 are also substantially aligned. This means that these edge portions are substantially aligned even when seen from the direction perpendicular to the substrate or the insulating plane of the insulating layer 120 formed thereover.

Since the first electron-transport layer B 114b has improved heat resistance by containing the first heteroaromatic compound having the first heteroaromatic ring and the first organic compound different from the first heteroaromatic compound, the upper temperature limit in the heat treatment at time of forming a resist mask is raised; therefore, it is possible to perform higher-resolution patterning. Furthermore, the reliability of the light-emitting apparatus is also improved. Note that it is preferable that the first aromatic compound and the first organic compound be each contained in the first electron-transport layer B 114b1 at 10% or more, further preferably 20% or more, still further preferably 30% or more.

A second light-emitting unit A 151a2 includes a second hole-injection layer A 111a2, a second hole-injection layer A 112a2, a second light-emitting layer 113a2, and a second electron-transport layer A 114a2 in this order from a second anode 101_2 side, and a second light-emitting unit B 151b2 includes a second hole-transport layer B 112b2, a second light-emitting layer B 113b2, and a second electron-transport layer B 114b2.

In the light-emitting device of one embodiment of the present invention, patterning and etching by a photolithography method are performed after the second electron-transport layer B 114b1 is formed, whereby the second light-emitting unit A 151a2, a second intermediate layer 150_2, and the second light-emitting unit B 151b2 are processed into a desired shape. Accordingly, the edge portions of the second light-emitting unit A 151a2, the second intermediate layer 1502, and the second light-emitting unit B 151b2 are substantially aligned. Needless to say, the edge portions of the plurality of organic layers included in the second light-emitting unit A 151a2 and the edge portions of the plurality of organic layers included in the second light-emitting unit B 151b2 are substantially aligned, and the edge portion of the second light-emitting layer A 113a2 of the second light-emitting unit A 151a2 and the edge portion of the second electron-transport layer B 114b2 included in the second light-emitting unit B 151b2 are also substantially aligned. This means that these edge portions are substantially aligned even when seen from the direction perpendicular to the substrate or the insulating plane of the insulating layer 120 formed thereover.

Since the second electron-transport layer B 114b has improved heat resistance by containing the second heteroaromatic compound having the second heteroaromatic ring and the second heteroaromatic compound different from the second heteroaromatic compound, the upper temperature limit in the heat treatment at time of forming a resist mask is raised; therefore, it is possible to perform higher-resolution patterning. Furthermore, the reliability of the light-emitting apparatus is also improved. Note that it is preferable that the second aromatic compound and the second organic compound be each contained in the second electron-transport layer B 114b2 at 10% or more, further preferably 20% or more, still further preferably 30% or more.

Here, it is preferable that the first heteroaromatic ring of the first heteroaromatic compound contained in the first electron-transport layer B 114b1 be the same as the second heteroaromatic ring of the second heteroaromatic compound contained in the second electron-transport layer B 114b2, and it is further preferable that the first heteroaromatic compound be the same as the second heteroaromatic compound.

Furthermore, here, it is preferable that the first organic compound contained in the first electron-transport layer B 114b1 be the same as the second organic compound contained in the second electron-transport layer B 114b2.

### [Light-Emitting Apparatus]

An example of the light-emitting apparatus of one embodiment of the present invention using the above light-emitting device is described below.

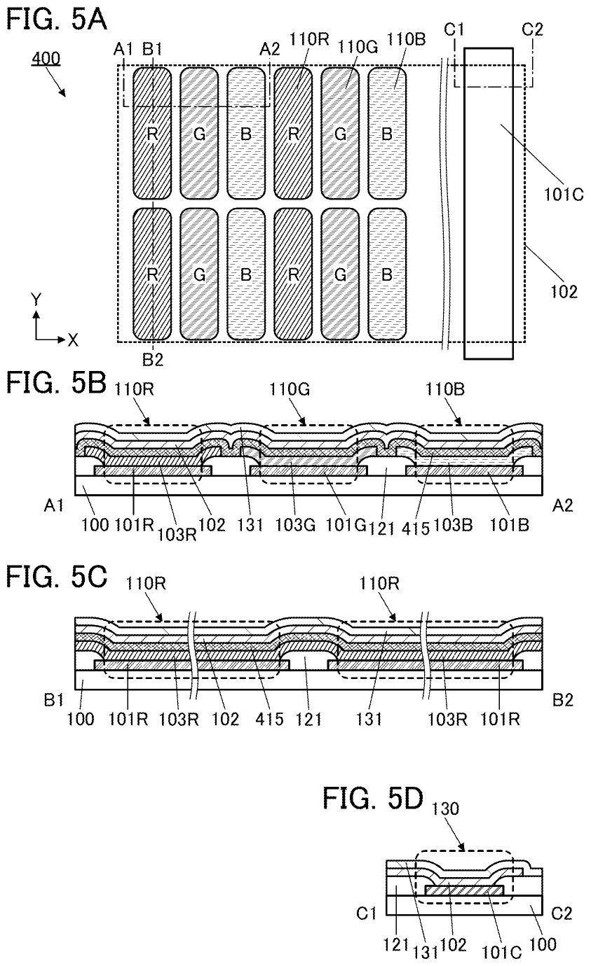

FIG. 5A is a schematic top view of a display device 400 of one embodiment of the present invention. The display device 400 includes a plurality of light-emitting devices 110R exhibiting red, a plurality of light-emitting devices 110G exhibiting green, and a plurality of light-emitting devices 110B exhibiting blue. In FIG. 5A, light-emitting regions of the light-emitting devices are denoted by R, G, and B to easily differentiate the light-emitting devices.

The light-emitting devices 110R, the light-emitting devices 110G, and the light-emitting devices 110B are arranged in a matrix. FIG. 5A illustrates what is called stripe arrangement, in which the light-emitting devices of the same color are arranged in one direction. Note that the arrangement method of the light-emitting devices is not limited thereto; another arrangement method such as delta arrangement, zigzag arrangement, or PenTile arrangement may also be used.

The light-emitting devices 110R, the light-emitting devices 110G, and the light-emitting devices 110B are arranged in the X direction. The light-emitting devices of the same color are arranged in the Y direction intersecting with the X direction.

The light-emitting device 110R, the light-emitting device 110G, and the light-emitting device 110B have the above-described structure.

FIG. 5B is a schematic cross-sectional view taken along the dashed-dotted line A1-A2 in FIG. 5A, and FIG. 5C is a schematic cross-sectional view taken along the dashed-dotted line B1-B2. FIG. 5B illustrates cross sections of the light-emitting device 110R, the light-emitting device 110G, and the light-emitting device 110B. The light-emitting device 110R includes an anode 101R, an EL layer 103R, the EL layer (corresponding to the electron-injection layer or the electron-injection layer B) 115, and the cathode 102. The light-emitting device 110G includes an anode 101G, an EL layer 103G, the EL layer (corresponding to the electron-injection layer or the electron-injection layer B) 115, and the cathode 102. The light-emitting device 110B includes an anode 101B, an EL layer 103B, the EL layer (corresponding to the electron-injection layer or the electron-injection layer B) 115, and the cathode 102. An EL layer 415 and the cathode 102 are provided to be shared by the light-emitting device 110R, the light-emitting device 110G, and the light-emitting device 110B. The EL layer 415 can also be referred to as a common layer.

The EL layer 103R included in the light-emitting device 110R contains at least a light-emitting organic compound that emits light with intensity in the red wavelength range. The EL layer 103G included in the light-emitting device 110G contains at least a light-emitting organic compound that emits light with intensity in the green wavelength range. The EL layer 103B included in the light-emitting device 110B contains at least a light-emitting organic compound that emits light with intensity in the blue wavelength range.

Note that the first light-emitting device and the second light-emitting device that are adjacent to each other correspond to the light-emitting device 110R and the light-emitting device 110G, and the light-emitting device 110G and the light-emitting device 110B in FIG. 5B, for example. Vertically arranged light-emitting devices of the same color in FIG. 5A can also be referred to as light-emitting devices adjacent to each other.

The EL layer 103R, the EL layer 103G, and the EL layer 103B may each include one or more of an electron-injection layer, an electron-transport layer, a hole-injection layer, a hole-transport layer, a carrier-blocking layer, an exciton-blocking layer, and the like in addition to the layer containing a light-emitting organic compound (the light-emitting layer). The EL layer 415 does not necessarily include the light-emitting layer. In the light-emitting apparatus of one embodiment of the present invention, the EL layer 415 is preferably an electron-injection layer. In the case where the electron-transport layer also serves as an electron-injection layer, the EL layer 415 may be omitted.

Alternatively, the EL layer 103R, the EL layer 103G, and the EL layer 103B each include a light-emitting unit A, an intermediate layer, and a light-emitting unit B. The light-emitting unit A includes at least a light-emitting layer A, and the light-emitting unit B includes at least a light-emitting layer B and an electron-transport layer B. In addition to these, one or more of an electron-injection layer, an electron-transport layer, a hole-injection layer, a hole-transport layer, a carrier-blocking layer, an exciton-blocking layer, and the like may be included. The EL layer 415 does not necessarily include the light-emitting layer. In the light-emitting apparatus of one embodiment of the present invention, the EL layer 415 is preferably an electron-injection layer. In the case where the electron-transport layer B also serves as an electron-injection layer, the EL layer 415 may be omitted.

The anode 101R, the anode 101G, and the anode 101B are provided for the respective light-emitting devices. Each of the cathode 102 and the EL layer 415 is provided as a continuous layer shared by the light-emitting device. A conductive film with a property of transmitting visible light is used for either the respective pixel electrodes or the cathode 102, and a conductive film with a property of reflecting visible light is used for the other. When the pixel electrodes are light-transmitting electrodes and the cathode 102 is a reflective electrode, a bottom-emission display device can be provided; whereas when the pixel electrodes are reflective electrodes and the cathode 102 is a light-transmitting electrode, a top-emission display device can be provided. Note that when both respective pixel electrodes and the cathode 102 have a light-transmitting property, a dual-emission display device can be obtained.

An insulating layer 131 is provided to cover the edge portions of the anode 101R, the anode 101G, and the anode 101B. The edge portion of the insulating layer 131 is preferably tapered. Note that the insulating layer 131 is not necessarily provided when not needed.

The EL layer 103R, the EL layer 103G, and the EL layer 103B each include a region in contact with the top surface of the pixel electrode and a region in contact with the surface of the insulating layer 131. The edge portions of the EL layer 103R, the EL layer 103G, and the EL layer 103B are positioned over the insulating layer 131.

In FIG. 5B, there is a gap between the two EL layers of the light-emitting devices of different colors. In this manner, the EL layer 103R, the EL layer 103G, and the EL layer 103G are preferably provided so as not to be in contact with each other. This suitably prevents unintentional light emission from being caused by a current flowing through two adjacent EL layers. As a result, the contrast can be increased to achieve a display device with high display quality.

FIG. 5C illustrates an example in which the EL layer 103R is formed in a belt-like shape so as to be continuous in the Y direction. When the EL layer 103R and the like are formed in a belt-like shape, no space for dividing the layer is needed and thus the area of a non-light-emitting region between the light-emitting devices can be reduced, resulting in a higher aperture ratio. Note that FIG. 5C illustrates the cross sections of the light-emitting devices 110R as an example; the light-emitting device 110G and the light-emitting device 110B can have a similar shape. Note that the EL layer may be divided for the light-emitting devices in the Y direction.

The insulating layer 121 is provided over the cathode 102 to cover the light-emitting device 110R, the light-emitting device 110G, and the light-emitting device 110B. The insulating layer 121 has a function of preventing diffusion of impurities such as water into the light-emitting devices from above.

The insulating layer 121 can have, for example, a single-layer structure or a stacked-layer structure at least including an inorganic insulating film. As the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide may be used for the insulating layer 121.

As the insulating layer 121, a stacked-layer film of an inorganic insulating film and an organic insulating film can be used. For example, a structure in which an organic insulating film is interposed between a pair of inorganic insulating films is preferable. Furthermore, the organic insulating film preferably functions as a planarization film. Thus, the top surface of the organic insulating film can be flat, and accordingly, coverage with the inorganic insulating film thereover can be improved, leading to an improvement in barrier properties. Moreover, the top surface of the insulating layer 121 is flat, which is preferable because the influence of uneven shape due to the lower structure can be reduced in the case where a component (e.g., a color filter, an electrode of a touch sensor, a lens array, or the like) is provided over the insulating layer 121.

FIG. 5A also illustrates a connection electrode 101C that is electrically connected to the cathode 102. The connection electrode 101C is supplied with a potential (e.g., an anode potential or a cathode potential) that is to be supplied to the cathode 102. The connection electrode 101C is provided outside a display region where the light-emitting devices 110R and the like are arranged. In FIG. 5A, the cathode 102 is denoted by a dashed line.

The connection electrode 101C can be provided along the outer periphery of the display region. For example, the connection electrode 101C may be provided along one side of the outer periphery of the display region or two or more sides of the outer periphery of the display region. That is, in the case where the display region has a rectangular top surface shape, the top surface shape of the connection electrode 101C can be a belt-like shape, an L shape, a U shape (a square bracket shape), a quadrangular shape, or the like.

FIG. 5D is a schematic cross-sectional view taken along dashed-dotted line C1-C2 in FIG. 5A. FIG. 5D illustrates a connection portion 130 in which the connection electrode 101C is electrically connected to the cathode 102. In the connection portion 130, the cathode 102 is provided on and in contact with the connection electrode 101C and the insulating layer 121 is provided to cover the cathode 102. In addition, the insulating layer 131 is provided to cover the edge portion of the connection electrode 101C.

### Manufacturing Method Example 1

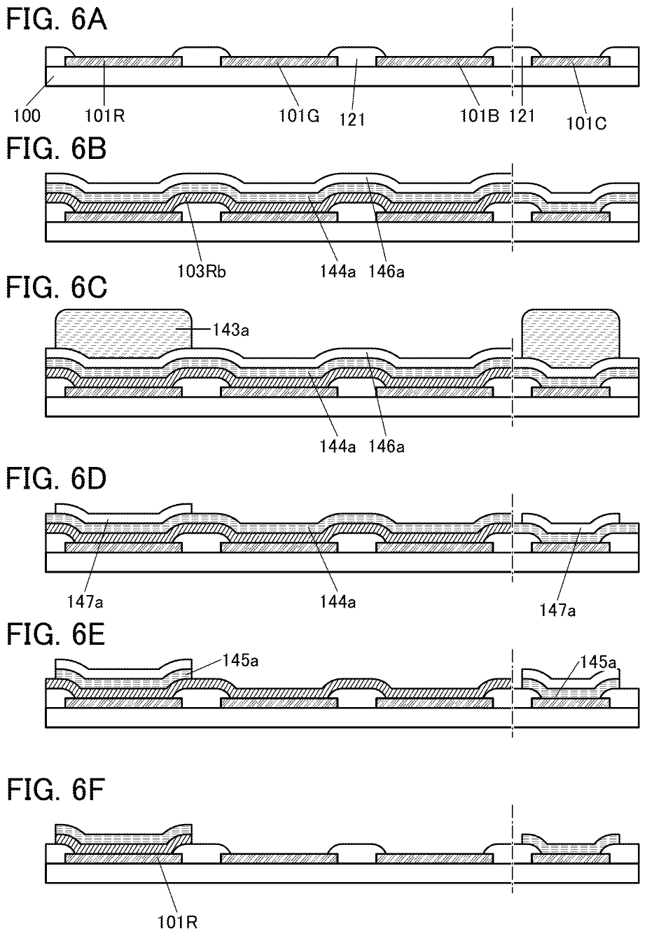

An example of a method for manufacturing the display device of one embodiment of the present invention is described below with reference to the drawings. Here, description is made with use of the display device 400 illustrated in the above structure example. FIG. 6A to FIG. 6F are each a cross-sectional schematic view of a step in a manufacturing method of the display device described below. In FIG. 6A and the like, the schematic cross-sectional views of the connection portion 130 and the periphery thereof are also illustrated on the right side.

Note that thin films included in the display device (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of the CVD method include a plasma-enhanced chemical vapor deposition (PECVD) method and a thermal CVD method. An example of a thermal CVD method is a metal organic CVD (MOCVD) method.

Alternatively, thin films included in the display device (e.g., insulating films, semiconductor films, and conductive films) can be formed by a method such as spin coating, dipping, spray coating, ink-jetting, dispensing, screen printing, offset printing, a doctor knife method, a slit coater, a roll coater, a curtain coater, or a knife coater.

Thin films included in the display device can be processed by a photolithography method or the like. Besides, a nanoimprinting method, a sandblasting method, a lift-off method, or the like may be used to process thin films. Alternatively, island-shaped thin films may be directly formed by a deposition method using a shielding mask such as a metal mask.

There are two typical examples of photolithography methods. In one of the methods, a resist mask is formed over a thin film that is to be processed, the thin film is processed by etching or the like, and then the resist mask is removed. In the other method, a photosensitive thin film is formed and then the thin film is processed into a desired shape by performing light exposure and development.

As light for exposure in a photolithography method, light with an i-line (with a wavelength of 365 nm), light with a g-line (with a wavelength of 436 nm), light with an h-line (with a wavelength of 405 nm), or light in which the i-line, the g-line, and the h-line are mixed can be used. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. It is preferable to use EUV, X-rays, or an electron beam because extremely minute processing can be performed. Note that a photomask is not needed when exposure is performed by scanning with a beam such as an electron beam.

For etching of thin films, a dry etching method, a wet etching method, a sandblast method, or the like can be used.

### [Preparation for Substrate 100]

A substrate that has heat resistance high enough to withstand at least heat treatment performed later can be used as the substrate 100. When an insulating substrate is used as the substrate 100, a glass substrate, a quartz substrate, a sapphire substrate, a ceramic substrate, an organic resin substrate, or the like can be used. Alternatively, a semiconductor substrate such as a single crystal semiconductor substrate or a polycrystalline semiconductor substrate of silicon, silicon carbide, or the like; a compound semiconductor substrate of silicon germanium or the like; an SOI substrate; or the like can be used.

As the substrate 100, it is particularly preferable to use the semiconductor substrate or the insulating substrate over which a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

### [Formation of Anodes 101R, 101G, and 101B and Connection Electrode 101C]

Next, the anode 101R, the anode 101G, the anode 101B, and the connection electrode 101C are formed over the substrate 100. First, a conductive film to be the anode (pixel electrode) is deposited, a resist mask is formed by a photolithography method, and an unnecessary portion of the conductive film is removed by etching. After that, the resist mask is removed to form the anode 101R, the anode 101G, and the anode 101B.

In the case where a conductive film with a property of reflecting visible light is used as each pixel electrode, it is preferable to use a material (e.g., silver or aluminum) having reflectance as high as possible in the whole wavelength range of visible light. This can increase color reproducibility as well as light extraction efficiency of the light-emitting devices. In the case where a conductive film with a property of reflecting visible light is used as each pixel electrode, what is called a top-emission light-emitting apparatus in which light is extracted in the direction opposite to the substrate can be obtained. In the case where a conductive film with a light-transmitting property is used as each pixel electrode, what is called a bottom-emission light-emitting apparatus in which light is extracted in the direction of the substrate can be obtained.

### [Formation of Insulating Layer 121]

Then, the insulating layer 121 is provided to cover the edge portions of the anode 101R, the anode 101G, and the anode 101B (FIG. 6A). An organic insulating film or an inorganic insulating film can be used as the insulating layer 121. The edge portion of the insulating layer 121 is preferably tapered to improve step coverage with an EL layer described later. In particular, when an organic insulating film is used, a photosensitive material is preferably used, in which case the shape of the edge portion can be easily controlled by the conditions of light exposure and development. In the case where the insulating layer 121 is not provided, the distance between the light-emitting devices can be further reduced to offer a light-emitting apparatus with a higher resolution.

[Formation of EL layer 103Rf]

Subsequently, an EL film 103Rf, which is to be the EL layer 103R, is formed over the anode 101R, the anode 101G, the anode 101B, and the insulating layer 121.

The EL layer 103Rf includes at least a film containing a light-emitting compound. A structure may be employed in which one or more films functioning as an electron-injection layer, an electron-transport layer, a charge-generation layer, a hole-transport layer, and a hole-injection layer are stacked in addition to the above.

In the case of a tandem light-emitting device, the EL layer 103Rf includes at least a light-emitting unit A, an intermediate layer, and a light-emitting unit B in this order from the anode side. The light-emitting unit A includes at least a light-emitting layer A, the light-emitting unit B includes at least a light-emitting layer B and an electron-transport layer B, and the electron-transport layer B is positioned farthest from the anode 101 in the EL layer 103Rf. The light-emitting unit A and the light-emitting unit B may each include one or more of an electron-injection layer, an electron-transport layer, a hole-injection layer, a hole-transport layer, a carrier-blocking layer, an exciton-blocking layer, and the like in addition to the light-emitting layer. Note that the intermediate layer can also serves as an electron-injection layer and a hole-injection layer, and thus the electron-injection layer of the light-emitting unit A and the hole-injection layer of the light-emitting unit B are not necessarily provided.

The EL layer 103Rf can be formed by, for example, an evaporation method, a sputtering method, an ink-jet method, or the like. Without limitation to this, the above-described film formation method can be used as appropriate.

For example, the EL layer 103Rf is preferably a stacked-layer film in which a hole-injection layer, a hole-transport layer, a light-emitting layer, and an electron-transport layer are stacked in this order. In that case, a film including the electron-injection layer 115 can be used as the EL layer formed later. In the light-emitting apparatus of one embodiment of the present invention, it is possible to inhibit damage to the light-emitting layer caused by a subsequent photolithography step or the like by providing an electron-transport layer to cover the light-emitting layer; thus, the light-emitting device with high reliability can be manufactured. When a layer containing at least the first heteroaromatic compound having the first heteroaromatic ring and the first organic compound different from the first heteroaromatic compound is used as the electron-transport layer, the heat resistance is improved and the upper temperature limit in heat treatment at the time of forming a resist mask later is raised; therefore, it is possible to perform higher-resolution patterning. Furthermore, the reliability of the light-emitting apparatus is also improved.

The EL layer 103Rf is preferably formed so as not to be provided over the connection electrode 101C. For example, in the case where the EL layer 103Rf is formed by an evaporation method (or a sputtering method), it is preferable that the EL layer 103Rf be formed using a shielding mask so as not to be formed over the connection electrode 101C; alternatively, it is preferable that an unnecessary portion of the EL layer 103Rf over the connection electrode 101C be removed in a later etching step.

[Formation of Sacrificial Film 144a]

Next, a sacrificial film 144a is formed to cover the EL layer 103Rf. The sacrificial film 144a is provided in contact with the top surface of the connection electrode 101C.

As the sacrificial film 144a, it is possible to use a film highly resistant to etching treatment performed on various EL layers such as the EL layer 103Rf, i.e., a film having high etching selectivity with respect to the EL layers. Furthermore, as the sacrificial film 144a, it is possible to use a film having high etching selectivity with respect to a protective film such as a protective film 146a described later. Moreover, as the sacrificial film 144a, it is possible to use a film that can be removed by a wet etching method that is less likely to cause damage to the EL film.

The sacrificial film 144a can be formed using an inorganic film such as a metal film, an alloy film, a metal oxide film, a semiconductor film, or an inorganic insulating film, for example. The sacrificial film 144a can be formed by any of a variety of film formation methods such as a sputtering method, an evaporation method, a CVD method, and an ALD method.

For the sacrificial film 144a, for example, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used. It is particularly preferable to use a low-melting-point material such as aluminum or silver.

For the sacrificial film 144a, a metal oxide such as an indium-gallium-zinc oxide (In—Ga—Zn oxide, also referred to as IGZO) can be used. It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Indium tin oxide containing silicon, or the like can also be used.

Note that an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium. In particular, M is preferably one or more kinds selected from gallium, aluminum, and yttrium.

For the sacrificial film 144a, an inorganic insulating material such as aluminum oxide, hafnium oxide, or silicon oxide can be used.

For the sacrificial film 144a, a material that can be dissolved in a solvent chemically stable with respect to at least the uppermost film of the EL layer 103Rf is preferably used. Specifically, a material that will be dissolved in water or alcohol can be suitably used for the sacrificial film 144a. In formation of the sacrificial film 144a, it is preferable that application of such a material dissolved in a solvent such as water or alcohol be performed by a wet deposition method and followed by heat treatment for evaporating the solvent. At this time, the heat treatment is preferably performed in a reduced-pressure atmosphere, in which case the solvent can be removed at a low temperature in a short time and thermal damage to the EL layer 103Rf can be reduced accordingly.

As a wet deposition method for forming the sacrificial film 144a, spin coating, dipping, spray coating, ink-jetting, dispensing, screen printing, offset printing, a doctor knife method, a slit coater, a roll coater, a curtain coater, a knife coater, or the like can be given.

For the sacrificial film 144a, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used.

[Formation of Protective Film 146a]

Next, the protective film 146a is formed over the sacrificial film 144a (FIG. 6B).

The protective film 146a is a film used as a hard mask when the sacrificial film 144a is etched later. In a later step of processing the protective film 146a, the sacrificial film 144a is exposed. Thus, the combination of films having high etching selectivity therebetween is selected for the sacrificial film 144a and the protective film 146a. It is thus possible to select a film that can be used for the protective film 146a depending on an etching condition of the sacrificial film 144a and an etching condition of the protective film 146a.

For example, in the case where dry etching using a gas containing fluorine (also referred to as a fluorine-based gas) is performed for the etching of the protective film 146a, the protective film 146a can be formed using silicon, silicon nitride, silicon oxide, tungsten, titanium, molybdenum, tantalum, tantalum nitride, an alloy containing molybdenum and niobium, an alloy containing molybdenum and tungsten, or the like. Here, a metal oxide film using IGZO, ITO, or the like is given as a film having high etching selectivity (that is, enabling low etching rate) in dry etching using the fluorine-based gas, and such a film can be used as the sacrificial film 144a.

Without being limited to the above, a material of the protective film 146a can be selected from a variety of materials depending on the etching condition of the sacrificial film 144a and the etching condition of the protective film 146a. For example, any of the films that can be used for the sacrificial film 144a can be used.

As the protective film 146a, a nitride film can be used, for example. Specifically, it is possible to use a nitride such as silicon nitride, aluminum nitride, hafnium nitride, titanium nitride, tantalum nitride, tungsten nitride, gallium nitride, or germanium nitride.

As the protective film 146a, an oxide film can also be used. Typically, it is possible to use an oxide film or an oxynitride film such as silicon oxide, silicon oxynitride, aluminum oxide, aluminum oxynitride, hafnium oxide, or hafnium oxynitride.

Alternatively, as the protective film 146a, an organic film that can be used for the EL layer 103Rf or the like can be used. For example, the organic film that is used as the EL layer 103Rf, an EL layer 103Gf, or an EL layer 103Bf can be used as the protective film 146a. The use of such an organic film is preferable, in which case the deposition apparatus for the EL layer 103Rf or the like can be used in common.

[Formation of Resist Mask 143a]

Then, a resist mask 143a is formed in a position being over the protective film 146a and overlapping with the anode 101R and a position being over the protective film 146a and overlapping with the connection electrode 101C (FIG. 6C).

For the resist mask 143a, a resist material containing a photosensitive resin such as a positive type resist material or a negative type resist material can be used.

On the assumption that the resist mask 143a is formed over the sacrificial film 144a without the protective film 146a therebetween, there is a risk of dissolving the EL layer 103Rf due to a solvent of the resist material if a defect such as a pinhole exists in the sacrificial film 144a. Such a defect can be prevented by using the protective film 146a.

In the case where a film that is unlikely to cause a defect such as a pinhole is used as the sacrificial film 144a, the resist mask 143a may be formed directly on the sacrificial film 144a without the protective film 146a therebetween.

[Etching of Protective Film 146a]

Next, part of the protective film 146a that is not covered with the resist mask 143a is removed by etching, so that a belt-shaped protective layer 147a is formed. At that time, the protective layer 147a is formed also over the connection electrode 101C.

In the etching of the protective film 146a, an etching condition with high selectively is preferably employed so that the sacrificial film 144a is not removed by the etching. Either wet etching or dry etching can be performed as the etching of the protective film 146a; however, a reduction in a pattern of the protective film 146a can be inhibited with use of dry etching.

[Removal of Resist Mask 143a]

Next, the resist mask 143a is removed (FIG. 6D).

The removal of the resist mask 143a can be performed by wet etching or dry etching. It is particularly preferable to perform dry etching (also referred to as plasma ashing) using an oxygen gas as an etching gas to remove the resist mask 143a.

At this time, the removal of the resist mask 143a is performed in a state where the EL layer 103Rf is covered with the sacrificial film 144a; thus, the EL layer 103Rf is less likely to be affected by the removal. In particular, when the EL layer 103Rf is exposed to oxygen, the electrical characteristics are adversely affected in some cases; thus, it is preferable that the EL layer 103Rf be covered with the sacrificial film 144a when etching using an oxygen gas, such as plasma ashing, is performed.

[Etching of Sacrificial Film 144a]

Next, part of the sacrificial film 144a that is not covered with the protective layer 147a is removed by etching with use of the protective layer 147a as a mask, so that a belt-shaped sacrificial layer 145a is formed (FIG. 6E). At that time, the sacrificial layer 145a is formed also over the connection electrode 101C.

Either wet etching or dry etching can be performed for the etching of the sacrificial film 144a; however, a dry etching method is preferably used because a reduction in a pattern of the sacrificial film 144a can be inhibited.

[Etching of EL Layer 103Rf and Protective Layer 147a]

Next, part of the EL layer 103Rf that is not covered with the sacrificial layer 145a is removed by etching at the same time as etching of the protective layer 147a, whereby the EL layer 103R having a belt-like shape is formed (FIG. 6F). At that time, the protective layer 147a over the connection electrode 101C is also removed.

The EL layer 103Rf and the protective layer 147a are preferably etched by the same treatment so that the process can be simplified to reduce the manufacturing cost of the display device.

For the etching of the EL layer 103Rf, it is particularly preferable to perform dry etching using an etching gas that does not contain oxygen as its main component. This can inhibit a change in the quality of the EL layer 103Rf to achieve a highly reliable display device. Examples of the etching gas that does not contain oxygen as its main component include CF₄, C₄F₈, SF₆, CHF₃, Cl₂, H₂O, BCl₃, H₂, or a rare gas such as He. Alternatively, a mixed gas of the above gas and a dilution gas that does not contain oxygen can be used as the etching gas.

Note that the etching of the EL layer 103Rf and the etching of the protective layer 147a may be performed separately. In that case, either the etching of the EL layer 103Rf or the etching of the protective layer 147a may be performed first.

At this step, the EL layer 103R and the connection electrode 101C are covered with the sacrificial layer 145a.

### [Formation of EL Layer 103Gf]

Subsequently, the EL layer 103Gf to be the EL layer 103G later is deposited over the sacrificial layer 145a, the insulating layer 121, the anode 101G, and the anode 101B. In that case, similarly to the EL layer 103Rf, the EL layer 103Gf is preferably not provided over the connection electrode 101C.

For the formation method of the EL layer 103Gf, the above description of the EL layer 103Rf can be referred to.

[Formation of Sacrificial Film 144b]

Then, a sacrificial film 144b is formed over the EL layer 103Gf. The sacrificial film 144b can be formed in a manner similar to that for the sacrificial film 144a. In particular, the sacrificial film 144b and the sacrificial film 144a are preferably formed using the same material.

At this time, the sacrificial film 144a is concurrently formed also over the connection electrode 101C so as to cover the sacrificial layer 145a.

[Formation of Protective Film 146b]

Next, a protective film 146b is formed over the sacrificial film 144b. The protective film 146b can be formed in a manner similar to that for the protective film 146a. In particular, the protective film 146b and the protective film 146a are preferably formed using the same material.

[Formation of Resist Mask 143b]

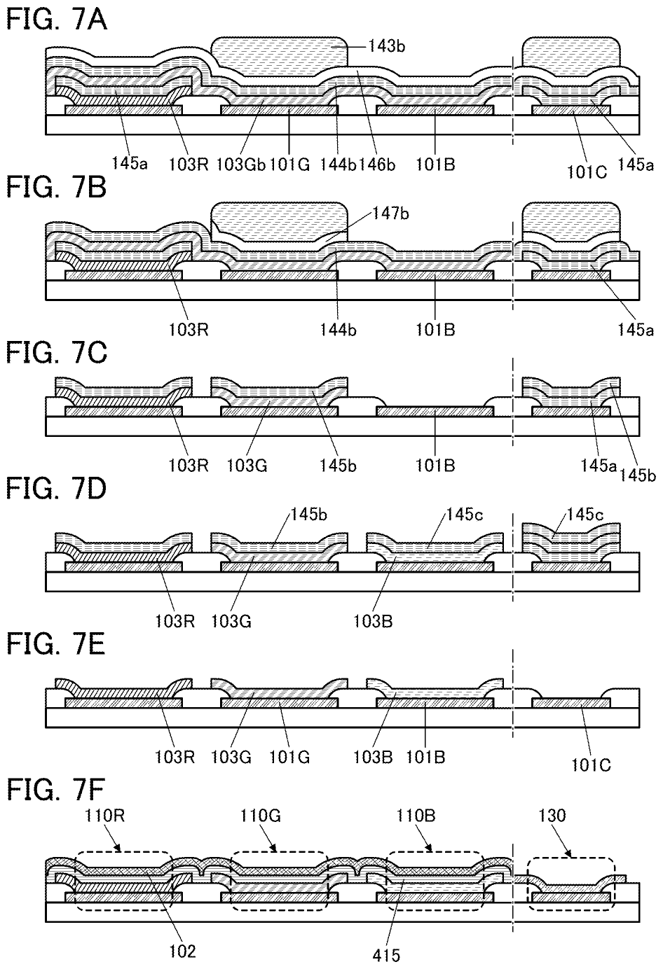

Then, a resist mask 143b is formed in a region being over the protective film 146b and overlapping with the anode 101G and a region being over the protective film 146b and overlapping with the connection electrode 101C (FIG. 7A).

The resist mask 143b can be formed in a manner similar to that for the resist mask 143a.

[Etching of Protective Film 146b]

Next, part of the protective film 146b that is not covered with the resist mask 143b is removed by etching, so that a belt-shaped protective layer 147b is formed (FIG. 7B). At that time, the protective layer 147b is formed also over the connection electrode 101C.

For the etching of the protective film 146b, the above description of the protective film 146a can be referred to.

[Removal of Resist Mask 143b]

Next, the resist mask 143a is removed. For the removal of resist mask 143b, the above description of the resist mask 143a can be referred to.

[Etching of Sacrificial Film 144b]

Next, part of the sacrificial film 144b that is not covered with the protective layer 147b is removed by etching with use of the protective layer 147b as a mask, so that a belt-shaped sacrificial layer 145b is formed. At that time, the sacrificial layer 145b is formed also over the connection electrode 101C. The sacrificial layer 145a and the sacrificial layer 145b are stacked over the connection electrode 101C.

For the etching of the sacrificial film 144b, the above description of the sacrificial film 144a can be referred to.

[Etching of EL Layer 103Gf and Protective Layer 147b]

Next, the protective layer 147b and part of the EL layer 103Gf that is not covered with the sacrificial layer 145b are removed by etching at the same time, so that the EL layer 103G having a belt-like shape is formed (FIG. 7C). At that time, the protective layer 147b over the connection electrode 101C is also removed.

For the etching of the EL layer 103Gf and the protective layer 147b, the above description of the EL layer 103Rf and the protective layer 147a can be referred to.

At this time, the EL layer 103R is protected by the sacrificial layer 145a, and thus damage due to the etching step of the EL layer 103Gf can be prevented.

In the above manner, the EL layer 103R having a belt-like shape and the EL layer 103G having a belt-like shape can be separately formed with highly accurate alignment.

### [Formation of EL Layer 103B]

The above steps are performed on the EL layer 103Bf (not illustrated), whereby the EL layer 103B having an island-like shape and a sacrificial layer 145c having an island-like shape can be formed (FIG. 7D).

That is, after the EL layer 103G is formed, the EL layer 103Bf, a sacrificial film 144c, a protective film 146c, and a resist mask 143c (each of which is not illustrated) are sequentially formed. After that, the protective film 146c is etched to form a protective layer 147c (not illustrated); then, the resist mask 143c is removed. Subsequently, the sacrificial film 144c is etched to form the sacrificial layer 145c. Then, the protective layer 147c and the EL layer 103Bf are etched to form the EL layer 103B having a belt-like shape.

After the EL layer 103B is formed, the sacrificial layer 145c is formed also over the connection electrode 101C at the same time. The sacrificial layer 145a, the sacrificial layer 145b, and the sacrificial layer 145c are stacked over the connection electrode 101C.

### [Removal of Sacrificial Layer]

Next, the sacrificial layer 145a, the sacrificial layer 145b, and the sacrificial layer 145c are removed to expose the top surfaces of the EL layer 103R, the EL layer 103G, and the EL layer 103B (FIG. 7E). At that time, the top surface of the connection electrode 101C is also exposed.

The sacrificial layer 145a, the sacrificial layer 145b, and the sacrificial layer 145c can be removed by wet etching or dry etching. At this time, a method that causes damage to the EL layer 103R, the EL layer 103G, and the EL layer 103B as little as possible is preferably employed. In particular, a wet etching method is preferably used. For example, wet etching using a tetramethyl ammonium hydroxide (TMAH) solution, diluted hydrofluoric acid, oxalic acid, phosphoric acid, acetic acid, nitric acid, or a mixed solution thereof is preferably performed.

Alternatively, the sacrificial layer 145a, the sacrificial layer 145b, and the sacrificial layer 145c are preferably removed by being dissolved in a solvent such as water or alcohol. Examples of the alcohol in which the sacrificial layer 145a, the sacrificial layer 145b, and the sacrificial layer 145c can be dissolved include ethyl alcohol, methyl alcohol, isopropyl alcohol (IPA), and glycerin.

After the sacrificial layer 145a, the sacrificial layer 145b, and the sacrificial layer 145c are removed, drying treatment is preferably performed in order to remove water contained in the EL layer 103R, the EL layer 103G, and the EL layer 103B and water adsorbed on the surfaces of the EL layer 103R, the EL layer 103G, and the EL layer 103B. For example, heat treatment is preferably performed in an inert gas atmosphere or a reduced-pressure atmosphere. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere because drying at a lower temperature is possible.

In the above manner, the EL layer 103R, the EL layer 103G, and the EL layer 103B can be separately formed.

Note that the electron-transport layers included in the EL LAYER 103R, the EL LAYER 103G, and the EL LAYER 103B may have the same or different components. It is preferable that the heteroaromatic rings of the heteroaromatic compounds contained in the electron-transport layers be the same as one another, and the heteroaromatic compounds contained in the electron-transport layers be the same as one another. In addition, it is preferable that the organic compounds contained in the electron-transport layers be the same as one another.

### [Formation of Electron-Injection Layer 115]

Then, the electron-injection layer 115 or the electron-injection layer B 115b is formed to cover the EL layer 103R, the EL layer 103G, and the EL layer 103B.

The electron-injection layer 115 or the electron-transport layer B 115b can be formed in a manner similar to that for the EL layer 103Rf or the like. In the case where the electron-injection layer 115 is deposited by an evaporation method, the electron-injection layer 115 is preferably deposited using a shielding mask so as not to be deposited over the connection electrode 101C.

### [Formation of Cathode 102]

Then, the cathode 102 is formed to cover the electron-injection layer 115 or the electron-transport layer B 115b and the connection electrode 101C (FIG. 7F).

The cathode 102 can be formed by a deposition method such as an evaporation method or a sputtering method. Alternatively, a film formed by an evaporation method and a film formed by a sputtering method may be stacked. In that case, the cathode 102 is preferably formed so as to cover a region where the electron-injection layer 115 or the electron-transport layer B 115b is formed. That is, a structure in which the edge portion of the electron-injection layer 115 or the electron-transport layer B 115b overlaps with the cathode 102 can be obtained. The cathode 102 is preferably formed using a shielding mask. The cathode 102 is electrically connected to the connection electrode 101C outside a display region.

### [Formation of Protective Layer]

Then, a protective layer is formed over the cathode 102. An inorganic insulating film used for the protective layer is preferably formed by a sputtering method, a PECVD method, or an ALD method. In particular, an ALD method is preferable because a film deposited by ALD method has excellent step coverage and is less likely to cause a defect such as pinhole. An organic insulating film is preferably formed by an ink-jet method because a uniform film can be formed in a desired area.

Through the above steps, the light-emitting apparatus of one embodiment of the present invention can be manufactured.

Although the cathode 102 and the electron-injection layer 115 or the electron-transport layer B 115b are formed so as to have different top surface shapes, they may be formed in the same region.

### [Structure Example of Light-Emitting Device]

Next, other structures and examples of materials of the light-emitting device in the light-emitting apparatus of one embodiment of the present invention are described. The light-emitting device in the light-emitting apparatus of one embodiment of the present invention illustrated in FIG. 1 includes, as described above, the EL layer 103 formed of a plurality of layers between the pair of electrodes, the anode 101 and the cathode 102. The EL layer 103 includes the light-emitting layer 113 containing a light-emitting material and the electron-transport layer 114 having the aforementioned structure. Note that the EL layer 103 may include a hole-injection layer, a hole-transport layer, a light-emitting layer, an electron-transport layer, an electron-injection layer, a carrier-blocking layer, an exciton-blocking layer, or the like, and it is possible to freely select and use components in accordance with the required performance except for the above-described essential layers.

As described above, the light-emitting device in the light-emitting apparatus of one embodiment of the present invention illustrated in FIG. 30 is a light-emitting device having a tandem structure in which the EL layer 103 (the light-emitting unit A 151a, the intermediate layer 150, the light-emitting unit B 151b, and the electron-transport layer B 115b) is provided between the pair of electrodes, the anode 101 and the cathode 102.

The light-emitting unit A 151a includes at least the light-emitting layer A 113a, and the light-emitting unit B 151b includes at least the light-emitting layer B 113b and the electron-transport layer B 114b. Note that each of the light-emitting units may include a hole-injection layer, a hole-transport layer, a light-emitting layer, an electron-transport layer, an electron-injection layer, a carrier-blocking layer, an exciton-blocking block layer, and the like, and it is possible to freely select and use components in accordance with the required performance except for the above-described essential layers. The intermediate layer also serves as a hole-injection layer of the light-emitting unit A, a hole-injection layer of the light-emitting unit B, or the like in some cases.

The anode 101 is preferably formed using a metal, an alloy, or a conductive compound having a high work function (specifically, 4.0 eV or more), a mixture thereof, or the like. Specifically, for example, indium oxide-tin oxide (ITO: Indium Tin Oxide), indium oxide-tin oxide containing silicon or silicon oxide, indium oxide-zinc oxide, indium oxide containing tungsten oxide and zinc oxide (IWZO), and the like can be given. These conductive metal oxide films are usually deposited by a sputtering method but may also be formed by application of a sol-gel method or the like. An example of the formation method is a method in which indium oxide-zinc oxide is formed by a sputtering method using a target in which 1 to 20 wt % zinc oxide is added to indium oxide. Indium oxide containing tungsten oxide and zinc oxide (IWZO) can also be formed by a sputtering method using a target containing 0.5 to 5 wt % tungsten oxide and 0.1 to 1 wt % zinc oxide with respect to indium oxide. In addition, gold (Au), platinum (Pt), nickel (Ni), tungsten (W), chromium (Cr), molybdenum (Mo), iron (Fe), cobalt (Co), copper (Cu), palladium (Pd), a nitride of a metal material (such as titanium nitride), and the like can be given as examples of the material that is used for the anode 101. Graphene can also be used for the material that is used for the anode 101. Note that when a composite material described later is used for a layer that is in contact with the anode 101 in the EL layer 103, an electrode material can be selected regardless of its work function.

Although the EL layer 103 preferably has a stacked-layer structure, there is no particular limitation on the stacked-layer structure, and any of various layer structures such as a hole-injection layer, a hole-transport layer, a light-emitting layer, an electron-transport layer, an electron-injection layer, a carrier-blocking layer (a hole-blocking layer, an electron-blocking layer), an exciton-blocking layer, and an intermediate layer (a charge-generation layer) can be employed. Note that one or more of the above layers are not necessarily provided. In this embodiment, a structure including the hole-injection layer 111 and the hole-transport layer 112 in addition to the electron-transport layer 114, the electron-injection layer 115, and the light-emitting layer 113 as illustrated in FIG. 1A to FIG. 1D is described below in detail.

The hole-injection layer 111 contains a substance having an acceptor property. Either an organic compound or an inorganic compound can be used as the substance having an acceptor property.

As the substance having an acceptor property, a compound having an electron-withdrawing group (a halogen group or a cyano group) can be used; 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylene-1,3,4,5,6,8,9,10-octafluoro-7H-pyren-2-ylidene)malononitrile, and the like can be given. A compound in which electron-withdrawing groups are bonded to a condensed aromatic ring having a plurality of heteroatoms, such as HAT-CN, is particularly preferable because it is thermally stable. A

radialene derivative having an electron-withdrawing group (in particular, a cyano group or a halogen group such as a fluoro group) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, molybdenum oxide, vanadium oxide, ruthenium oxide, tungsten oxide, manganese oxide, or the like can be used, other than the above-described organic compounds. Alternatively, the hole-injection layer 111 can be formed using a phthalocyanine-based complex compound such as phthalocyanine (abbreviation: H₂Pc) or copper phthalocyanine (CuPc), an aromatic amine compound such as 4,4′-bis[N-(4-diphenylaminophenyl)-N-phenylamino]biphenyl (abbreviation: DPAB) or N,N-bis{4-[bis(3-methylphenyl)amino]phenyl}-N,N-diphenyl-(1,1′-biphenyl)-4,4′-diamine (abbreviation: DNTPD), or a high molecule such as poly(3,4-ethylenedioxythiophene)/poly(styrenesulfonic acid) (PEDOT/PSS). The substance having an acceptor property can extract electrons from an adjacent hole-transport layer (or hole-transport material) by the application of an electric field.

Alternatively, a composite material in which a material having a hole-transport property contains the above-described substance having an acceptor property can be used for the hole-injection layer 111. By using a composite material in which a material having a hole-transport property contains a substance having an acceptor property, a material used to form an electrode can be selected regardless of its work function. In other words, besides a material having a high work function, a material having a low work function can also be used for the anode 101. As the material having a hole-transport property used for the composite material, any of a variety of organic compounds such as aromatic amine compounds, carbazole derivatives, aromatic hydrocarbons, and high molecular compounds (e.g., oligomers, dendrimers, or polymers) can be used. Note that the material having a hole-transport property used for the composite material preferably has a hole mobility higher than or equal to 1×10⁻⁶ cm²/Vs. Organic compounds which can be used as the material having a hole-transport property in the composite material are specifically given below.

Examples of the aromatic amine compounds that can be used for the composite material include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B). Specific examples of the carbazole derivatives include 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenylanthracen-9-yl)phenyl]-9H-carbazole (abbreviation: CzPA), and 1,4-bis[4-(N-carbazolyl)phenyl]-2,3,5,6-tetraphenylbenzene. Examples of the aromatic hydrocarbon include 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl)perylene. Other examples include pentacene and coronene. The aromatic hydrocarbon may have a vinyl skeleton. Examples of the aromatic hydrocarbon having a vinyl group include 4,4′-bis(2,2-diphenylvinyl)biphenyl (abbreviation: DPVBi) and 9,10-bis[4-(2,2-diphenylvinyl)phenyl]anthracene (abbreviation: DPVPA). Note that the organic compound of one embodiment of the present invention can also be used.

Other examples include high molecular compounds such as poly(N-vinylcarbazole) (abbreviation: PVK), poly(4-vinyltriphenylamine) (abbreviation: PVTPA), poly[N-(4-{N¹-[4-(4-diphenylamino)phenyl]phenyl-N¹-phenylamino}phenyl)methacrylamide] (abbreviation: PTPDMA), and poly[N,N-bis(4-butylphenyl)-N,N-bis(phenyl)benzidine] (abbreviation: Poly-TPD). The material having a hole-transport property used for the composite material further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of the amine through an arylene group may be used. Note that these second organic compounds are preferably substances having an N,N-bis(4-biphenyl)amino group because a light-emitting device with a long lifetime can be manufactured. As the above-described second organic compound, for example, N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), NN-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-diphenyl-4′-(2-naphthyl)-4″-{9-(4-biphenylyl)carbazole)}triphenylamine (abbreviation: YGTBiβNB), N-[4-(9-phenyl-9Hcarbazol-3-yl)phenyl]-N-[4-(1-naphthyl)phenyl]-9,9′-spirobi[9H-fluoren]-2-amine (abbreviation: PCBNBSF), NN-bis(4-biphenylyl)-9,9′-spirobi[9H-fluoren]-2-amine (abbreviation: BBASF), N,N-bis(1,1′-biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(4-biphenyl)-N-(dibenzofuran-4-yl)-9,9-dimethyl-9H-fluoren-2-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, or the like can be used.

Further preferably, the material having a hole-transport property that is used in the composite material is a substance having a relatively deep HOMO level higher than or equal to −5.7 eV and lower than or equal to −5.4 eV. The relatively deep HOMO level of the material having a hole-transport property used for the composite material makes it easy to inject holes into the hole-transport layer 112 and to obtain a light-emitting device with along lifetime. In addition, when the material having a hole-transport property that is used in the composite material is a substance having a relatively deep HOMO level, induction of holes can be inhibited properly so that the light-emitting device can have a more favorable lifetime.

Note that mixing the above composite material with a fluoride of an alkali metal or an alkaline earth metal (the proportion of fluorine atoms in the layer is preferably greater than or equal to 20%) can lower the refractive index of the layer. This also enables a layer with a low refractive index to be formed in the EL layer 103, leading to higher external quantum efficiency of the light-emitting device.

The formation of the hole-injection layer 111 can improve the hole-injection property, whereby a light-emitting device having a low driving voltage can be obtained.

Among substances having an acceptor property, the organic compound having an acceptor property is easy to use because it is easily deposited by vapor deposition.

The hole-transport layer 112 contains a material having a hole-transport property. The material having a hole-transport property preferably has a hole mobility higher than or equal to 1×10⁻⁶ cm²/Vs.

Examples of the material having a hole-transport property include a compound having an aromatic amine skeleton, such as 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBB1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(1,1′-biphenyl-3-yl)-3,3′-bi-9H-carbazole (abbreviation: BismBPCz), 9-(1,1′-biphenyl-3-yl)-9′-(1,1′-biphenyl-4-yl)-9H,9′H-3,3′-bicarbazole (abbreviation: mBPCCBP), or 9-(2-naphthyl)-9′-phenyl-9H,9′H-3,3′-bicarbazole (abbreviation: βNCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the material having a hole-transport property that is used for the composite material for the hole-injection layer 111 can also be suitably used as the material included in the hole-transport layer 112.

The light-emitting layer 113 contains a light-emitting substance and a host material. The light-emitting layer 113 may additionally contain other materials. Alternatively, the light-emitting layer 113 may be a stack of two layers with different compositions.

The light-emitting substance may be a fluorescent substance, a phosphorescent substance, a substance exhibiting thermally activated delayed fluorescence (TADF), or another light-emitting substance. Note that one embodiment of the present invention can more suitably be used in the case where the light-emitting layer 113 is a layer that exhibits fluorescence, specifically, blue fluorescence.

Examples of the material that can be used as a fluorescent substance in the light-emitting layer 113 are as follows. Fluorescent substances other than those can also be used.

The examples of the material include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N,N-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N,N,N′,N′,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(1,1′-biphenyl-2-yl)-2-anthryl]-N,N,N-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone, (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[i]quinolizin-9-yl)ethenyl]-4H-pyran-4-ylidene}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N-(1,6-pyrene-diyl)bis[(6-phenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

Examples of the material that can be used when a phosphorescent substance is used as the light-emitting substance in the light-emitting layer 113 are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), or tris[4-(3-biphenyl)-5-isopropyl-3-phenyl-4H-1,2,4-triazolato]iridium(III) (abbreviation: [Ir(iPrptz-3b)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) or tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpmi)₃]) or tris[3-(2,6-dimethylphenyl)-7-methylimidazo[1,2-f]phenanthridinato]iridium(III) (abbreviation: [Ir(dmpimpt-Me)₃]); and an organometallic iridium complex in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: [Ir(CF₃ppy)₂(pic)]), or bis[2-(4′,6′-difluorophenyl)pyridinato-N,C²′]iridium(III) acetylacetonate (abbreviation: FIr(acac)). These compounds exhibit blue phosphorescence and have an emission peak in the wavelength range of 440 nm to 520 nm.

Examples also include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²′)iridium(III) acetylacetonate (abbreviation: [Ir(pq)₂(acac)]), [2-d3-methyl-8-(2-pyridinyl-κN)benzofuro[2,3-b]pyridine-κC]bis[2-(5-d3-methyl-2-pyridinyl-κN2)phenyl-κC]iridium(III) (abbreviation: [Ir(5mppy-d3)₂(mbfpypy-d3)]), [2-(methyl-d3)-8-[4-(1-methylethyl-1-d)-2-pyridinyl-κNA]benzofuro2,[3-b]pyridin-7-yl-κC]bis[5-(methyl-d3)-2-[5-(methyl-d3)-2-pyridinyl-κN]phenyl-κC]iridium(III) (abbreviation: Ir(5mtpy-d6)₂(mbfpypy-iPr-d4)), [2-d3-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d3)), or [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); and a rare earth metal complex such as tris(acetylacetonato)(monophenanthroline)terbium(III) (abbreviation: [Tb(acac)₃(Phen)]). These are mainly compounds that exhibit green phosphorescence and have an emission peak in the wavelength range of 500 nm to 600 nm. Note that organometallic iridium complexes having a pyrimidine skeleton have distinctively high reliability or emission efficiency and thus are particularly preferable.

Other examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato) (dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C²′)iridium(III) (abbreviation: [Ir(piq)₃]) or bis(1-phenylisoquinolinato-N,C²′)iridium(III) acetylacetonate (abbreviation: [Ir(piq)₂(acac)]); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato) (monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These compounds exhibit red phosphorescence and have an emission peak in the wavelength range of 600 nm to 700 nm. Furthermore, from the organometallic iridium complex having a pyrazine skeleton, red light emission with favorable chromaticity can be obtained.

Besides the above phosphorescent compounds, known phosphorescent compounds may be selected and used.

As a TADF material, a fullerene, a derivative thereof, an acridine, a derivative thereof, an eosin derivative, or the like can be used. Other examples include a metal-containing porphyrin containing magnesium (Mg), zinc (Zn), cadmium (Cd), tin (Sn), platinum (Pt), indium (In), palladium (Pd), or the like. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

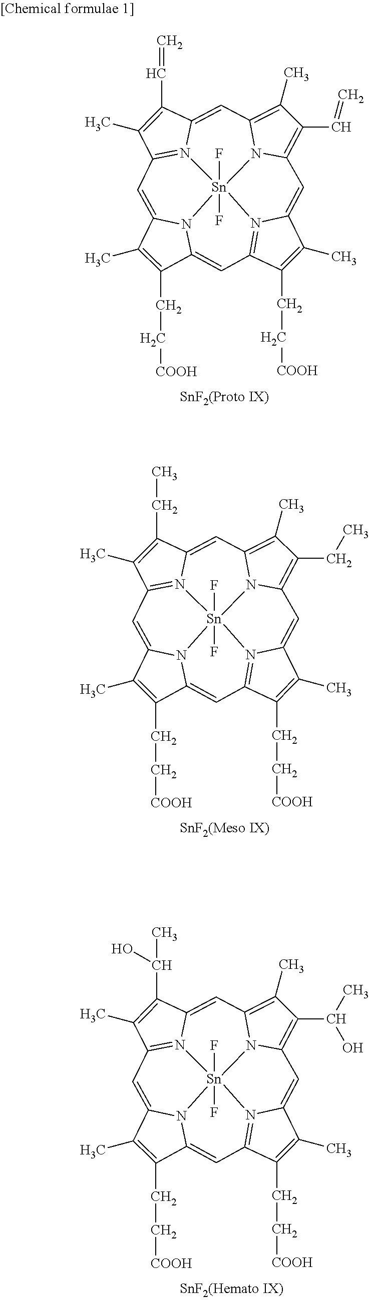

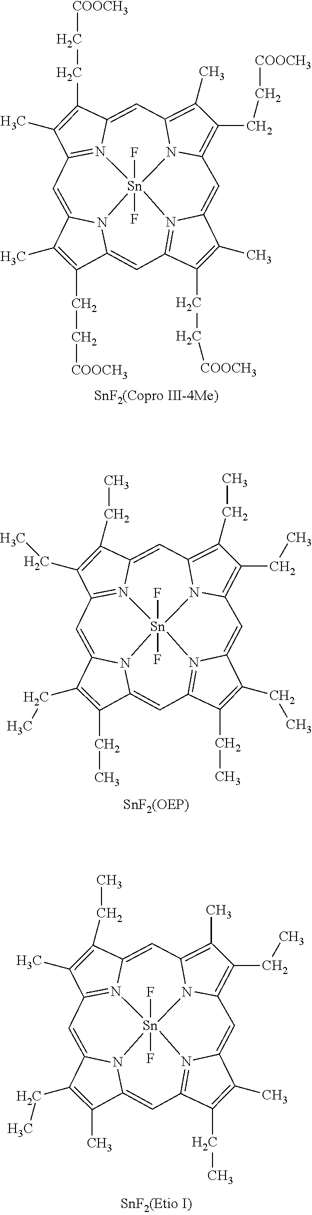

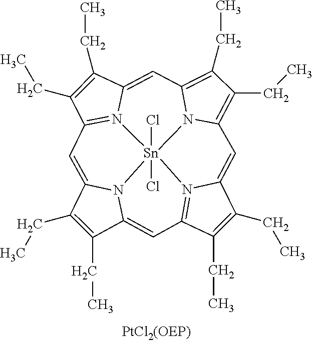

Alternatively, a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 9-[4-(4,6-diphenyl-1,3,5-triazin-2-yl)phenyl]-9′-phenyl-9H,9′H-3,3′-bicarbazole (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport property and hole-transport property owing to a π-electron rich heteroaromatic ring and a π-electron deficient heteroaromatic ring. Among skeletons having a π-electron deficient heteroaromatic ring, a pyridine skeleton, a diazine skeleton (a pyrimidine skeleton, a pyrazine skeleton, and a pyridazine skeleton), and a triazine skeleton are particularly preferable because of their stability and favorable reliability. In particular, a benzofuropyrimidine skeleton, a benzothienopyrimidine skeleton, a benzofuropyrazine skeleton, and a benzothienopyrazine skeleton are preferable because of their high acceptor property and favorable reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

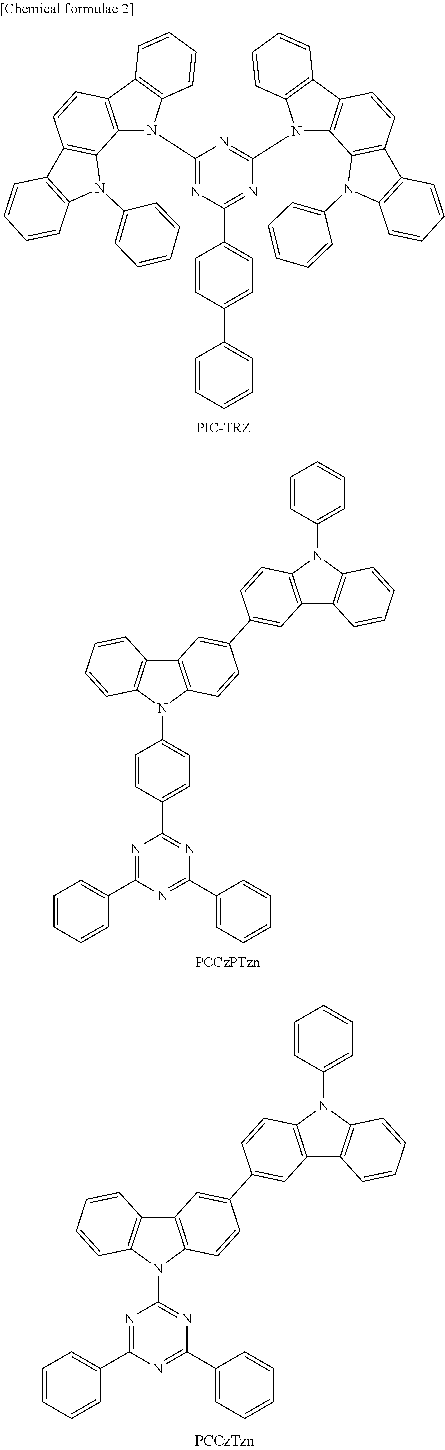 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

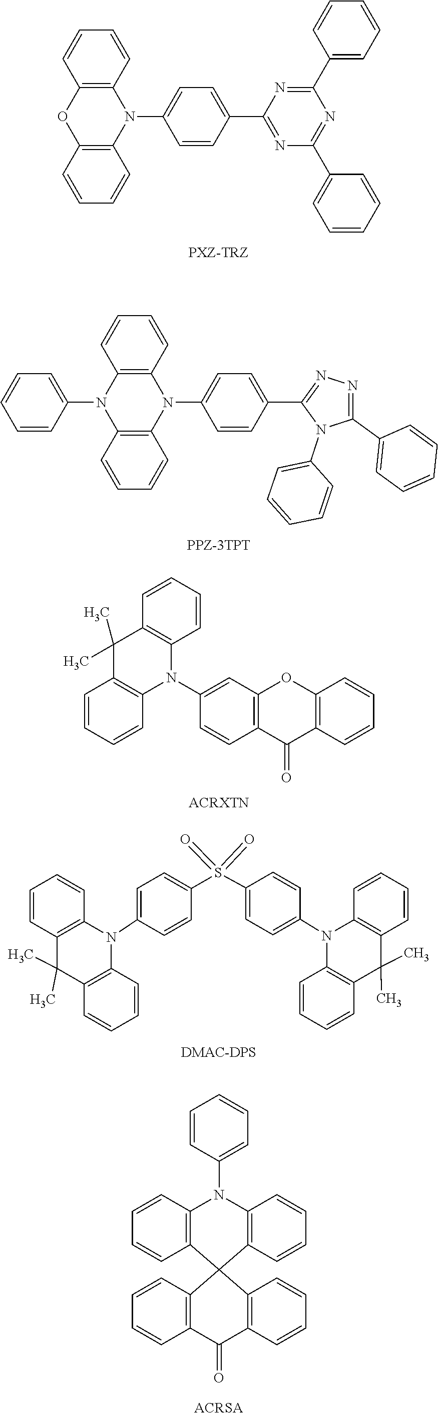

Note that the TADF material is a material that has a small difference between the S1 level and the T1 level and has a function of converting triplet excitation energy into singlet excitation energy by reverse intersystem crossing. Thus, it is possible to upconvert triplet excitation energy into singlet excitation energy (reverse intersystem crossing) using a little thermal energy and to efficiently generate a singlet excited state. In addition, the triplet excitation energy can be converted into luminescence.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than that of the TADF material. In addition, the T1 level of the host material is preferably higher than that of the TADF material.

As the host material in the light-emitting layer, various carrier-transport materials such as materials having an electron-transport property, materials having a hole-transport property, and the above-described TADF materials can be used.

The material having a hole-transport property is preferably an organic compound having an amine skeleton or a π-electron rich heteroaromatic ring skeleton. Examples of the substance include compounds having an aromatic amine skeleton such as 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBAIBP), 4,4′-diphenyl-4″-(9-phenyl-9H-carbazol-3-yl)triphenylamine (abbreviation: PCBBiiBP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]spiro-9,9′-bifluoren-2-amine9H (abbreviation: PCBASF); compounds having a carbazole skeleton such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), and 3,3′-bis(9-phenyl-9H-carbazole) (abbreviation: PCCP); compounds having a thiophene skeleton such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer 112 can also be used.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferable. Examples of the organic compound including a π-electron deficient heteroaromatic ring include organic compounds including a heteroaromatic ring having a polyazole skeleton, such as 2-(4-biphenylyl)-5-(4-tert-butyl-phenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), and 2-[3-(dibenzothiophen-4-yl)phenyl]-1-phenyl-1H-benzimidazole (abbreviation: mDBTBIm-II); organic compounds including a heteroaromatic ring having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 2,6-bis(4-naphthalen-1-ylphenyl)-4-[4-(3-pyridyl)phenyl]pyrimidine (abbreviation: 2,4NP-6PyPPm), 6-(1,1′-biphenyl-3-yl)-4-[3,5-bis(9H-carbazol-9-yl)phenyl)-2-phenylpyrimidine (abbreviation: 6mBP-4Cz2PPm), 4-[3,5-bis(9H-carbazol-9-yl) phenyl]-2-phenyl-6-(1,1′-biphenyl-4-yl)pyrimidine (abbreviation: 6BP-4Cz2PPm), and 7-[4-(9-phenyl-9H-carbazol-2-yl)quinazolin-2-yl]-7H-dibenzo[c,g]carbazole (abbreviation: PC-cgDBCzQz); organic compounds including a heteroaromatic ring having a pyridine skeleton, such as 3,5-bis[3-(9H-carbazol-9-yl)phenyl]pyridine (abbreviation: 35DCzPPy) and 1,3,5-tri[3-(3-pyridyl)-phenyl]benzene (abbreviation: TmPyPB); and organic compounds including a heteroaromatic ring having a triazine skeleton, such as 2-[3′-(9,9-dimethyl-9H-fluoren-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d] furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)-1,1′-biphenyl-3-yl]-4,6-diphenyl′-1,3,5-triazine (abbreviation: mTpBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 9-[4-(4,6-diphenyl-1,3,5-triazin-2-yl)-2-dibenzothiophenyl]-2-phenyl-9H-carbazole (abbreviation: PCDBfTzn), and 2-[1,1′-biphenyl]-3-yl-4-phenyl-6-(8-[1,1′:4′,1″-terphenyl]-4-yl-1-dibenzofuranyl)-1,3,5-triazine (abbreviation: mBP-TPDBfTzn). Among the above materials, the organic compound including a heteroaromatic ring having a diazine skeleton, the organic compound including a heteroaromatic ring having a pyridine skeleton, and the organic compound including a heteroaromatic ring having a triazine skeleton have high reliability and thus are preferable. In particular, the organic compound including a heteroaromatic ring having a diazine (pyrimidine or pyrazine) skeleton and the organic compound including a heteroaromatic ring having a triazine skeleton have a high electron-transport property to contribute to a reduction in driving voltage.

As the TADF material that can be used as the host material, the above-mentioned materials given as TADF materials can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. At this time, the TADF material functions as an energy donor, and the light-emitting substance functions as an energy acceptor.

This is very effective in the case where the light-emitting substance is a fluorescent substance. In that case, the S1 level of the TADF material is preferably higher than that of the fluorescent substance in order that high emission efficiency be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier transport performance, whereby the TADF material and the luminophore of the fluorescent substance can be distanced from each other with little influence on carrier transportation or carrier recombination. Here, the luminophore refers to an atomic group (skeleton) that causes light emission in a fluorescent substance. The luminophore is preferably a skeleton having a π bond, further preferably includes an aromatic ring, still further preferably includes a condensed aromatic ring or a condensed heteroaromatic ring. Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitable for the host material. The use of a substance having an anthracene skeleton as a host material for a fluorescent substance makes it possible to achieve a light-emitting layer with a favorable emission efficiency and durability. As the substance having an anthracene skeleton that is used as the host material, a substance having a diphenylanthracene skeleton, in particular, a substance having a 9,10-diphenylanthracene skeleton, is preferable because of its chemical stability. The host material preferably has a carbazole skeleton because the hole-injection and hole-transport properties are improved; further preferably, the host material has a benzocarbazole skeleton in which a benzene ring is further condensed to carbazole because the HOMO level thereof is shallower than that of carbazole by approximately 0.1 eV and thus holes enter the host material easily. In particular, the host material having a dibenzocarbazole skeleton is preferable because its HOMO level is shallower than that of carbazole by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)-benzo[b]naphtho[2,3-d]furan (abbreviation: Bnf(II)PhA), 9-(2-naphthyl)-10-[3-(2-naphthyl)phenyl]anthracene (abbreviation: ON-mPNPAnth), and 1-[4-(10-[1,1′-biphenyl]-4-yl-9-anthracenyl)phenyl]-2-ethyl-1H-benzimidazole (abbreviation: EtBImPBPhA). In particular, CzPA, cgDBCzPA2mBnfPPA, and PCzPA exhibit excellent properties and thus are preferably selected.

Note that a host material may be a material of a mixture of a plurality of kinds of substances; in the case of using a mixed host material, it is preferable to mix a material having an electron-transport property with a material having a hole-transport property. When the material having an electron-transport property is mixed with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, the phosphorescent substance can be used as an energy donor for supplying excitation energy to the fluorescent substance.

An exciplex may be formed by these mixed materials. A combination is preferably selected so as to form an exciplex that exhibits light emission overlapping with the wavelength of a lowest-energy-side absorption band of a light-emitting substance, because energy can be transferred smoothly and light emission can be efficiently obtained. The use of the structure is preferable because the driving voltage is also reduced.

Note that at least one of the materials forming an exciplex may be a phosphorescent substance. In this case, triplet excitation energy can be efficiently converted into singlet excitation energy by reverse intersystem crossing.

A combination of a material having an electron-transport property and a material having a hole-transport property whose HOMO level is higher than or equal to the HOMO level of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to a longer wavelength side than the emission spectrum of each of the materials (or has another peak on the longer wavelength side) observed in comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed in comparison of transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed in comparison of the transient EL of the material having a hole-transport property, the transient EL of the material having an electron-transport property, and the transient EL of the mixed film of these materials.

As described above, the electron-transport layer contains at least a heteroaromatic compound having a heteroaromatic ring and an organic compound different from the heteroaromatic compound. As at least one of these two materials, it is preferable to use an organic compound that has an electron-transport property and has an electron mobility of 1×10⁻⁶ cm²/Vs or higher when the square root of the electric field strength [V/cm] is 600. Note that other substances can be used as long as they have a property of transporting more electrons than holes. An organic compound including a π-electron deficient heteroaromatic ring is preferable as the above organic compound. The organic compound including a π-electron deficient heteroaromatic ring is preferably one or more of an organic compound including a heteroaromatic ring having a polyazole skeleton, an organic compound including a heteroaromatic ring having a pyridine skeleton, an organic compound including a heteroaromatic ring having a diazine skeleton, and an organic compound including a heteroaromatic ring having a triazine skeleton.

Specific examples of the organic compound that can be used for the above electron-transport layer include an organic compound including a heteroaromatic ring having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound including a heteroaromatic ring having a pyridine skeleton, such as 3,5-bis[3-(9H-carbazol-9-yl)phenyl]pyridine (abbreviation: 35DCzPPy) 1,3,5-tri[3-(3-pyridyl)phenyl]benzene (abbreviation: TmPyPB), 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: Bphen), bathocuproine (abbreviation: BCP), or 2,9-bis(naphthalen-2-yl)-4,7-diphenyl-1,10-phenanthroline (abbreviation: NBphen); an organic compound including a heteroaromatic ring having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[(3′-dibenzothiophen-4-yl)biphenyl-3-yl]naphtho[1′,2′:4,5]furo[2,3-b]pyrazine (abbreviation: 9mDBtBPNfpr), 9-[3′-dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(1,1′-biphenyl-3-yl)]naphtho[1′,2′:4,5]furo[3,2-d]pyrimidine (abbreviation: 8mDBtBPNfpm), 8-[(2,2′-binaphthalen)-6-yl)]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine} (abbreviation: 2,6(NP-PPm)2Py), 6-(1,1′-biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 6-(1,1′-biphenyl-3-yl)-4-[3,5-bis(9H-carbazol-9-yl)phenyl)-2-phenylpyrimidine (abbreviation: 6mBP-4Cz2PPm), 4-[3,5-bis(9H-carbazol-9-yl)phenyl]-2-phenyl-6-(1,1′-biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazol (abbreviation: PC-cgDBCzQz); and an organic compound including a heteroaromatic ring having a triazine skeleton, such as 2-[3′-(9,9-dimethyl-9H-fluoren-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)-1,1′-biphenyl-3-yl]-4,6-diphenyl-1,3,5-triazine (abbreviation: mFBPTzn), 5-[3-(4,6-diphenyl-1,3,5-triazin-2yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 5-[3-(4,6-diphenyl-1,3,5-triazine-2yl)pheny;]-7,7-dimethyl-5H,7H-indeno[2,1-b]carbazole (abbreviation: mINc(II)PTzn), 11-[4-[1,1′-niphenyl]-4-yl-6-phenyl-1,3,5-triazin-2-yl]-11,12-dihydro-12-phenyl-indolo[2,3-a]carbazole (abbreviation: BP-Icz(II)Tzn), 5-[3-(4,6-diphenyl-1,3,5-triazine-2-yl)phenyl-7,7-dimethyl-5H,7H-indeno[2,1-b]carbazole (abbreviation: mINc(II)PTzn), 2-[3′-(triphenylen-2-yl)-1,1′-biphenyl-3-yl]-4,6-diphenyl′1,3,5-triazine (abbreviation: mTpBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 9-[4-(4,6-diphenyl-1,3,5-triazin-2-yl)-2-dibenzothiophenyl]-2-phenyl-9H-carbazole (abbreviation: PCDBfTzn), or 2-[1,1′-biphenyl]-3-yl-4-phenyl-6-(8-[1,1′:4′,1″-terphenyl]-4-yl-1-dibenzofuranyl)-1,3,5-triazine (abbreviation: mBP-TPDBfTzn). Among the above materials, the organic compound including a heteroaromatic ring having a diazine skeleton, the organic compound including a heteroaromatic ring having a pyridine skeleton, and the organic compound including a heteroaromatic ring having a triazine skeleton have high reliability and thus are preferable. In particular, the organic compound including a heteroaromatic ring having a diazine (pyrimidine or pyrazine) skeleton and the organic compound including a heteroaromatic ring having a triazine skeleton have a high electron-transport property to contribute to a reduction in driving voltage.

Note that the above-described organic compounds that can be used for the electron-transport layer can each be used as both the heteroaromatic compound having the heteroaromatic ring included in the electron-transport layer or the electron-transport layer B and the organic compound different from the heteroaromatic compound.

As the organic compound different from the heteroaromatic compound, an organic compound other than those described above can be used but any of the above-described organic compounds that can be used for the electron-transport layer is preferably used. Note that the electron-transport layer 114 having this composition also serves as the electron-injection layer 115 in some cases.

A layer including an alkali metal, an alkaline earth metal, a compound thereof, or a complex thereof, such as lithium fluoride (LiF), cesium fluoride (CsF), calcium fluoride (CaF₂), or 8-hydroxyquinolinato-lithium (abbreviation: Liq) is preferably provided as the electron-injection layer 115 between the electron-transport layer 114 and the cathode 102. For example, an electride or a layer that is formed using a substance having an electron-transport property and that includes an alkali metal, an alkaline earth metal, or a compound thereof can be used as the electron-injection layer 115. Examples of the electride include a substance in which electrons are added at high concentration to a mixed oxide of calcium and aluminum.

Note that the intermediate layer used in the tandem light-emitting device is preferably a charge-generation layer. The charge-generation layer has a function of injecting electrons into one of the light-emitting units and injecting holes into the other thereof when voltage is applied to the anode and the cathode. The charge-generation layer injects electrons into the light-emitting unit A and holes into the light-emitting unit B when voltage is applied such that the potential of the anode becomes higher than the potential of the cathode.

The charge-generation layer includes at least a p-type layer. The P-type layer is preferably formed using the composite materials given above as the material that can form the hole-injection layer. The P-type layer may be formed by stacking a film containing the above acceptor material as a material included in the composite material and a film containing the above hole-transport material. When a potential is applied to the p-type layer, electrons and holes are injected into the electron-transport layer A of the light-emitting unit A and the hole-transport layer B of the light-emitting unit B, respectively, so that the light-emitting device is operated.

Note that one or both of an electron-relay layer and an electron-injection buffer layer are preferably provided in the charge-generation layer in addition to the P-type layer.

The electron-relay layer contains at least a substance having an electron-transport property and has a function of preventing an interaction between the electron-injection buffer layer and the p-type layer to smoothly transfer electrons. The LUMO level of the substance having an electron-transport property included in the electron-relay layer is preferably between the LUMO level of an acceptor substance in the P-type layer and the LUMO level of a substance included in a layer of the electron-transport layer in contact with the charge-generation layer. Specifically, the LUMO level of the substance having an electron-transport property in the electron-relay layer is preferably higher than or equal to −5.0 eV, further preferably higher than or equal to −5.0 eV and lower than or equal to −3.0 eV. Note that as the substance having an electron-transport property in the electron-relay layer, a phthalocyanine-based material or a metal complex having a metal-oxygen bond and an aromatic ligand is preferably used.

For the above electron-injection buffer layer, a substance having a high electron-injection property, such as an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)), can be used.

In the case where the electron-injection buffer layer is formed so as to include the substance having an electron-transport property and a donor substance, an organic compound such as tetrathianaphthacene (abbreviation: TTN), nickelocene, or decamethylnickelocene can be used as the donor substance, as well as an alkali metal, an alkaline earth metal, a rare earth metal, a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). Note that as the substance having an electron-transport property, a material similar to the above-described material forming the electron-transport layer 114 can be used for the formation.

The organic EL device having two light-emitting units is described with reference to FIG. 34; however, one embodiment of the present invention can also be applied to an organic EL device in which three or more light-emitting units are stacked. With a plurality of light-emitting units partitioned by the charge-generation layer between a pair of electrodes as in the light-emitting device of this embodiment, it is possible to provide a long-life element that can emit high-luminance light with a current density kept low. Moreover, a light-emitting apparatus that can be driven at a low voltage and has low power consumption can be achieved.

When the emission colors of the light-emitting units are different, light emission of a desired color can be obtained from the organic EL device as a whole. For example, in an organic EL device having two light-emitting units, the emission colors of the light-emitting unit A may be red and green and the emission color of the light-emitting unit B may be blue, so that the organic EL device can emit white light as the whole. When light emission of the same color is obtained from the light-emitting unit A and the light-emitting unit B, it is possible to obtain light emission with high luminance while the current density is kept low; thus, the element can have a long lifetime.

As a substance of the cathode 102, any of metals, alloys, and electrically conductive compounds with a low work function (specifically, lower than or equal to 3.8 eV), mixtures thereof, and the like can be used. Specific examples of such a cathode material include elements belonging to Group 1 and Group 2 of the periodic table, such as alkali metals (e.g., lithium (Li) and cesium (Cs)), magnesium (Mg), calcium (Ca), and strontium (Sr), alloys containing these elements (e.g., MgAg and AlLi), rare earth metals such as europium (Eu) and ytterbium (Yb), and alloys containing these rare earth metals. However, when the electron-injection layer is provided between the cathode 102 and the electron-transport layer, any of a variety of conductive materials such as Al, Ag, ITO, or indium oxide-tin oxide containing silicon or silicon oxide can be used for the cathode 102 regardless of the work function.

Films of these conductive materials can be formed by a dry process such as a vacuum evaporation method or a sputtering method, an ink-jet method, a spin coating method, or the like. Alternatively, the films may be formed by a wet process using a sol-gel method or a wet process using a paste of a metal material.

Various methods can be used as a method for forming the EL layer 103 regardless of whether it is a dry process or a wet process. For example, a vacuum evaporation method, a gravure printing method, an offset printing method, a screen printing method, an ink-jet method, a spin coating method, or the like may be used.

Different deposition methods may be used to form the electrodes or the layers described above.

The structure of the layers provided between the anode 101 and the cathode 102 is not limited to the above-described structure. Preferably, a light-emitting region where holes and electrons recombine is positioned away from the anode 101 and the cathode 102 so as to inhibit quenching due to the proximity of the light-emitting region and a metal used for electrodes or carrier-injection layers.

Furthermore, in order that transfer of energy from an exciton generated in the light-emitting layer can be inhibited, preferably, the hole-transport layer or the electron-transport layer, which is in contact with the light-emitting layer 113, particularly a carrier-transport layer closer to the recombination region in the light-emitting layer 113, is preferably formed using a substance having a wider band gap than the light-emitting material of the light-emitting layer or the light-emitting material included in the light-emitting layer. This embodiment can be freely combined with the other embodiments.

### Embodiment 2

In this embodiment, structure examples of display devices of one embodiment of the present invention are described.

The display device in this embodiment can be a high-definition display device or a large-sized display device. Accordingly, the display device in this embodiment can be used for display portions of electronic devices such as a digital camera, a digital video camera, a digital photo frame, a mobile phone, a portable game machine, a smartphone, a watch-type terminal, a tablet terminal, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Device 400A]

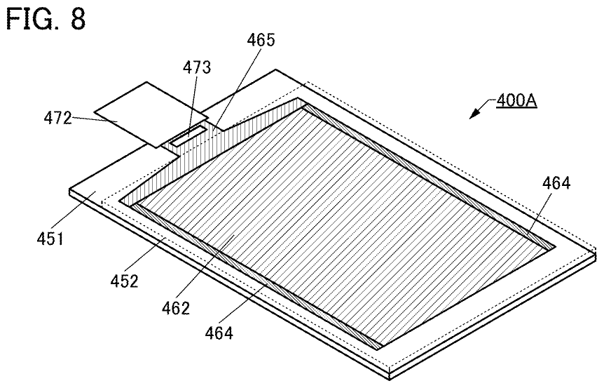

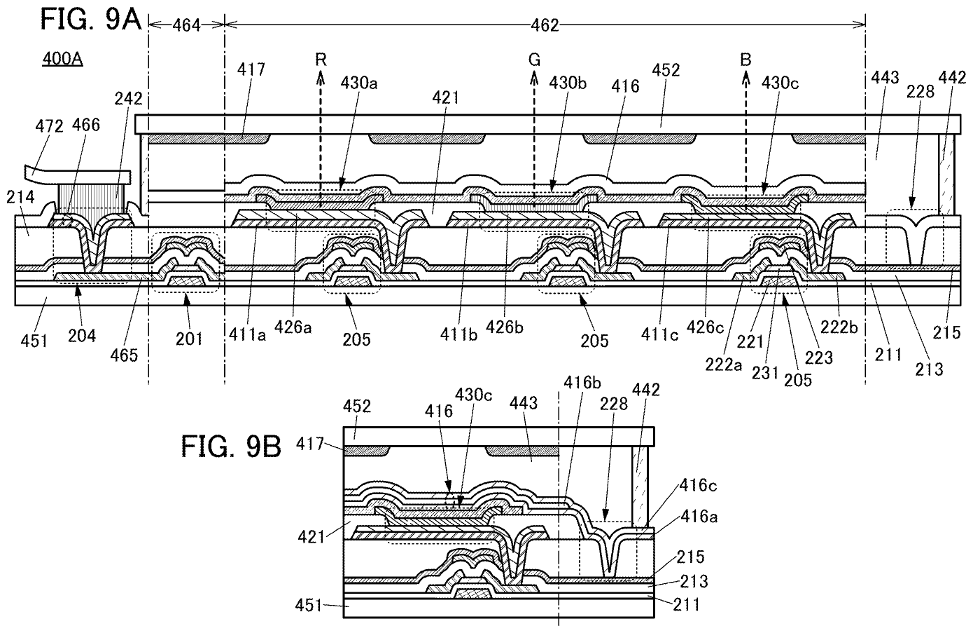

FIG. 8 is a perspective view of a display device 400A, and FIG. 9A is a cross-sectional view of the display device 400A.

The display device 400A has a structure in which a substrate 452 and a substrate 451 are bonded to each other. In FIG. 9, the substrate 452 is denoted by a dashed line.

The display device 400A includes a display portion 462, a circuit 464, a wiring 465, and the like. FIG. 9 illustrates an example in which an IC 473 and an FPC 472 are mounted on the display device 400A. Thus, the structure illustrated in FIG. 9 can be regarded as a display module including the display device 400A, the IC (integrated circuit), and the FPC.

As the circuit 464, a scan line driver circuit can be used, for example.

The wiring 465 has a function of supplying a signal and power to the display portion 462 and the circuit 464. The signal and power are input to the wiring 465 from the outside through the FPC 472 or input to the wiring 465 from the IC 473.

FIG. 9 illustrates an example in which the IC 473 is provided over the substrate 451 by a COG (Chip On Glass) method, a COF (Chip on Film) method, or the like. An IC including a scan line driver circuit, a signal line driver circuit, or the like can be used as the IC 473, for example. Note that the display device 400A and the display module are not necessarily provided with an IC. The IC may be mounted on the FPC by a COF method or the like.

FIG. 9A illustrates an example of cross sections of part of a region including the FPC 472, part of the circuit 464, part of the display portion 462, and part of a region including an edge portion of the display device 400A.

The display device 400A illustrated in FIG. 9A includes a transistor 201, a transistor 205, a light-emitting device 430a that emits red light, a light-emitting device 430b that emits green light, a light-emitting device 430c that emits blue light, and the like between the substrate 451 and the substrate 452.

The light-emitting device described in Embodiment 1 can be used as the light-emitting device 430a, the light-emitting device 430b, and the light-emitting device 430c.

In the case where a pixel of the display device includes three kinds of subpixels including light-emitting devices emitting different colors from each other, the three subpixels can be of three colors of R, G, and B or of three colors of yellow (Y), cyan (C), and magenta (M). In the case where four subpixels are included, the four subpixels can be of four colors of R, G, B, and white (W) or of four colors of R, G, B, and Y.

A protective layer 416 and the substrate 452 are bonded to each other with an adhesive layer 442. A solid sealing structure, a hollow sealing structure, or the like can be employed to seal the light-emitting devices. In FIG. 9A, a hollow sealing structure is employed in which a space 443 surrounded by the substrate 452, the adhesive layer 442, and the substrate 451 is filled with an inert gas (e.g., nitrogen or argon). The adhesive layer 442 may be provided to overlap with the light-emitting device. The space 443 surrounded by the substrate 452, the adhesive layer 442, and the substrate 451 may be filled with a resin different from that of the adhesive layer 442.

The light-emitting devices 430a, 430b, and 430c each include an optical adjustment layer between a pixel electrode and an EL layer. The light-emitting device 430a includes an optical adjustment layer 426a, the light-emitting device 430b includes an optical adjustment layer 426b, and the light-emitting device 430c includes an optical adjustment layer 426c. Refer to Embodiment 1 for the details of the light-emitting devices.

Pixel electrodes 411a, 411b, and 411c are each connected to a conductive layer 222b included in the transistor 205 through an opening provided in an insulating layer 214.

The edge portions of the pixel electrodes and the optical adjustment layers are covered with an insulating layer 421. The pixel electrodes each contain a material that reflects visible light, and a counter electrode contains a material that transmits visible light.

Light from the light-emitting device is emitted toward the substrate 452 side. For the substrate 452, a material having a high visible-light-transmitting property is preferably used.

The transistor 201 and the transistor 205 are formed over the substrate 451. These transistors can be fabricated using the same material in the same step.

An insulating layer 211, an insulating layer 213, an insulating layer 215, and the insulating layer 214 are provided in this order over the substrate 451. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This is because such an insulating layer can function as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

Here, an organic insulating film often has a lower barrier property than an inorganic insulating film. Therefore, the organic insulating film preferably has an opening in the vicinity of the edge portion of the display device 400A. This can inhibit entry of impurities from the edge portion of the display device 400A through the organic insulating film. Alternatively, the organic insulating film may be formed such that its edge portion is positioned inward from the edge portion of the display device 400A, to prevent the organic insulating film from being exposed at the end edge of the display device 400A.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

In a region 228 illustrated in FIG. 9A, an opening is formed in the insulating layer 214. This can inhibit entry of impurities into the display portion 462 from the outside through the insulating layer 214 even when an organic insulating film is used as the insulating layer 214. Consequently, the reliability of the display device 400A can be increased.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device in this embodiment. For example, a planar transistor, a staggered transistor, or an inverted staggered transistor can be used. A top-gate or bottom-gate transistor structure can be used. Alternatively, gates may be provided above and below a semiconductor layer where a channel is formed.

The structure in which the semiconductor layer where a channel is formed is provided between two gates is used for the transistor 201 and the transistor 205. The two gates may be connected to each other and supplied with the same signal to operate the transistor. Alternatively, the threshold voltage of the transistor may be controlled by supplying a potential for controlling the threshold voltage to one of the two gates and a potential for driving to the other.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be inhibited.

It is preferable that a semiconductor layer of a transistor contain a metal oxide (also referred to as an oxide semiconductor). That is, a transistor using a metal oxide in its channel formation region (hereinafter, an OS transistor) is preferably used for the display device in this embodiment. Alternatively, a semiconductor layer of a transistor may contain silicon. Examples of silicon include amorphous silicon and crystalline silicon (e.g., low-temperature polysilicon or single crystal silicon).

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used as the semiconductor layer.

When the semiconductor layer is an In-M-Zn oxide, the atomic ratio of In is preferably greater than or equal to the atomic ratio of Min the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

The transistor included in the circuit 464 and the transistor included in the display portion 462 may have the same structure or different structures. A plurality of transistors included in the circuit 464 may have the same structure or two or more kinds of structures. Similarly, a plurality of transistors included in the display portion 462 may have the same structure or two or more kinds of structures.

A connection portion 204 is provided in a region of the substrate 451 that does not overlap with the substrate 452. In the connection portion 204, the wiring 465 is electrically connected to the FPC 472 through a conductive layer 466 and a connection layer 242. An example is illustrated in which the conductive layer 466 has a stacked-layer structure of a conductive film obtained by processing the same conductive film as the pixel electrode and a conductive film obtained by processing the same conductive film as the optical adjustment layer. On the top surface of the connection portion 204, the conductive layer 466 is exposed. Thus, the connection portion 204 and the FPC 472 can be electrically connected to each other through the connection layer 242.

A light-blocking layer 417 is preferably provided on the surface of the substrate 452 on the substrate 451 side. A variety of optical members can be arranged on the outer side of the substrate 452. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided on the outer side of the substrate 452.

Providing the protective layer 416 covering the light-emitting devices inhibits entry of impurities such as water into the light-emitting devices; as a result, the reliability of the light-emitting devices can be increased.

In the region 228 in the vicinity of the edge portion of the display device 400A, the insulating layer 215 and the protective layer 416 are preferably in contact with each other through an opening in the insulating layer 214. In particular, the inorganic insulating film included in the insulating layer 215 and the inorganic insulating film included in the protective layer 416 are preferably in contact with each other. This can inhibit entry of impurities into the display portion 462 from the outside through the organic insulating film. Consequently, the reliability of the display device 400A can be increased.

FIG. 9B illustrates an example in which the protective layer 416 has a three-layer structure. In FIG. 9B, the protective layer 416 includes an inorganic insulating layer 416a over the light-emitting device 430c, an organic insulating layer 416b over the inorganic insulating layer 416a, and an inorganic insulating layer 416c over the organic insulating layer 416b.

The edge portion of the inorganic insulating layer 416a and the edge portion of the inorganic insulating layer 416c extend beyond the edge portion of the organic insulating layer 416b and are in contact with each other. The inorganic insulating layer 416a is in contact with the insulating layer 215 (inorganic insulating layer) through the opening in the insulating layer 214 (organic insulating layer). Accordingly, the light-emitting device can be surrounded by the insulating layer 215 and the protective layer 416, whereby the reliability of the light-emitting device can be increased.

As described above, the protective layer 416 may have a stacked-layer structure of an organic insulating film and an inorganic insulating film. In that case, the edge portions of the inorganic insulating films preferably extend beyond the edge portion of the organic insulating film.

For each of the substrate 451 and the substrate 452, glass, quartz, ceramics, sapphire, a resin, a metal, an alloy, a semiconductor, or the like can be used. The substrate on the side from which light from the light-emitting device is extracted is formed using a material that transmits the light. When the substrate 451 and the substrate 452 are formed using a flexible material, the flexibility of the display device can be increased. Furthermore, a polarizing plate may be used as the substrate 451 or the substrate 452.

For each of the substrate 451 and the substrate 452, it is possible to use a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like. Glass that is thin enough to have flexibility may be used for one or both of the substrate 451 and the substrate 452.

In the case where a circularly polarizing plate overlaps with the display device, a highly optically isotropic substrate is preferably used as the substrate included in the display device. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display panel might be changed, e.g., creases are generated. Thus, for the substrate, a film with a low water absorption rate is preferably used. For example, the water absorption rate of the film is preferably 1% or lower, further preferably 0.1% or lower, still further preferably 0.01% or lower.

As the adhesive layer, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-component resin may be used. An adhesive sheet or the like may be used.

As the connection layer 242, an anisotropic conductive film (ACF), an anisotropic conductive paste (ACP), or the like can be used.

As materials for the gates, the source, and the drain of a transistor and conductive layers such as a variety of wirings and electrodes included in the display device, any of metals such as aluminum, titanium, chromium, nickel, copper, yttrium, zirconium, molybdenum, silver, tantalum, and tungsten, or an alloy containing any of these metals as its main component can be used. A single-layer structure or a stacked-layer structure including a film containing any of these materials can be used.

As a light-transmitting conductive material, a conductive oxide such as indium oxide, an indium tin oxide, an indium zinc oxide, zinc oxide, or zinc oxide containing gallium, or graphene can be used. It is also possible to use a metal material such as gold, silver, platinum, magnesium, nickel, tungsten, chromium, molybdenum, iron, cobalt, copper, palladium, or titanium; or an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to transmit light. Alternatively, a stacked film of any of the above materials can be used for the conductive layers. For example, a stacked film of an indium tin oxide and an alloy of silver and magnesium is preferably used because conductivity can be increased. They can also be used for conductive layers such as a variety of wirings and electrodes included in the display device, and conductive layers (e.g., conductive layers functioning as the pixel electrode and the common electrode) included in the light-emitting device.

Examples of insulating materials that can be used for the insulating layers include resins such as an acrylic resin and an epoxy resin, and inorganic insulating materials such as silicon oxide, silicon oxynitride, silicon nitride oxide, silicon nitride, and aluminum oxide.

### [Display Device 400B]

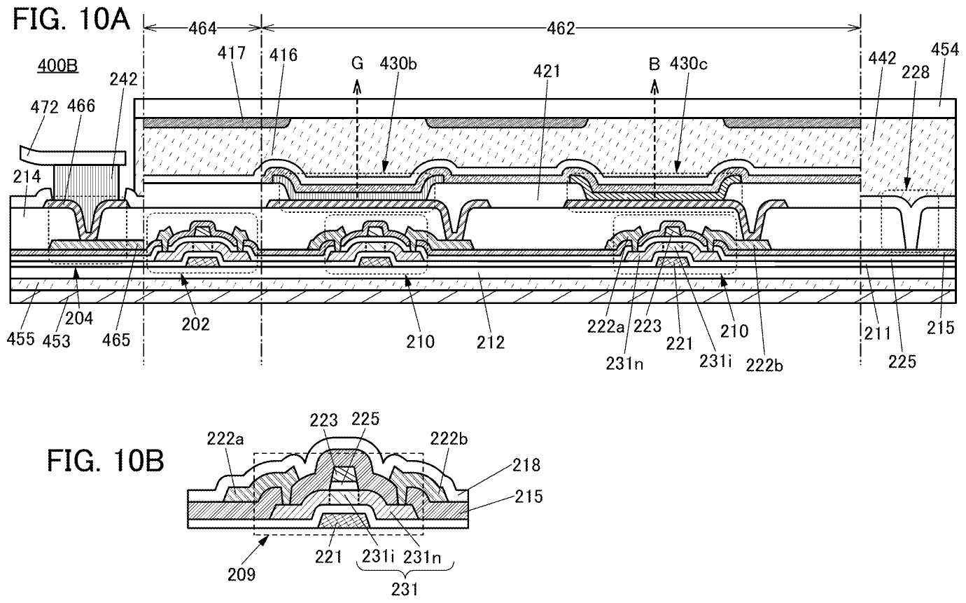

FIG. 10A is a cross-sectional view of a display device 400B. A perspective view of the display device 400B is similar to that of the display device 400A (FIG. 8). FIG. 10A illustrates an example of cross sections of part of a region including the FPC 472, part of the circuit 464, and part of the display portion 462 in the display device 400B. FIG. 10A specifically illustrates an example of a cross section of a region including the light-emitting device 430b emitting green light and the light-emitting device 430c emitting blue light in the display portion 462. Note that portions similar to those in the display device 400A are not described in some cases.

The display device 400B illustrated in FIG. 10A includes a transistor 202, transistors 210, the light-emitting device 430b, the light-emitting device 430c, and the like between a substrate 453 and a substrate 454.

The substrate 454 and the protective layer 416 are bonded to each other with the adhesive layer 442. The adhesive layer 442 is provided to overlap with the light-emitting device 430b and the light-emitting device 430c, and the display device 400B employs a solid sealing structure.

The substrate 453 and an insulating layer 212 are bonded to each other with an adhesive layer 455.

As a method of fabricating the display device 400B, first, a formation substrate provided with the insulating layer 212, the transistors, the light-emitting devices, and the like and the substrate 454 provided with the light-blocking layer 417 are bonded to each other with the adhesive layer 442. Then, the substrate 453 is attached to a surface exposed by separation of the formation substrate, whereby the components formed over the formation substrate are transferred to the substrate 453. The substrate 453 and the substrate 454 are preferably flexible. Accordingly, the display device 400B can be highly flexible.

The inorganic insulating film that can be used as the insulating layer 211, the insulating layer 213, and the insulating layer 215 can be used as the insulating layer 212

The pixel electrode is connected to the conductive layer 222b included in the transistor 210 through the opening provided in the insulating layer 214. The conductive layer 222b is connected to a low-resistance region 231n through an opening provided in the insulating layer 215 and an insulating layer 225. The transistor 210 has a function of controlling the driving of the light-emitting device.

The edge portion of the pixel electrode is covered with the insulating layer 421.

Light from the light-emitting devices 430b and 430c is emitted toward the substrate 454 side. For the substrate 454, a material having a high visible-light-transmitting property is preferably used.

The connection portion 204 is provided in a region of the substrate 453 that does not overlap with the substrate 454. In the connection portion 204, the wiring 465 is electrically connected to the FPC 472 through the conductive layer 466 and the connection layer 242. The conductive layer 466 can be obtained by processing the same conductive film as the pixel electrode. Thus, the connection portion 204 and the FPC 472 can be electrically connected to each other through the connection layer 242.

The transistor 202 and the transistor 210 each include the conductive layer 221 functioning as a gate, the insulating layer 211 functioning as a gate insulating layer, a semiconductor layer including a channel formation region 231i and a pair of low-resistance regions 231n, the conductive layer 222a connected to one of the pair of low-resistance regions 231n, the conductive layer 222b connected to the other of the pair of low-resistance regions 231n, the insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the corresponding low-resistance regions 231n through openings provided in the insulating layer 215. One of the conductive layer 222a and the conductive layer 222b functions as a source, and the other functions as a drain.

FIG. 10A illustrates an example in which the insulating layer 225 covers the top and side surfaces of the semiconductor layer. The conductive layer 222a and the conductive layer 222b are connected to the corresponding low-resistance regions 231n through openings provided in the insulating layer 225 and the insulating layer 215.

In a transistor 209 illustrated in FIG. 10B, the insulating layer 225 overlaps with the channel formation region 231i of the semiconductor layer 231 and does not overlap with the low-resistance regions 231n. The structure illustrated in FIG. 10B is obtained by processing the insulating layer 225 with the conductive layer 223 as a mask, for example. In FIG. 10B, the insulating layer 215 is provided to cover the insulating layer 225 and the conductive layer 223, and the conductive layer 222a and the conductive layer 222b are connected to the corresponding low-resistance regions 231n through the openings in the insulating layer 215. Furthermore, an insulating layer 218 covering the transistor may be provided

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 3

In this embodiment, a structure example of a display device different from those described above will be described.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on the head, such as a VR device like a head-mounted display and a glasses-type AR device.

### [Display Module]

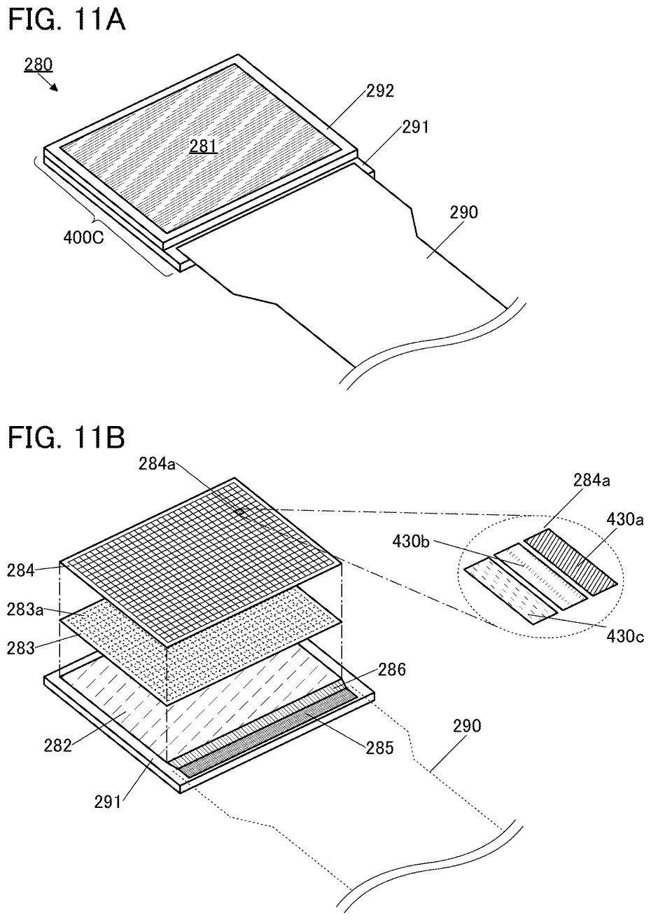

FIG. 11A is a perspective view of a display module 280. The display module 280 includes a display device 400C and an FPC 290. Note that the display device included in the display module 280 is not limited to the display device 400C and may be a display device 400D or a display device 400E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 11B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion that is over the substrate 291 and does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 11B. The pixel 284a includes the light-emitting devices 430a, 430b, and 430c that emit light of different colors from each other. The plurality of light-emitting devices may be arranged in a stripe arrangement as illustrated in FIG. 11B. With the stripe arrangement that enables high-density arrangement of pixel circuits, a high-resolution display device can be provided. Alternatively, a variety of arrangement methods, such as delta arrangement and PenTile arrangement, can be employed.

The pixel circuit portion 283 includes a plurality of pixel circuits 283a arranged periodically.

One pixel circuit 283a is a circuit that controls light emission of three light-emitting devices included in one pixel 284a. One pixel circuit 283a may be provided with three circuits each of which controls light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to one of a source and a drain of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head-mounted display or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device such as a watch.

### [Display Device 400C]

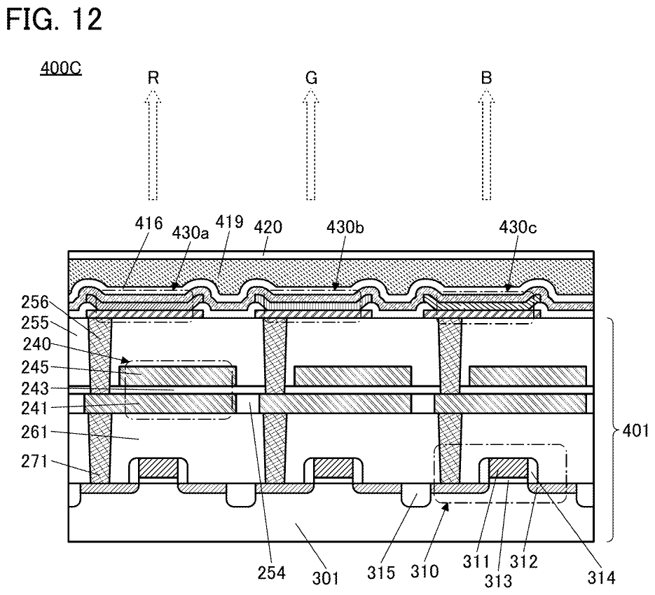

The display device 400C illustrated in FIG. 12 includes a substrate 301, the light-emitting devices 430a, 430b, and 430c, a capacitor 240, and a transistor 310.

The substrate 301 corresponds to the substrate 291 in FIG. 11A and FIG. 11B. A stacked-layer structure including the substrate 301 and the components thereover up to an insulating layer 255 corresponds to the substrate 100 and the insulating layer 120 in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and function as a source and a drain. The insulating layer 314 is provided to cover the side surface of the conductive layer 311 and functions as an insulating layer.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

The insulating layer 255 is provided to cover the capacitor 240, and the light-emitting devices 430a, 430b, and 430c and the like are provided over the insulating layer 255. The protective layer 416 is provided over the light-emitting devices 430a, 430b, and 430c, and a substrate 420 is bonded to the top surface of the protective layer 416 with a resin layer 419.

The pixel electrode of the light-emitting device is electrically connected to one of the source and the drain of the transistor 310 through a plug 256 embedded in the insulating layer 255, the conductive layer 241 embedded in the insulating layer 254, and the plug 271 embedded in the insulating layer 261.

### [Display Device 400D]

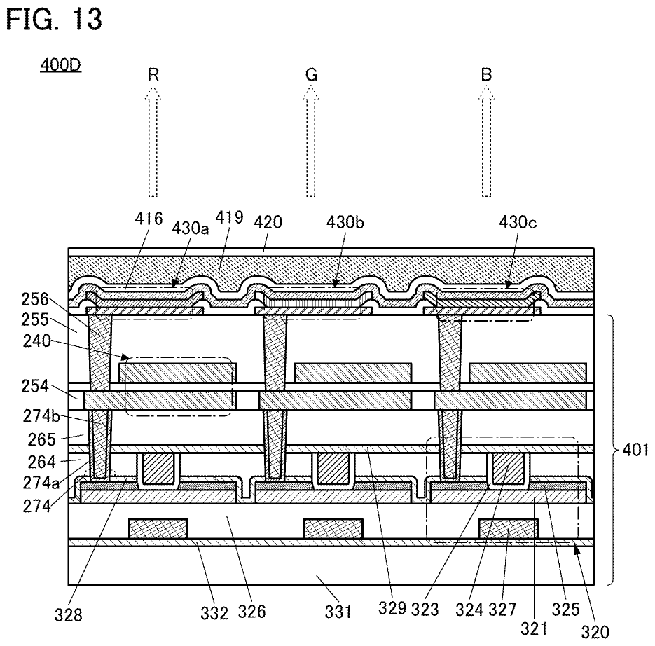

The display device 400D illustrated in FIG. 13 differs from the display device 400C mainly in a structure of a transistor. Note that portions similar to those in the display device 400C are not described in some cases.

A transistor 320 is a transistor that contains a metal oxide (also referred to as an oxide semiconductor) in a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 11A and FIG. 11B. A stacked-layer structure 401 including the substrate 331 and the components thereover up to the insulating layer 255 corresponds to a layer including a transistor in Embodiment 1. As the substrate 331, an insulating substrate or a semiconductor substrate can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film through which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. A material that can be suitably used for the semiconductor layer 321 will be described in detail later.

The pair of conductive layers 325 are provided over and in contact with the semiconductor layer 321 and function as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water and hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material through which hydrogen and oxygen are less likely to diffuse is preferably used for the conductive layer 274a.

The structures of the insulating layer 254 and the components thereover up to the substrate 420 in the display device 400D are similar to those in the display device 400C.

### [Display Device 400E]

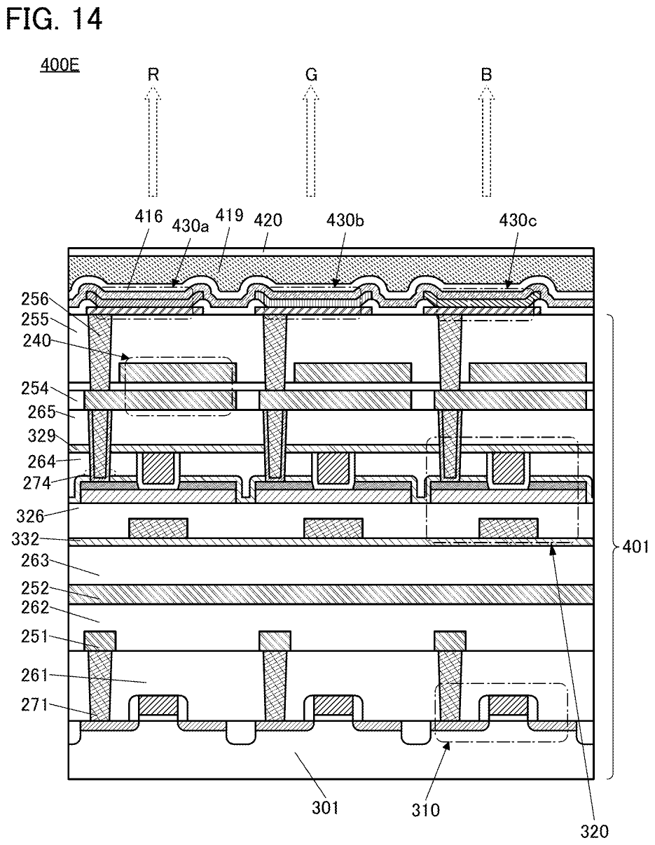

The display device 400E illustrated in FIG. 14 has a structure in which the transistor 310 whose channel is formed in the substrate 301 and the transistor 320 including a metal oxide in the semiconductor layer where the channel is formed are stacked. Note that portions similar to those in the display devices 400C and 400D are not described in some cases.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display device can be downsized as compared with the case where a driver circuit is provided around a display region.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 5

In this embodiment, a high-resolution display device is described.

### [Structure Example of Pixel Circuit]

An example of a pixel suitable for a high-resolution display device and an arrangement method thereof are described below.

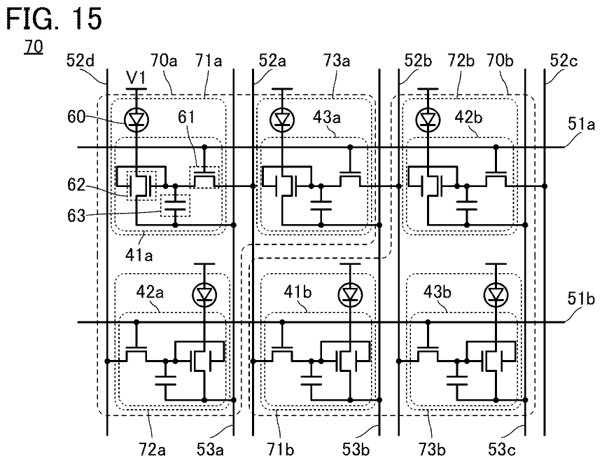

FIG. 15A illustrates an example of a circuit diagram of a pixel unit 70. The pixel unit 70 is composed of two pixels (a pixel 70a and a pixel 70b). In addition, the pixel unit 70 is connected to a wiring 51a, a wiring 51b, a wiring 52a, a wiring 52b, a wiring 52c, a wiring 52d, a wiring 53a, a wiring 53b, and a wiring 53c and the like.

The pixel 70a includes a subpixel 71a, a subpixel 72a, and a subpixel 73a. The pixel 70b includes a subpixel 71b, a subpixel 72b, and a subpixel 73b. The subpixel 71a, the subpixel 72a, and the subpixel 73a include a pixel circuit 41a, a pixel circuit 42a, and a pixel circuit 43a, respectively. The subpixel 71b, the subpixel 72b, and the subpixel 73b include a pixel circuit 41b, a pixel circuit 42b, and a pixel circuit 43b, respectively.

Each subpixel includes the pixel circuit and a display element 60. For example, the subpixel 71a includes the pixel circuit 41a and the display element 60. A light-emitting device such as an organic EL element is used here as the display element 60.

The wiring 51a and the wiring 51b each function as a gate line. The wiring 52a, the wiring 52b, the wiring 52c, and the wiring 52d each function as a signal line (also referred to as a data line). The wiring 53a, the wiring 53b, and the wiring 53c each have a function of supplying a potential to the display element 60.

The pixel circuit 41a is electrically connected to the wiring 51a, the wiring 52a, and the wiring 53a. The pixel circuit 42a is electrically connected to the wiring 51b, the wiring 52d, and the wiring 53a. The pixel circuit 43a is electrically connected to the wiring 51a, the wiring 52b, and the wiring 53b. The pixel circuit 41b is electrically connected to the wiring 51b, the wiring 52a, and the wiring 53b. The pixel circuit 42b is electrically connected to the wiring 51a, the wiring 52c, and the wiring 53c. The pixel circuit 43b is electrically connected to the wiring 51b, the wiring 52b, and the wiring 53c.

With the structure illustrated in FIG. 15 in which two gate lines are connected to one pixel, the number of source lines can be conversely reduced by half as compared with that in a stripe arrangement. As a result, the number of terminals of the ICs used as source driver circuits can be reduced by half and the number of components can be reduced.

One wiring functioning as a signal line is preferably connected to pixel circuits corresponding to the same color. For example, when a signal with an adjusted potential is supplied to the wiring to correct for variation in luminance between pixels, the correction value may greatly vary between colors. Thus, when pixel circuits connected to one signal line are pixel circuits corresponding to the same color, the correction can be performed easily.

In addition, each pixel circuit includes a transistor 61, a transistor 62, and a capacitor 63. In the pixel circuit 41a, for example, a gate of the transistor 61 is electrically connected to the wiring 51a, one of a source and a drain of the transistor 61 is electrically connected to the wiring 52a, and the other of the source and the drain is electrically connected to a gate of the transistor 62 and one electrode of the capacitor 63. One of a source and a drain of the transistor 62 is electrically connected to one electrode of the display element 60, and the other of the source and the drain is electrically connected to the other electrode of the capacitor 63 and the wiring 53a. The other electrode of the display element 60 is electrically connected to a wiring to which a potential V1 is supplied.

Note that, as illustrated in FIG. 15, the other pixel circuits are similar to the pixel circuit 41a except for the wiring to which the gate of the transistor 61 is connected, the wiring to which one of the source and the drain of the transistor 61 is connected, and the wiring to which the other electrode of the capacitor 63 is connected.

In FIG. 15, the transistor 61 functions as a selection transistor. The transistor 62 is in a series connection with the display element 60 and has a function of controlling a current flowing into the display element 60. The capacitor 63 has a function of holding the potential of a node connected to the gate of the transistor 62. Note that the capacitor 63 does not have to be intentionally provided in the case where an off-state leakage current of the transistor 61, a leakage current through the gate of the transistor 62, and the like are extremely small.

The transistor 62 preferably includes a first gate and a second gate electrically connected to each other as illustrated in FIG. 15. This structure with the two gates can increase the amount of current that the transistor 62 can carry. Such a structure is particularly preferable for a high-resolution display device because the amount of current can be increased without increasing the size, the channel width in particular, of the transistor 62.

Note that the transistor 62 may have one gate. This structure eliminates the need for forming the second gate and thus can simplify the process as compared with the above structure. The transistor 61 may have two gates. This structure enables a reduction in size of each transistor. A first gate and a second gate of each transistor can be electrically connected to each other. Alternatively, one gate may be electrically connected to a different wiring. In this case, threshold voltages of the transistors can be controlled by varying potentials that are applied to the wirings.

One of a pair of electrodes of the display element 60 that is electrically connected to the transistor 62 corresponds to a pixel electrode. FIG. 5 illustrates a structure where an electrode of the display element 60 that is electrically connected to the transistor 62 is a cathode and the opposite electrode is an anode. This structure is particularly effective when the transistor 62 is an n-channel transistor. That is, when the transistor 62 is on, the potential applied through the wiring 53a is a source potential; accordingly, the amount of current flowing into the transistor 62 can be constant regardless of variation and change in resistance of the display element 60. Alternatively, a p-channel transistor may be used as a transistor of the pixel circuit.

### Embodiment 6

Described in this embodiment is a metal oxide (also referred to as an oxide semiconductor) that can be used in the OS transistor described in the above embodiment.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a chemical vapor deposition (CVD) method such as a metal organic chemical vapor deposition (MOCVD) method, an atomic layer deposition (ALD) method, or the like.

### <Classification of Crystal Structures>

Amorphous (including completely amorphous), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

A crystal structure of a film or a substrate can be evaluated with an X-ray diffraction (XRD) spectrum. For example, evaluation is possible using an XRD spectrum obtained by GIXD (Grazing-Incidence XRD) measurement. Note that a GIXD method is also referred to as a thin film method or a Seemann-Bohlin method.

For example, the XRD spectrum of a quartz glass substrate shows a peak with a substantially bilaterally symmetrical shape. On the other hand, the peak of the XRD spectrum of an IGZO film having a crystal structure has a bilaterally asymmetrical shape. The asymmetrical peak of the XRD spectrum clearly shows the existence of a crystal in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is suggested that the IGZO film deposited at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS will be described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element Mmay be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the grain boundary becomes a recombination center and traps carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Hence, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Hence, the orientation in the whole film is not observed. Accordingly, the nc-OS cannot be distinguished from an a-like OS or an amorphous oxide semiconductor by some analysis methods. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

[a-like OS]

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Composition of Oxide Semiconductor>>

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted with [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] and lower [Ga] than the second region. Moreover, the second region has higher [Ga] and lower [In] than the first region.

Specifically, the first region includes an indium oxide, an indium zinc oxide, or the like as its main component. The second region includes a gallium oxide, a gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of the oxygen gas to the total flow rate of the deposition gas in deposition is preferably as low as possible; for example, the ratio of the flow rate of the oxygen gas to the total flow rate of the deposition gas in deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (p) can be achieved.

The second region has a higher insulating property than the first region. In other words, when the second regions are distributed in a metal oxide, leakage current can be inhibited.

Thus, in the case where the CAC-OS is used for a transistor, a switching function (On/Off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using the CAC-OS has high reliability. Thus, the CAC-OS is most suitable for a variety of semiconductor devices such as display devices.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor having high reliability can be achieved.

An oxide semiconductor with a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurities>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor using an oxide semiconductor that contains an alkali metal or an alkaline earth metal tends to have normally-on characteristics. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 7

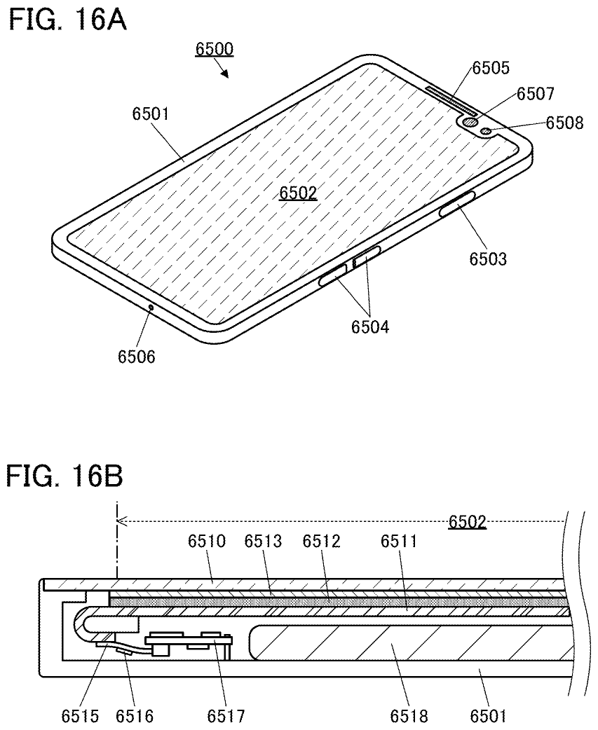

In this embodiment, electronic devices of one embodiment of the present invention will be described with reference to FIG. 16 to FIG. 19.

An electronic device of this embodiment includes the display device of one embodiment of the present invention. Resolution, definition, and sizes of the display device of one embodiment of the present invention are easily increased. Thus, the display device of one embodiment of the present invention can be used for display portions of a variety of electronic devices.

The display device of one embodiment of the present invention can be manufactured at low cost, which leads to a reduction in manufacturing cost of an electronic device.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, a display device of one embodiment of the present invention can have a high resolution, and thus can be favorably used for an electronic device having a relatively small display portion. As such an electronic device, a watch-type or bracelet-type information terminal device (wearable device); and a wearable device worn on a head, such as a device for VR such as a head mounted display and a glasses-type device for AR can be given, for example. Examples of wearable devices include a device for SR and a device for MR.

The resolution of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K2K (number of pixels: 3840×2160), or 8K4K (number of pixels: 7680×4320). In particular, resolution of 4K2K, 8K4K, or higher is preferable. Furthermore, the pixel density (definition) of the display device of one embodiment of the present invention is preferably higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With such a display device with high resolution and high definition, the electronic device can have higher realistic sensation, sense of depth, and the like in personal use such as portable use and home use.

The electronic device of this embodiment can be incorporated along a curved surface of an inside wall or an outside wall of a house or a building or the interior or the exterior of a car.

The electronic device of this embodiment may include an antenna. With the antenna receiving a signal, the electronic device can display an image, information, and the like on a display portion. When the electronic device includes the antenna and a secondary battery, the antenna may be used for contactless power transmission.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 16A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 16B is a schematic cross-sectional view including an edge portion of the housing 6501 on the microphone 6506 side.

A protective member 6510 having alight-transmitting property is provided on the display surface side of the housing 6501, and a display panel 6511, an optical member 6512, a touch sensor panel 6513, a printed circuit board 6517, a battery 6518, and the like are provide][ ]d in a space surrounded by the housing 6501 and the protective member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. An electronic device with a narrow frame can be achieved when part of the display panel 6511 is folded back so that the portion connected to the FPC 6515 is provided on the rear side of a pixel portion.

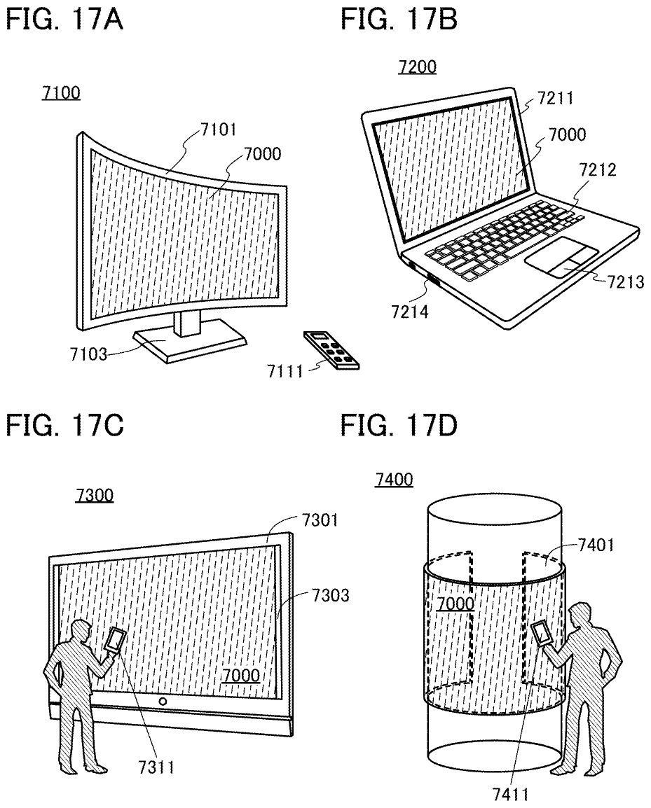

FIG. 17A illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used in the display portion 7000.

Operation of the television device 7100 illustrated in FIG. 17A can be performed with an operation switch provided in the housing 7101 and a separate remote controller 7111. Alternatively, the display portion 7000 may include a touch sensor, and the television device 7100 may be operated by a touch on the display portion 7000 with a finger or the like. The remote controller 7111 may include a display portion for displaying information output from the remote controller 7111. With operation keys or a touch panel provided in the remote controller 7111, channels and volume can be controlled, and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 17B illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIGS. 17C and 17D illustrate examples of digital signage.

A digital signage 7300 illustrated in FIG. 17C includes a housing 7301, the display portion 7000, a speaker 7303, and the like. Furthermore, the digital signage can include an LED lamp, operation keys (including a power switch or an operation switch), a connection terminal, a variety of sensors, a microphone, and the like.

FIG. 17D illustrates a digital signage 7400 mounted on a cylindrical pillar 7401. The digital signage 7400 includes the display portion 7000 provided along a curved surface of the pillar 7401.

The display device of one embodiment of the present invention can be used in the display portion 7000 in each of FIG. 17C and FIG. 17D.

A larger area of the display portion 7000 can increase the amount of information that can be provided at a time. The larger display portion 7000 attracts more attention, so that the advertising effectiveness can be enhanced, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 17C and FIG. 17D, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

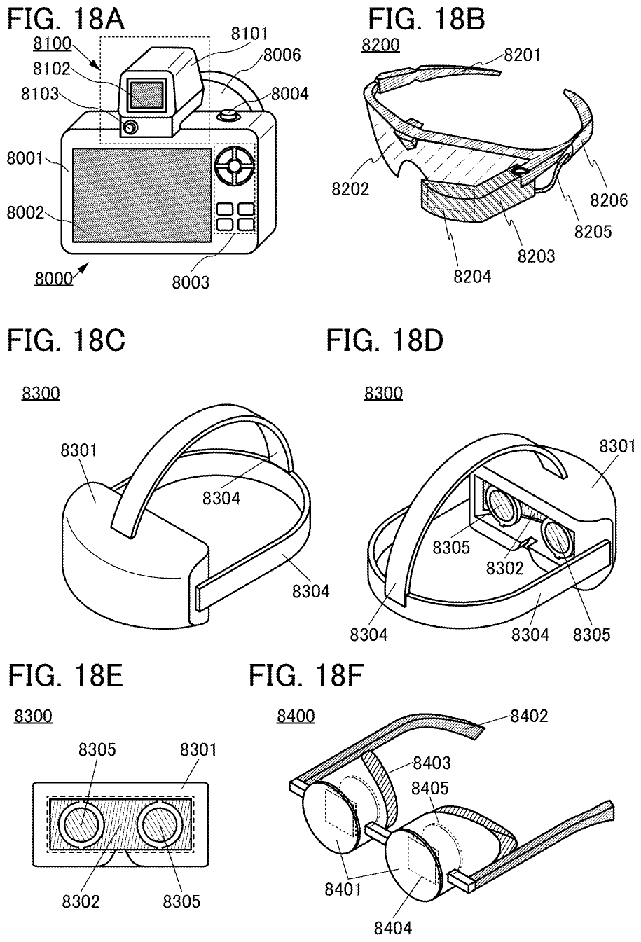

FIG. 18A is an external view of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000. Note that the lens 8006 and the housing 8001 may be integrated with each other in the camera 8000.

The camera 8000 can take images by the press of the shutter button 8004 or touch on the display portion 8002 serving as a touch panel.

The housing 8001 includes a mount including an electrode, so that, in addition to the finder 8100, a stroboscope or the like can be connected to the housing.

The finder 8100 includes a housing 8101, a display portion 8102, a button 8103, and the like.

The housing 8101 is attached to the camera 8000 with the mount engaging with a mount of the camera 8000. In the finder 8100, a video or the like received from the camera 8000 can be displayed on the display portion 8102.

The button 8103 has a function of a power button or the like.

The display device of one embodiment of the present invention can be used for the display portion 8002 of the camera 8000 and the display portion 8102 of the finder 8100. Note that a finder may be incorporated in the camera 8000.

FIG. 18B is an external view of a head-mounted display 8200.

The head-mounted display 8200 includes a mounting portion 8201, a lens 8202, a main body 8203, a display portion 8204, a cable 8205, and the like. In addition, a battery 8206 is incorporated in the mounting portion 8201.

The cable 8205 supplies power from the battery 8206 to the main body 8203. The main body 8203 includes a wireless receiver or the like and can display received video information on the display portion 8204. In addition, the main body 8203 is provided with a camera, and information on the movement of the user's eyeball or eyelid can be used as an input means.

The mounting portion 8201 may be provided with a plurality of electrodes capable of sensing current flowing in response to the movement of the user's eyeball in a position in contact with the user to have a function of recognizing the user's sight line. Furthermore, the mounting portion 8201 may have a function of monitoring the user's pulse with the use of current flowing through the electrodes. Moreover, the mounting portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, or the like.

The display device of one embodiment of the present invention can be used for the display portion 8204.

FIG. 18C to FIG. 18E are external views of a head-mounted display 8300. The head-mounted display 8300 includes a housing 8301, a display portion 8302, band-shaped fixing units 8304, and a pair of lenses 8305.

A user can see display on the display portion 8302 through the lenses 8305. Note that the display portion 8302 is preferably placed to be curved, in which case the user can feel a high realistic sensation. In addition, when another image displayed on a different region of the display portion 8302 is viewed through the lenses 8305, three-dimensional display using parallax or the like can also be performed. Note that the structure is not limited to the structure in which one display portion 8302 is provided; two display portions 8302 may be provided and one display portion may be provided per eye of the user.

The display device of one embodiment of the present invention can be used for the display portion 8302. The display device of one embodiment of the present invention achieves extremely high resolution. For example, a pixel is not easily seen by the user even when the user sees display that is magnified by the use of the lenses 8305 as illustrated in FIG. 18E. In other words, a video with a strong sense of reality can be seen by the user with use of the display portion 8302.

FIG. 18F is an external view of a goggle-type head-mounted display 8400. The head-mounted display 8400 includes a pair of housings 8401, a mounting portion 8402, and a cushion 8403. A display portion 8404 and a lens 8405 are provided in each of the pair of housings 8401. Furthermore, when the pair of display portions 8404 display different images, three-dimensional display using parallax can be performed.

A user can see display on the display portion 8404 through the lens 8405. The lens 8405 has a focus adjustment mechanism, and the focus adjustment mechanism can adjust the position of the lens 8405 according to the user's eyesight. The display portion 8404 is preferably a square or a horizontal rectangle. This can improve a realistic sensation.

The mounting portion 8402 preferably has flexibility and elasticity so as to be adjusted to fit the size of the user's face and not to slide down. In addition, part of the mounting portion 8402 preferably has a vibration mechanism functioning as a bone conduction earphone. Thus, audio devices such as an earphone and a speaker are not necessarily provided separately, and the user can enjoy images and sounds only by wearing the head-mounted display 8400. Note that the housing 8401 may have a function of outputting sound data by wireless communication.

The mounting portion 8402 and the cushion 8403 are portions in contact with the user's face (forehead, cheek, or the like). The cushion 8403 is in close contact with the user's face, so that light leakage can be prevented, which increases the sense of immersion. The cushion 8403 is preferably formed using a soft material so that the head-mounted display 8400 is in close contact with the user's face when being worn by the user. For example, a material such as rubber, silicone rubber, urethane, or sponge can be used. Furthermore, when a sponge or the like whose surface is covered with cloth, leather (natural leather or synthetic leather), or the like is used, a gap is unlikely to be generated between the user's face and the cushion 8403, whereby light leakage can be suitably prevented. Furthermore, using such a material is preferable because it has a soft texture and the user does not feel cold when wearing the device in a cold season, for example. The member in contact with user's skin, such as the cushion 8403 or the mounting portion 8402, is preferably detachable in order to easily perform cleaning or replacement.

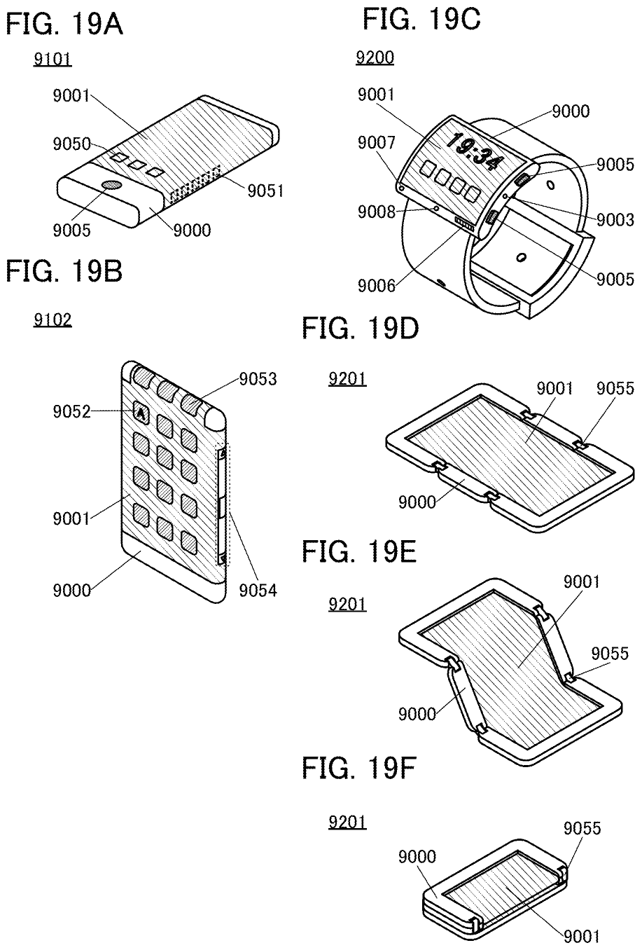

Electronic devices illustrated in FIG. 19A to FIG. 19F include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 19A to FIG. 19F have a variety of functions. For example, the electronic device can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The display device of one embodiment of the present invention can be used for the display portion 9001.

The details of the electronic devices illustrated in FIG. 19A to FIG. 19F are described below.

FIG. 19A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display characters and image information on its plurality of surfaces. FIG. 19A illustrates an example in which three icons 9050 are displayed. Information 9051 indicated by dashed rectangles can be displayed on another surface of the display portion 9001. Examples of the information 9051 include notification of reception of an e-mail, SNS, an incoming call, or the like, the title and sender of an e-mail, SNS, or the like, the date, the time, remaining battery, and the reception strength of an antenna. Alternatively, the icon 9050 or the like may be displayed at the position where the information 9051 is displayed.

FIG. 19B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 displayed in a position that can be observed from above the portable information terminal 9102, with the portable information terminal 9102 put in a breast pocket of his/her clothes. The user can seethe display without taking out the portable information terminal 9102 from the pocket and decide whether to answer a call, for example.

FIG. 19C is a perspective view illustrating a watch-type portable information terminal 9200. The portable information terminal 9200 can be used as a smartwatch (registered trademark), for example. The display portion 9001 is provided such that its display surface is curved, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 19D to FIG. 19F are perspective views showing a foldable portable information terminal 9201. FIG. 19D is a perspective view of an opened state of the portable information terminal 9201, FIG. 19F is a perspective view of a folded state thereof, and FIG. 19E is a perspective view of a state in the middle of change from one of FIG. 19D and FIG. 19F to the other. The portable information terminal 9201 is highly portable in the folded state and is highly browsable in the opened state because of a seamless large display region. The display portion 9001 of the portable information terminal 9201 is supported by three housings 9000 joined by hinges 9055. For example, the display portion 9001 can be folded with a radius of curvature greater than or equal to 0.1 mm and less than or equal to 150 mm.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Example 1

In this example, results of heat resistance tests performed on samples (films) obtained by forming films differing in material and structure (a stacked-layer film, a mixed film, or the like) over glass substrates are described. Note that nine kinds of samples were fabricated by varying a combination of a plurality of heteroaromatic compounds and a film structure. Note that the structures of the samples are shown in Table 1 together with the results. The chemical formulae of the materials used in this example are shown below.

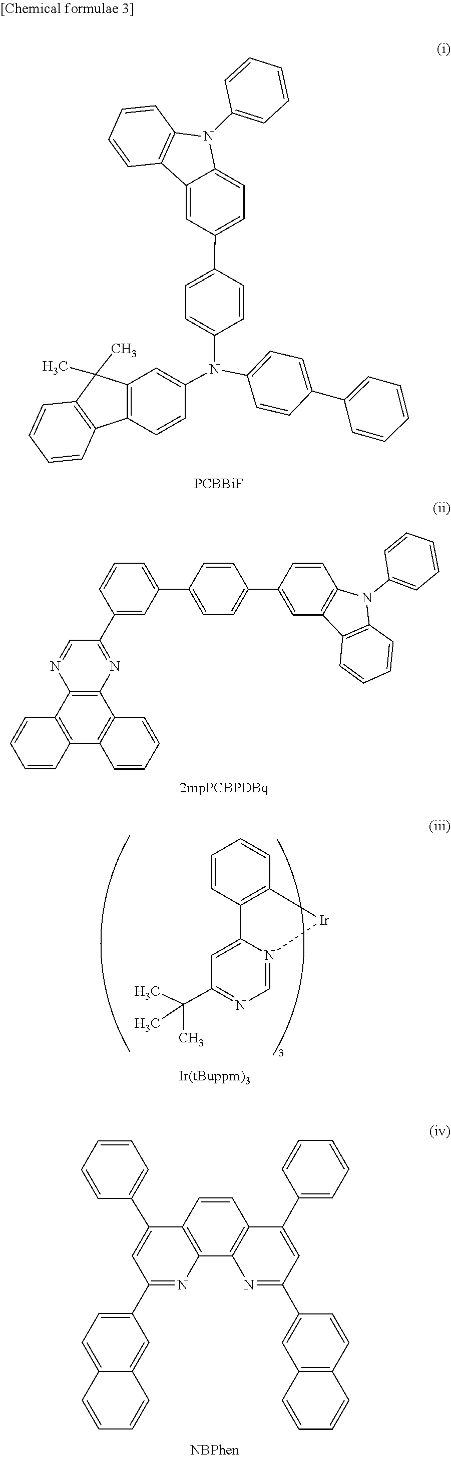

A method for fabricating the samples (a sample 1 to a sample 9) is described below.

First, a sample layer was formed over a glass substrate with a vacuum evaporation apparatus and cut into strips of 1 cm×3 cm. Next, the substrate was introduced into a bell jar type vacuum oven (BV-001, SHIBATA SCIENTIFIC TECHNOLOGY LTD.), and the pressure was reduced to approximately 10 hPa, followed by 1-hour baking at temperature in the range of 80° C. to 150° C.

The sample 1 is a single-layer film using one kind of heteroaromatic compound, which was formed by evaporation of 2,9-di(2-naphthyl)-4,7-diphenyl-1,10-phenanthroline (abbreviation: NBPhen) to a thickness of 10 nm over the glass substrate.

The sample 2 is a single-layer film using one kind of heteroaromatic compound, which was formed by evaporation of 2-[4′-(9-phenyl-9H-carbazol-3-yl)-3,1′-biphenyl-1-yl]dibenzo[f,h]quinoxaline (abbreviation: 2mpPCBPDBq) to a thickness of 10 nm over the glass substrate.

The sample 3 is a mixed film using a plurality of heteroaromatic compounds, which was formed by co-evaporation of 2mpPCBPDBq, N-(1,1′-biphenyl-4-yl)-N-[4-(9-phenyl-9H-carbazol-3-yl)phenyl]-9,9-dimethyl-9H-fluoren-2-amine (abbreviation: PCBBiF), and tris(4-t-butyl-6-phenylpyrimidinato)iridium(III) (abbreviation: [Ir(tBuppm)₃]) in a weight ratio of 0.8:0.2:0.06 (=2mpPCBPDBq:PCBBiF:Ir(tBuppm)₃) to a thickness of 40 nm over the glass substrate.

The sample 4 is a stacked-layer film using a plurality of heteroaromatic compounds, which was formed by evaporation of 2mpPCBPDBq to a thickness of 10 nm and then evaporation of NBPhen to a thickness of 10 nm over the glass substrate.

The sample 5 is a mixed film using a plurality of heteroaromatic compounds, which was formed by co-evaporation of 2mpPCBPDBq, PCBBiF, and Ir(tBuppm)₃ in a weight ratio of 0.8:0.2:0.06 (=2mpPCBPDBq:PCBBiF:Ir(tBuppm)₃) to a thickness of 40 nm, evaporation of 2mpPCBPDBq to a thickness of 10 nm, and then evaporation of NBPhen to a thickness of 10 nm over the glass substrate.

The sample 6 is a single-layer film using one kind of heteroaromatic compound, which was formed by evaporation of PCBBiF to a thickness of 40 nm over the glass substrate.

The sample 7 is a mixed film using a plurality of heteroaromatic compounds, which was formed by co-evaporation of 2mpPCBPDBq and NBPhen in a weight ratio of 0.5:0.5 (=2mpPCBPDBq:NBPhen) to a thickness of 20 nm over the glass substrate.

The sample 8 is a mixed film using a plurality of heteroaromatic compounds, which was formed by co-evaporation of 2mpPCBPDBq, PCBBiF, and Ir(tBuppm)₃ in a weight ratio of 0.8:0.2:0.06 (=2mpPCBPDBq:PCBBiF:Ir(tBuppm)₃) to a thickness of 40 nm and then evaporation of NBPhen to a thickness of 20 nm over the glass substrate.

The sample 9 is a mixed film using a plurality of heteroaromatic compounds, which was formed by co-evaporation of 2mpPCBPDBq, PCBBiF, and Ir(tBuppm)₃ in a weight ratio of 0.8:0.2:0.06 (=2mpPCBPDBq:PCBBiF:Ir(tBuppm)₃) to a thickness of 40 nm and then co-evaporation of 2mpPCBPDBq and NBPhen in a weight ratio of 0.5:0.5 (=2mpPCBPDBq:NBPhen) to a thickness of 20 nm over the glass substrate.

The samples formed by such a method were observed visually and with an optical microscope (MX61L semiconductor/FPD inspection microscope, Olympus Corporation).

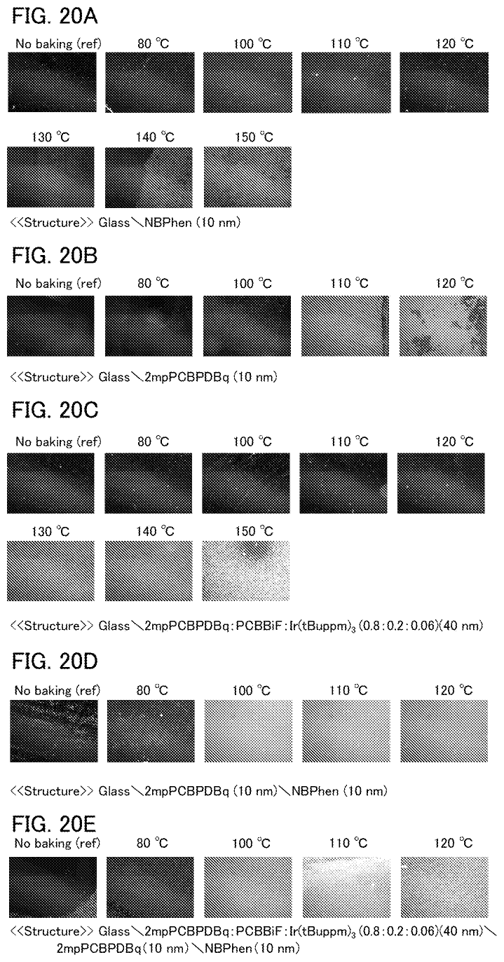

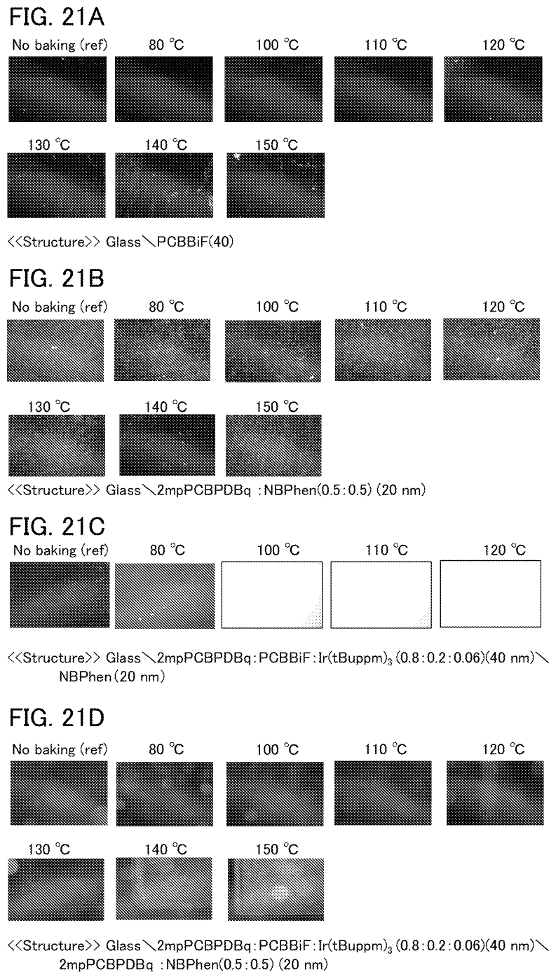

FIG. 20 and FIG. 21 show photographs of the samples fabricated in this example (observation at a magnification of 100 times). Furthermore, the samples without baking (ref) are also shown as comparative examples.

Table 1 shows the structures of the samples fabricated in this examples and the observation results thereof. In Table 1, a circle indicates that no crystal was generated and a cross indicates that a crystal was generated. In addition, a triangle indicates that it was not able to be clearly determined.

TABLE 1

| Sample | | | | | | | | | |
|---|---|---|---|---|---|---|---|---|---|
| NO. | Structure | rt | 80° C. | 100° C. | 110° C. | 120° C. | 130° C. | 140° C. | 150° C. |
| 1 | NBPhen (10 nm) | ∘ | ∘ | ∘ | ∘ | ∘ | ∘ | Δ | Δ |
| 2 | 2mpPCBPDBq (10 nm) | ∘ | ∘ | ∘ | Δ or x | Δ or x | — | — | — |
| 3 | 2mpPCBPDBq:PCBBiF:Ir(tBuppm)₃ | ∘ | ∘ | ∘ | ∘ | ∘ | x | x | x |
| | (0.8:0.2:0.06)(40 nm) | | | | | | | | |
| 4 | NBPhen (10 nm) | ∘ | ∘ | x | x | x | — | — | — |
| | 2mpPCBPDBq (10 nm) | | | | | | | | |
| 5 | NBPhen(10 nm) | ∘ | ∘ | x | x | x | — | — | — |
| | 2mpPCBPDBq(10 nm) | | | | | | | | |
| | 2mpPCBPDBq:PCBBiF:Ir(tBuppm)₃ | | | | | | | | |
| | (0.8:0.2:0.06)(40 nm) | | | | | | | | |
| 6 | PCBBiF (40 nm) | ∘ | ∘ | ∘ | ∘ | ∘ | ∘ | ∘ | ∘ |
| 7 | 2mpPCBPDBq:NBPhen | ∘ | ∘ | ∘ | ∘ | ∘ | ∘ | ∘ | ∘ |
| | (0.5:0.5)(20 nm) | | | | | | | | |
| 8 | NBPhen(20 nm) | ∘ | x | x | x | x | — | — | — |
| | 2mpPCBPDBq:PCBBiF:Ir(tBuppm)₃ | | | | | | | | |
| | (0.8:0.2:0.06)(40 nm) | | | | | | | | |
| 9 | 2mpPCBPDBq:NBPhen | ∘ | ∘ | ∘ | ∘ or Δ | ∘ or Δ | Δ or x | x | x |
| | (0.5:0.5)(20 nm) | | | | | | | | |
| | 2mpPCBPDBq:PCBBiF:Ir(tBuppm)₃ | | | | | | | | |
| | (0.8:0.2:0.06)(40 nm) | | | | | | | | |

The above results reveal that crystals were less likely to be formed in the sample 3 and the sample 7, which are mixed films using a plurality of heteroaromatic compounds, than in the sample 4 and the sample 5, which are stacked-layer films using a plurality of heteroaromatic compounds. Accordingly, it was found that the mixed film using a plurality of heteroaromatic compounds had improved heat resistance. In particular, with the sample 4 and the sample 7 compared with each other, although they used the same heteroaromatic compounds, crystallization occurred at 100° C. in the sample 4 that is a stacked-layer film while crystallization did not occur up to 150° C. in the sample 7 that is a mixed film. This indicates that the mixed film using a plurality of π-electron deficient heteroaromatic compounds particularly exhibited an effect of improving heat resistance.

In addition, it is found from the above results that crystallization sometimes occurs at a low temperature when the materials are stacked although single films of the materials have relatively good heat resistance. In the comparison of the samples 5, 8, and 9 formed with stacked films, crystallization occurred at 100° C. in the sample 5 and crystallization occurred at 80° C. in the sample 8, whereas crystallization did not occur clearly up to 130° C. in the sample 9. It was found that the electron-transport layer formed with the mixed film using a plurality of heteroaromatic compounds exhibited an effect of improving the heat resistance by 30° C. or more as compared with the case where the electron-transport layer was formed with one material. A light-emitting device is often formed by stacking a plurality of organic compounds. Therefore, the use of the light-emitting device of one embodiment of the present invention makes it possible to significantly increase the heat resistance of the light-emitting device.

### Example 2

The results in Example 1 reveal that the mixed film of the heteroaromatic compound and the organic compound that are used for the electron-transport layer in the light-emitting device of one embodiment of the present invention has higher heat resistance than a stacked-layer film in which single-layer films of these compounds are stacked. Therefore, a light-emitting device 1 including the mixed film of the heteroaromatic compound and the organic compound in an electron-transport layer and a comparative light-emitting device 1 including a stacked-layer film of the heteroaromatic compound and the organic compound in an electron-transport layer were fabricated, and characteristics of the devices were compared. The element structures and their characteristics are described below. Specific structures of the light-emitting device 1 and the comparative light-emitting device 1 used in this example are shown in Table 1. Chemical formulae of materials used in this example are shown below.

TABLE 2

| | | | Light-emitting | Comparative light- |
|---|---|---|---|---|
| | Film thickness | | device1 | emitting device1 |
| Second electrode | 200 | nm | Al | |
| Electron-injection layer | 1 | nm | LiF | |
| Electron-transport | 30 | nm | 2mpPCBPDBq:NBPhen | NBPhen (20 nm) |
| layer | | | (1:1) | 2mpPCBPDBq (10 nm) |

| | | | |
|---|---|---|---|
| Light-emitting layer | 50 | nm | 2mpPCBPDBq:PCBBiF:Ir(tBuppm)₃ |
| | | | (0.8:0.2:0.05) |
| Hole-transport layer | 50 | nm | PCBBiF |
| Hole-injection layer | 10 | nm | PCBBiF:OCHD-003 |
| | | | (1:0.03) |
| First electrode | 70 | nm | ITSO |

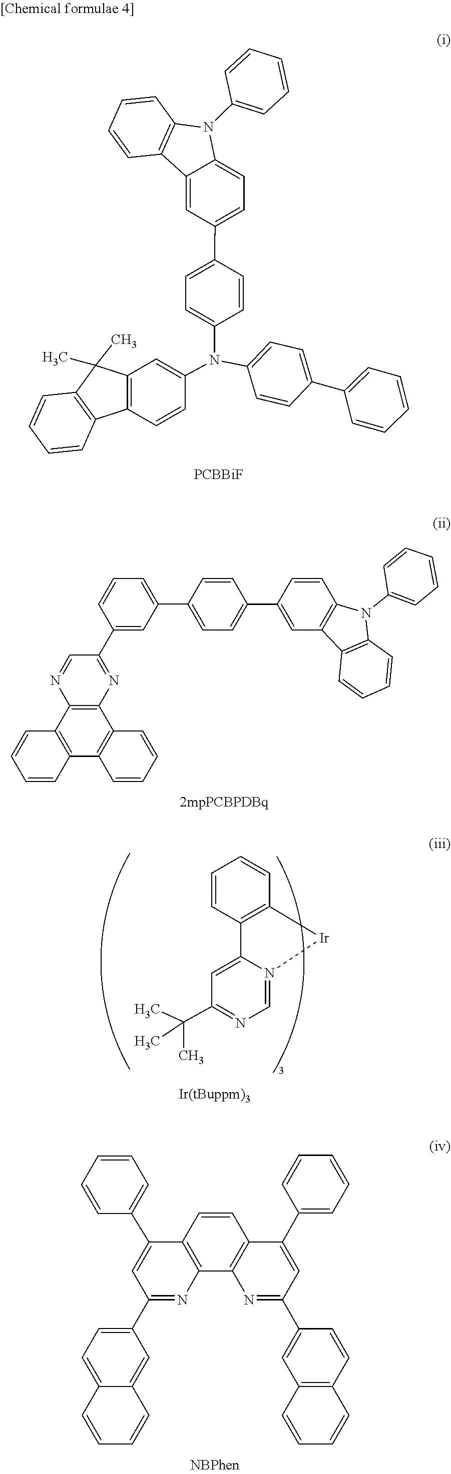

### <<Fabrication of Light-Emitting Device 1>>

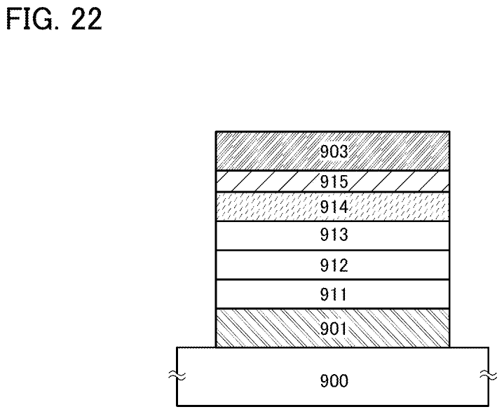

The light-emitting device 1 described in this example has a structure, as illustrated in FIG. 22, in which a hole-injection layer 911, a hole-transport layer 912, a light-emitting layer 913, an electron-transport layer 914, and an electron-injection layer 915 are stacked in this order over a first electrode 901 formed over a substrate 900, and a second electrode 903 is stacked over the electron-injection layer 915.

First, the first electrode 901 was formed over the substrate 900. The electrode area was set to 4 mm² (2 mm×2 mm). A glass substrate was used as the substrate 900. The first electrode 901 was formed to a thickness of 70 nm using indium tin oxide containing silicon oxide (ITSO) by a sputtering method.

As pretreatment, a surface of the substrate was washed with water, baking was performed at 200° C. for one hour, and then UV ozone treatment was performed for 370 seconds. After that, the substrate was transferred into a vacuum evaporation apparatus where the inside pressure had been reduced to approximately 10-4 Pa, and was subjected to vacuum baking at 170° C. for 60 minutes in a heating chamber of the vacuum evaporation apparatus, and then the substrate was cooled down for approximately 30 minutes.

Next, the hole-injection layer 911 was formed over the first electrode 901. The hole-injection layer 911 was formed in such a manner that the pressure in the vacuum evaporation apparatus was reduced to 10-4 Pa, and then N-(1,1′-biphenyl-4-yl)-N-[4-(9-phenyl-9H-carbazol-3-yl)phenyl]-9,9-dimethyl-9H-fluoren-2-amine (abbreviation: PCBBiF) represented by Structure formula (i) shown above and an electron acceptor material (OCHD-003) that contains fluorine and has a molecular weight of 672 were deposited by co-evaporation to a thickness of 10 nm in a weight ratio of PCBBiF:OCHD-003=1:0.03.

Then, the hole-transport layer 912 was formed over the hole-injection layer 911. The hole-transport layer 912 was formed to a thickness of 50 nm by evaporation of PCBBiF.

Next, the light-emitting layer 913 was formed over the hole-transport layer 912.

The light-emitting layer 913 was formed to a thickness of 50 nm by co-evaporation of 2-[4′-(9-phenyl-9H-carbazol-3-yl)-3,1′-biphenyl-1-yl]dibenzo[f,h]quinoxaline (abbreviation: 2mpPCBPDBq) represented by Structure formula (ii) shown above, PCBBiF, and tris(4-t-butyl-6-phenylpyrimidinato)iridium(III) (abbreviation: Ir(tBuppm)₃) represented by Structure formula (iii) shown above in a weight ratio of 2mpPCBPDBq:PCBBiF:Ir(tBuppm)₃=0.8:0.2:0.05.

Next, the electron-transport layer 914 was formed over the light-emitting layer 913. The electron-transport layer 914 was formed to a thickness of 30 nm by co-evaporation of 2mpPCBPDBq and 2,9-di(2-naphthyl)-4,7-diphenyl-1,10-phenanthroline (abbreviation: NBPhen) represented by Structure formula (iv) shown above in a weight ratio of 2mpPCBPDBq:NBPhen=1:1.

Then, the electron-injection layer 915 was formed over the electron-transport layer 914. The electron-injection layer 915 was formed by evaporation of lithium fluoride (LiF) to a thickness of 1 nm.

Next, the second electrode 903 was formed over the electron-injection layer 915. The second electrode 903 was formed using aluminum by an evaporation method to a thickness of 200 nm. In this example, the second electrode 903 functions as a cathode.

Through the above steps, the light-emitting device 1 in which an EL layer was provided between the pair of electrodes over the substrate 900 was formed. The hole-injection layer 911, the hole-transport layer 912, the light-emitting layer 913, the electron-transport layer 914, and the electron-injection layer 915 described in the above steps are functional layers forming the EL layer in one embodiment of the present invention. Furthermore, in all the evaporation steps in the above fabrication method, an evaporation method by a resistance-heating method was used.

The fabricated light-emitting device 1 was sealed in a glove box containing a nitrogen atmosphere so as not to be exposed to the air (a sealant was applied to surround the element, and at the time of sealing, UV treatment was performed and then heat treatment was performed at 80° C. for one hour).

### <<Fabrication of Comparative Light-Emitting Device 1>>

The comparative light-emitting device 1 was fabricated in the same manner as the light-emitting device 1 except that the electron-transport layer 914 was formed not by co-evaporation of 2mpPCBPDBq and NBPhen but by evaporation of 2mpPCBPDBq to a thickness of 10 nm and successively by evaporation of NBPhen to a thickness of 20 nm.

### <<Operation Characteristics of Light-Emitting Device 1>>

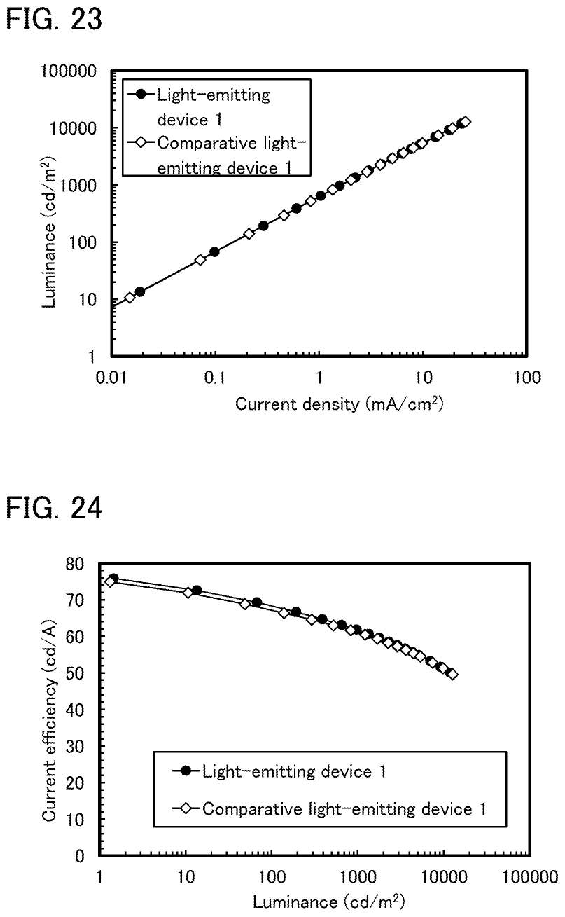

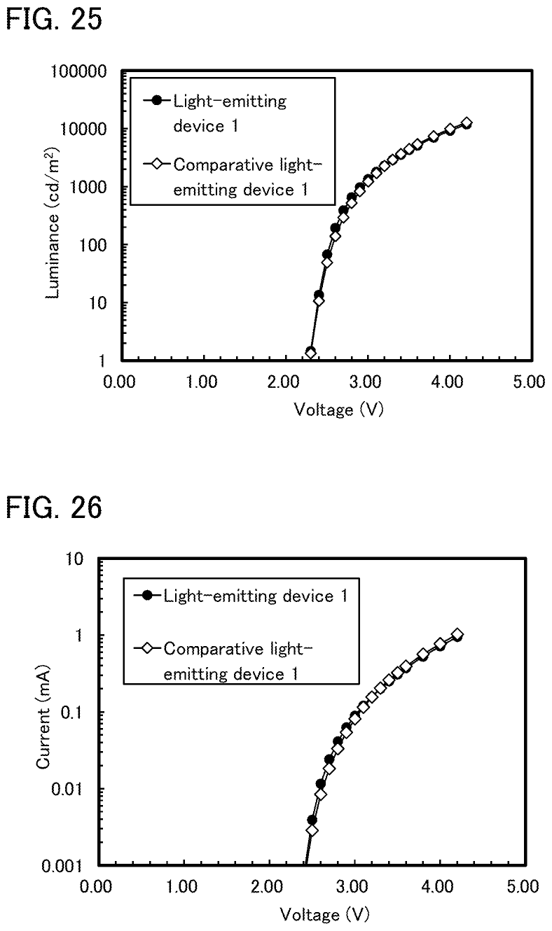

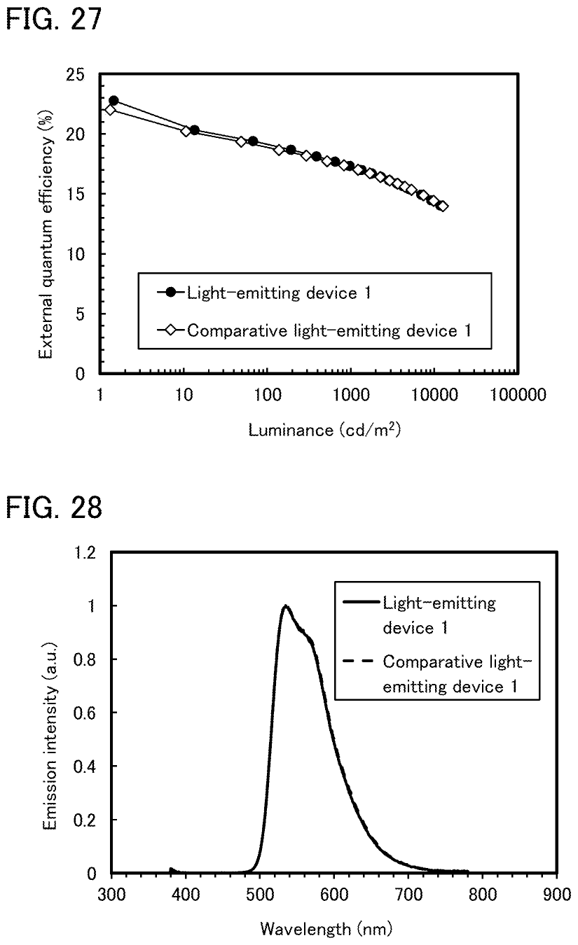

FIG. 23 shows the luminance-current density characteristics of the light-emitting device 1 and the comparative light-emitting device 1; FIG. 24 shows the current efficiency-luminance characteristics thereof; FIG. 25 shows the luminance-voltage characteristics thereof; FIG. 26 shows the current-voltage characteristics thereof; FIG. 27 shows the external quantum efficiency-luminance characteristics thereof; and FIG. 28 shows the emission spectra thereof. Table 3 shows the main characteristics of the light-emitting device 1 and the comparative light-emitting device 1 at approximately 1000 cd/m². The luminance, CIE chromaticity, and emission spectra were measured at normal temperature with a spectroradiometer (SR-UL1R manufactured by TOPCON TECHNOHOUSE CORPORATION).

TABLE 3

| | | | | | | Current | External |
|---|---|---|---|---|---|---|---|
| | Voltage | Current | Current density | Chromaticity | Chromaticity | efficiency | quantum |
| | (V) | (mA) | (mA/cm²) | x | y | (cd/A) | efficiency (%) |
| Light-emitting device 1 | 2.9 | 0.06 | 1.6 | 0.40 | 0.58 | 61.9 | 17.3 |
| Comparative light-emitting device 1 | 2.9 | 0.05 | 1.4 | 0.41 | 0.58 | 61.7 | 17.4 |

The results in FIG. 23 to FIG. 28 and Table 3 reveal that the light-emitting device 1 of one embodiment of the present invention has operation characteristics equivalent to those of the comparative light-emitting device 1.

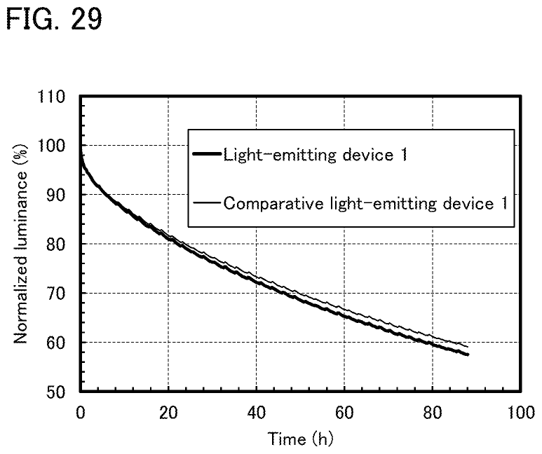

Next, a reliability test was performed on each light-emitting device. FIG. 29 shows the results of the reliability test of the light-emitting device 1 and the comparative light-emitting device 1. In FIG. 29, the vertical axis represents normalized luminance (%) with an initial luminance of 100%, and the horizontal axis represents device driving time (h). As the reliability test, a driving test at a constant current density of 50 mA/cm² was performed on each of the light-emitting devices.

The results in FIG. 29 showed that the light-emitting device 1 of one embodiment of the present invention had favorable reliability comparable to that of the comparative light-emitting device 1.

### Example 3

In this example, a synthesis method of 2-[4′-(9-phenyl-9H-carbazol-3-yl)-3,1′-biphenyl-1-yl]dibenzo[f,h]quinoxaline (abbreviation: 2mpPCBPDBq) used in Example 1 and Example 2 is described. A structural formula of 2mpPCBPDBq is shown below.

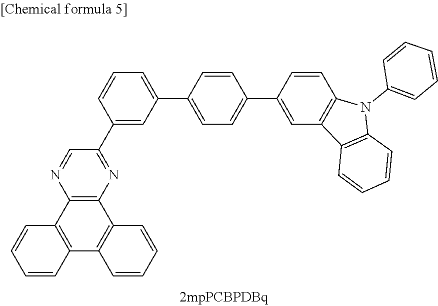 [SMILES: c1ccc(-n2c3ccccc3c3cc(-c4ccc(-c5cccc(-c6cnc7c8ccccc8c8ccccc8c7n6)c5)cc4)ccc32)cc1]

<<Synthesis of 2mpPCBPDBq>>

Into a 200-mL three-neck flask were put 6.9 g (17 mmol) of 3-(4-bromophenyl)-9-phenylcarbazole, 4.4 g (17 mmol) of bis(pinacolate)diborane, 0.17 g (0.4 mmol) of 2-di-tert-butylphosphino-2′,4′,6′-triisopropylbiphenyl (tBuXPhos), 4.0 g (40 mmol) of potassium acetate, and 90 mL of xylene, degassing was performed under reduced pressure, and then a nitrogen gas was made to flow continuously in the system. After the mixture was heated to 80° C., 0.17 mg (0.2 mmol) of [1,1′-bis(diphenylphosphino)ferrocene]palladium(II) dichloride (Pd(dppf)Cl₂) was added, and the mixture was stirred at 120° C. for 10 hours.

To the obtained mixture, 5.8 g (17 mmol) of 2-(3-chlorophenyl)dibenzo[f,h]quinoxaline, 13 g (40 mmol) of cesium carbonate, and 0.18 mg (0.4 mmol) of tBuXPhos were added, degassing was performed under reduced pressure, and then a nitrogen gas was made to flow continuously in the system. After the mixture was heated to 80° C., 0.16 mg (0.2 mmol) of Pd(dppf)Cl₂ was added, and the mixture was heated and stirred at 130° C. for 3 hours and then at 150° C. for 15 hours. After the stirring, the precipitated solid was collected by suction filtration and washed with water and ethanol. The obtained solid was suction-filtered through Celite (Wako Pure Chemical Industries, Ltd., Catalog No. 537-02305) and alumina with the use of 1 L of toluene and then recrystallized with toluene to give 1.4 g of a target white powder (yield: 12%). The synthesis scheme is shown in Formula (a-1) below.

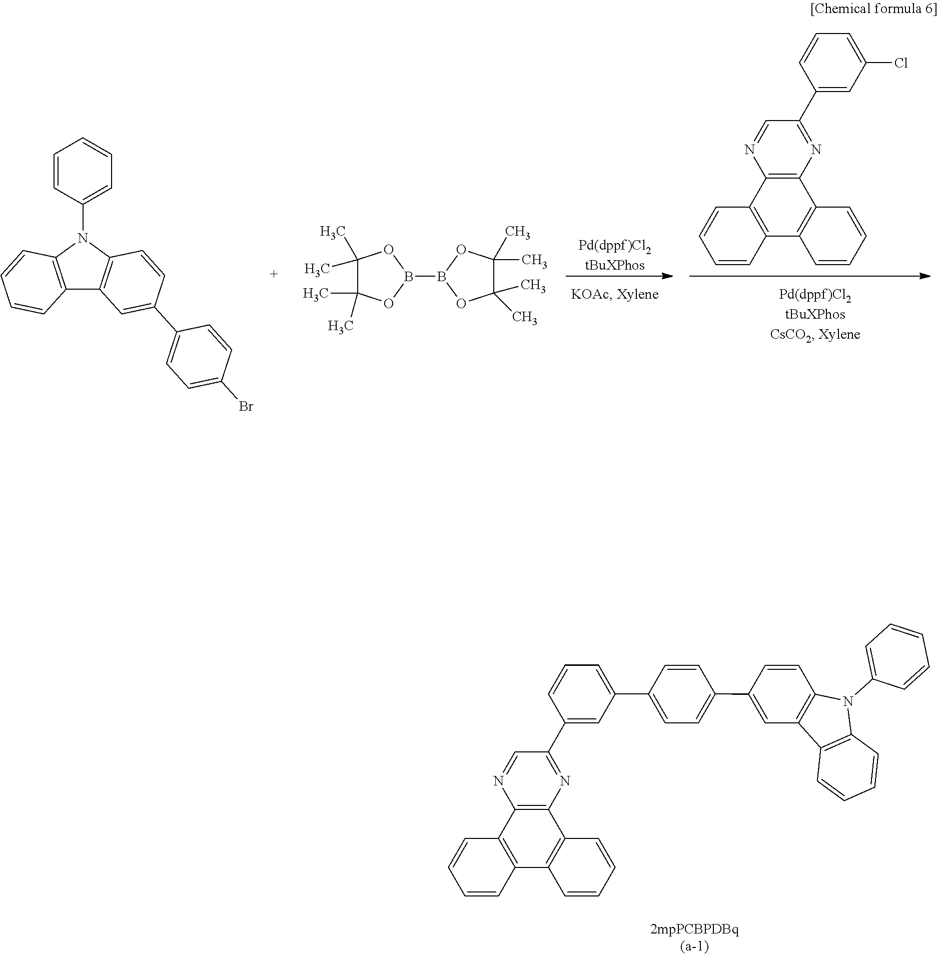

The obtained solid was sublimated and purified by a train sublimation method. In the sublimation purification, 1.3 g of the obtained solid was heated at 340° C. for 15 hours. The pressure was 3.9 Pa and the argon flow rate was 15 sccm at the time of the sublimation purification. After the sublimation purification, 1.5 g of a target solid was obtained at a collection rate of 85%.

Results of analysis by nuclear magnetic resonance (¹H-NMR) spectroscopy of the solid obtained above are shown below. The results show that 2mpPCBPDBq was obtained in this example.

¹H NMR (chloroform-d, 500 MHz): δ=7.32-7.35 (m, 1H), 7.446 (s, 1H), 7.454 (s, 1H), 7.49-7.53 (m, 2H), 7.61-7.66 (m, 4H), 7.71-7.92 (m, 11H), 8.24 (d, J=8.0 Hz, 1H), 8.33 (d, J=8.0 Hz, 1H), 8.46 (sd, J-1.0 Hz, 1H), 8.67-8.68 (m, 3H), 9.26 (dd, J=7.8 Hz, J=1.3 Hz, 1H), 9.47 (dd, J=8.0 Hz, J=1.5 Hz, 1H), 9.48 (s, 1H).

### REFERENCE NUMERALS

41a: pixel circuit, 41b: pixel circuit, 42a: pixel circuit, 42b: pixel circuit, 43a: pixel circuit, 43b: pixel circuit, 51a: wiring, 51b: wiring, 52a: wiring, 52b: wiring, 52c: wiring, 52d: wiring, 53a: wiring, 53b: wiring, 53c: wiring, 60 display element, 61: transistor, 62: transistor, 63: capacitor, 70: pixel unit, 70a: pixel, 70b: pixel, 71a: subpixel, 71b: subpixel, 72a: subpixel, 72b: subpixel, 73a: subpixel, 73b: subpixel, 100: substrate, 101: anode, 101_1: first anode, 101_2: second anode, 101b: conductive film, 101C: connection electrode, 101R: anode, 101B: anode, 101B: anode, 102: cathode, 103: EL layer, 103R: EL layer, 103Rf: EL film, 103G: EL layer, 103Gf: EL film, 103B: EL layer, 110_1: first light-emitting device, 110_2: second light-emitting device, 110R: light-emitting device, 110G: light-emitting device, 110B: light-emitting device, 111: hole-injection layer, 111a: hole-injection layer A, 111a1: first hole-transport layer A, 111a2: second hole-transport layer A, 111f: organic layer, 112: hole-transport layer, 112a: hole-transport layer A, 112a1: first hole-transport layer A, 112a2: second hole-transport layer A, 112b: hole-transport layer B, 112b1: first hole-transport layer B, 112b2: second hole-transport layer B, 112f: organic layer, 113: light-emitting layer, 113a: light-emitting layer A, 113a1: first light-emitting layer A, 113a2: second light-emitting layer A, 113b: light-emitting layer B, 113b1: first light-emitting layer B, 1b3b2: second light-emitting layer B, 113f: organic layer, 114: electron-transport layer, 114a: electron-transport layer A, 114a1: first electron-transport layer A, 114a2: second electron-transport layer A, 114b: electron-transport layer B, 114b1: first electron-transport layer B, 114b2: second electron-transport layer B, 114bf: organic layer, 114f: organic layer, 115: electron-injection layer, 115b: electron-injection layer B, 120: insulating layer, 121: insulating film, 121f: insulating film, 125: insulating layer, 125f: insulating film, 126: insulating layer, 126f: insulating film, 127: sacrificial layer, 130: connection portion, 131: protective layer, 143a: resist mask, 143b: resist mask, 144a: sacrificial film, 144b: sacrificial film, 145a: sacrificial film, 145b: sacrificial film, 145c: sacrificial film, 146a: protective film, 146b: protective film, 147a: protective layer, 147b: protective layer, 150: intermediate layer, 150_1: first intermediate layer, 150_2: second intermediate layer, 151f: organic layer, 151a: light-emitting unit A, 151a1: first light-emitting unit A, 151a2: second light-emitting unit A, 151af: organic layer, 151b: light-emitting unit B, 151b1: first light-emitting unit B, 151b2: second light-emitting unit B, 151bf: organic layer, 201: transistor, 202: transistor, 204: connection portion, 205: transistor, 209: transistor, 210: transistor, 211: insulating layer, 212: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 228: region, 231: semiconductor layer, 231i: channel formation region, 231n: low-resistance region, 240: capacitor, 241: conductive layer, 242: connection layer, 243: insulating layer, 245: conductive layer, 251: conductive layer, 252: conductive layer, 254: insulating layer, 255: insulating layer, 256: plug, 261: insulating layer, 262: insulating layer, 263: insulating layer, 264: insulating layer, 265: insulating layer, 271: plug, 274: plug, 274a: conductive layer, 274b: conductive layer, 280: display module, 281: display portion, 282: circuit portion, 283: pixel circuit portion, 283a: pixel circuit, 284: pixel portion, 284a: pixel, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 400: light-emitting apparatus, 400A: light-emitting apparatus, 400C: light-emitting apparatus, 401: layer, 411a: pixel electrode, 411b: pixel electrode, 411c: pixel electrode, 415: EL layer, 416: protective layer, 416a: inorganic insulating layer, 416b: organic insulating layer, 416c: inorganic insulating layer, 417: light-blocking layer, 419: resin layer, 420: substrate, 421: insulating layer, 426a: optical adjustment layer, 426b: optical adjustment layer, 426c: optical adjustment layer, 430a: light-emitting device, 430b: light-emitting device, 430c: light-emitting device, 442: adhesive layer, 443: space, 451: substrate, 452: substrate, 453: substrate, 454: substrate, 455: adhesive layer, 462: display portion, 464: circuit, 465: wiring, 466: conductive layer, 472: FPC, 473: IC, 900: substrate, 901: anode, 903: cathode, 911: hole-injection layer, 912: hole-transport layer, 913: light-emitting layer, 914: electron-transport layer, 915: electron-injection layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: mounting portion, 8202: lens, 8203: main body, 8204: display portion, 8205: cable, 8206: battery, 8300: head-mounted display, 8301: housing, 8302: display portion, 8304: fixing unit, 8305: lens, 8400: head-mounted display, 8401: housing, 8402: mounting portion, 8403: cushion, 8404: display portion, 8405: lens, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9200: portable information terminal, 9201: portable information terminal

1. A light-emitting apparatus comprising a first light-emitting device and a second light-emitting device adjacent each other over an insulating plane,
wherein the first light-emitting device comprises a first anode, a first cathode, and a first EL layer interposed between the first anode and the first cathode,
wherein the second light-emitting device comprises a second anode, a second cathode, and a second EL layer interposed between the second anode and the second cathode,
wherein the first EL layer comprises at least a first light-emitting layer and a first electron-transport layer,
wherein the first electron-transport layer is positioned between the first light-emitting layer and the first cathode,
wherein the second EL layer comprises at least a second light-emitting layer and a second electron-transport layer,
wherein the second electron-transport layer is positioned between the second light-emitting layer and the second cathode,
wherein the first electron-transport layer comprises at least a first heteroaromatic compound comprising a first heteroaromatic ring and a first organic compound different from the first heteroaromatic compound,
wherein the second electron-transport layer comprises at least a second heteroaromatic compound comprising a second heteroaromatic ring and a second organic compound different from the second heteroaromatic compound,
wherein an edge portion of the first light-emitting layer and an edge portion of the first electron-transport layer are substantially aligned at a first edge portion when seen from a direction perpendicular to the insulating plane,
wherein an edge portion of the second light-emitting layer and an edge portion of the second electron-transport layer are substantially aligned at a second edge portion when seen from the direction perpendicular to the insulating plane, and
wherein a distance between the first edge portion and the second edge portion facing each other is 2 μm to 5 μm.

2. The light-emitting apparatus according to claim 1,
wherein the first electron-transport layer comprises the first heteroaromatic compound comprising the first heteroaromatic ring and the first organic compound different from the first heteroaromatic compound, and
wherein the second electron-transport layer comprises the second heteroaromatic compound comprising the second heteroaromatic ring and the second organic compound different from the second heteroaromatic compound.

3. The light-emitting apparatus according to claim 1,
wherein the first heteroaromatic compound and the first organic compound are each contained in the first electron-transport layer at 10 weight % or more, and
wherein the second heteroaromatic compound and the second organic compound are each contained in the second electron-transport layer at 10 weight % or more.

4. The light-emitting apparatus according to claim 1,
wherein the first electron-transport layer and the second electron-transport layer do not comprise a metal complex.

5. The light-emitting apparatus according to claim 1,
wherein the first electron-transport layer and the second electron-transport layer do not comprise an alkali metal complex or an alkaline earth metal complex.

6. The light-emitting apparatus according to claim 1,
wherein the first electron-transport layer and the second electron-transport layer do not comprise alkali metal quinolinolato or alkaline earth metal quinolinolato.

7. A light-emitting apparatus comprising a first light-emitting device and a second light-emitting device adjacent to each other over an insulating plane,
wherein the first light-emitting device comprises a first anode, a first cathode, and a first EL layer interposed between the first anode and the first cathode,
wherein the second light-emitting device comprises a second anode, a second cathode, and a second EL layer interposed between the second anode and the second cathode,
wherein the first EL layer comprises at least a light-emitting layer 1a, a first charge-generation layer, a light-emitting layer 1b, and an electron-transport layer 1b in this order from the first anode side,
wherein the electron-transport layer 1b is positioned between the light-emitting layer 1b and the first cathode,
wherein the second EL layer comprises at least a light-emitting layer 2a, a second charge-generation layer, a light-emitting layer 2b, and an electron-transport layer 2b in this order from the second anode side,
wherein the electron-transport layer 2b is positioned between the light-emitting layer 2b and the second cathode,
wherein the electron-transport layer 1b comprises at least a first heteroaromatic compound comprising a first heteroaromatic ring and a first organic compound different from the first heteroaromatic compound,
wherein the electron-transport layer 2b comprises at least a second heteroaromatic compound comprising a second heteroaromatic ring and a second organic compound different from the second heteroaromatic compound,
wherein an edge portion of the light-emitting layer 1a and an edge portion of the electron-transport layer 1b are substantially aligned at a first edge portion when seen from a direction perpendicular to the insulating plane,
wherein an edge portion of the light-emitting layer 2a and an edge portion of the electron-transport layer 2b are substantially aligned at a second edge portion when seen from the direction perpendicular to the insulating plane, and
wherein a distance between the first edge portion and the second edge portion facing each other is 2 μm to 5 μm.

8. The light-emitting apparatus according to claim 7,
wherein the electron-transport layer 1b comprises the first heteroaromatic compound comprising the first heteroaromatic ring and the first organic compound different from the first heteroaromatic compound, and
wherein the electron-transport layer 2b comprises the second heteroaromatic compound comprising the second heteroaromatic ring and the second organic compound different from the second heteroaromatic compound.

9. The light-emitting apparatus according to claim 7,
wherein the first heteroaromatic compound and the first organic compound are each contained in the electron-transport layer 1b at 10 weight % or more, and
wherein the second heteroaromatic compound and the second organic compound are each contained in the electron-transport layer 2b at 10 weight % or more.

10. The light-emitting apparatus according to claim 7,
wherein the electron-transport layer 1b and the electron-transport layer 2b do not comprise a metal complex.

11. The light-emitting apparatus according to claim 7,
wherein the electron-transport layer 1b and the electron-transport layer 2b do not comprise an alkali metal complex or an alkaline earth metal complex.

12. The light-emitting apparatus according to claim 7,
wherein the electron-transport layer 1b and the electron-transport layer 2b do not comprise alkali metal quinolinolato or alkaline earth metal quinolinolato.

13. The light-emitting apparatus according to claim 7,
wherein the first EL layer comprises an electron-transport layer 1a between the light-emitting layer 1a and a first intermediate layer,
wherein the second EL layer comprises an electron-transport layer 2a between the light-emitting layer 2a and a second intermediate layer, and
wherein a composition of the electron-transport layer 1a is different from that of the electron-transport layer 1b and a composition of the electron-transport layer 2a is different from that of the electron-transport layer 2b.

14. The light-emitting apparatus according to claim 13,
wherein the first EL layer comprises the electron-transport layer 1a between the light-emitting layer 1a and the first intermediate layer,
wherein the second EL layer comprises the electron-transport layer 2a between the light-emitting layer 2a and the second intermediate layer, and
wherein the composition of the electron-transport layer 1a is the same as that of the electron-transport layer 1b and the composition of the electron-transport layer 2a is the same as that of the electron-transport layer 2b.

15. The light-emitting apparatus according to claim 14,
wherein one or both of the electron-transport layer 1a and the electron-transport layer a comprise one kind of organic compound.

16. The light-emitting apparatus according to claim 15,
wherein the first intermediate layer and the second intermediate layer are charge-generation layers.

17. The light-emitting apparatus according to claim 1,
wherein the first heteroaromatic ring is the same as the second heteroaromatic ring.

18. The light-emitting apparatus according to claim 1,
wherein the first heteroaromatic compound is the same as the second heteroaromatic compound.

19. The light-emitting apparatus according to claim 1,
wherein the first organic compound is the same as the second organic compound.

20. The light-emitting apparatus according to claim 1,
wherein the first organic compound is an organic compound comprising a heteroaromatic ring.

21. The light-emitting apparatus according to claim 1,
wherein the first organic compound is an organic compound comprising a heteroaromatic ring that is the same as the first heteroaromatic ring.

22. The light-emitting apparatus according to claim 1,
wherein the second organic compound is an organic compound comprising a heteroaromatic ring.

23. The light-emitting apparatus according to claim 1,
wherein the second organic compound is an organic compound comprising a heteroaromatic ring that is the same as the second heteroaromatic ring.

24. The light-emitting apparatus according to claim 1, wherein one or both of the first organic compound and the second organic compound are heteroaromatic compounds each comprising two or more nitrogen atoms.

25. The light-emitting apparatus according to claim 1, wherein one or both of the first organic compound and the second organic compound comprise heteroaromatic rings comprising two or more nitrogen atoms.

26. The light-emitting apparatus according to claim 1, wherein one or both of the first heteroaromatic compound and the second heteroaromatic compound comprise two or more nitrogen atoms.

27. The light-emitting apparatus according to claim 1, wherein one or both of the first heteroaromatic ring and the second heteroaromatic ring comprise two or more nitrogen atoms.

28. The light-emitting apparatus according to claim 1,
wherein one or both of the first heteroaromatic ring and the second heteroaromatic ring are π-electron deficient heteroaromatic rings.

29. The light-emitting apparatus according to claim 1,
wherein one or both of the first heteroaromatic ring and the second heteroaromatic ring are condensed heteroaromatic rings.

30. The light-emitting apparatus according to claim 1,
wherein one or both of the first heteroaromatic compound and the second heteroaromatic compound are organic compounds comprising π-electron deficient heteroaromatic rings.

31. The light-emitting apparatus according to claim 1,
wherein one or both of the first heteroaromatic ring and the second heteroaromatic ring are any of a heteroaromatic ring comprising a polyazole skeleton, a heteroaromatic ring comprising a pyridine skeleton, a heteroaromatic ring comprising a diazine skeleton, and a heteroaromatic ring comprising a triazine skeleton.

32. The light-emitting apparatus according to claim 1,
wherein the first EL layer comprises a first electron-injection layer that is between the first electron-transport layer and the first cathode and in contact with the first cathode,
wherein the second EL layer comprises a second electron-injection layer that is between the second electron-transport layer and the second cathode and in contact with the second cathode, and
wherein the first electron-injection layer and the second electron-injection layer are continuous in the first light-emitting device and the second light-emitting device.

33. The light-emitting apparatus according to claim 1,
wherein the first cathode and the second cathode are continuous in the first light-emitting device and the second light-emitting device.

34. An electronic device comprising the light-emitting apparatus according to claim 1, a sensor, an operation button, and a speaker or a microphone.
